(19) United States
(12) Patent Application Publication
(10) Pub. No.: US 2011/0050227 A1
(43) Pub. Date: Mar. 3, 2011

(54) System and Methods for Manipulating Coherence of Spins and Pseudospins Using the Internal Structure of Strong Control Pulses

(76) Inventors: Sean E. Barrett, North Haven, CT (US); Yanqun Dong, Stratford, CT (US); Rona G. Ramos, New Haven, CT (US); Dale Li, Boulder, CO (US)

(21) Appl. No.: 12/676,825

(22) PCT Filed: Sep. 5, 2008
(86) PCT No.: PCT/US08/10393

§ 371 Date: Nov. 17, 2010

Related U.S. Application Data
(60) Provisional application No. 60/967,627, filed on Sep. 6, 2007.

(51) Int. Cl. G01R 33/48

(52) U.S. Cl. 324/310

(57) ABSTRACT

Systems and methods are provided for controlling coherence of a magnetic resonance signal of spin species. The small difference between hard π pulses and their delta-function approximation is exploited to provide new classes of spin echoes which have applications in nuclear magnetic resonance (NMR) spectroscopy, magnetic resonance imaging (MRI) and magnetic resonance microscopy (MRM), and related spectroscopies of solids, and mixtures of solids and liquids. Systems and methods are also provided for controlling coherence of the resonance signal from pseudospin species.

### 1. CROSS-REFERENCE TO RELATED APPLICATION

This application claims priority to U.S. Provisional Application No. 60/967,627, filed Sep. 6, 2007.

This invention was made with Government support under grants no. (FRG) DMR-0653377, no. (ITR) DMR-0325580, and no. DMR-0207539 awarded by the National Science Foundation (NSF). This invention also was made with support in part by the National Security Agency (NSA) and Advanced Research and Development Activity (ARDA) under Army Research Office (ARO) Contracts No. DAAD19-01-1-0507 and No. DAAD19-02-1-0203. The Government has certain rights in the invention.

### 2. FIELD OF THE INVENTION

The invention relates to systems and methods for controlling coherence of a magnetic resonance signal of spin species. The invention also relates to systems and methods for controlling coherence of the resonance signal from pseudospin species.

### 3. BACKGROUND OF THE INVENTION

In typical clinical magnetic resonance imaging (MRI) applications, nuclear magnetic resonance (NMR) measurements are made to detect the resonance signal from hydrogen (1H), also referred to as protons, in water. Usually, these NMR measurements are carried out in a constant externally applied magnetic field of strength B=1.5 Tesla applied in a direction, about which the spin species precess in the presence of the magnetic field. Pulsed magnetic field gradients (e.g., spatially-varying magnetic fields) and radio-frequency (rf) pulses are then applied to the samples, in addition to the constant externally applied magnetic field, to produce a resonance signal. The spatially-varying magnetic fields are applied to derive spatial information from the NMR signal. The time scale for the spin species to relax to the equilibrium state after an excitation is applied goes as the spin-lattice relaxation time constant T₁. However, the detected signals actually decay (i.e., diminish) approximately exponentially with time constant T₂ which is usually shorter than T₁. Time constant T₂ is the transverse relaxation time, such as due to fluctuating magnetic fields experienced by the spin species. Time constant T₂ may vary by tissue type and disease state, and can be greater than 10 ms.

A common technique for manipulating the magnetic resonance signals in order to detect magnetic resonance signals involves applying various rf pulses in a sequence, with the goal of producing what are commonly referred to as spin echoes, which are points during the motion of the spin species when a previously decaying (i.e., diminishing) signal is observed to re-emerge, thereby facilitating additional measurement of resonance signals from the sample. For example, the basic two-pulse Hahn echo sequence produces an echo signal after the application of a single rf pulse that rotates the spin species by an angle of 90° (also referred to as a π/2 pulse), followed after a time interval by a single rf pulse that rotates the spin species by an angle of 180° (also referred to as a π pulse). The NMR signal observed following the initial π/2 excitation pulse decays with time constant T₂* due to, e.g., spin-spin relaxation and inhomogeneous effects, such as a distribution of chemical shifts or magnetic field gradients, which cause different spin species to precess at different rates, resulting in decoherence or dephasing of the NMR signal. The π pulse applied after a period of time τ of dephasing causes rephrasing of the signal to form an echo at time 2τ.

The minimal volume element that can be resolved in conventional MRI is slightly below (1 mm)³. The technique of MRI may be modified to resolve smaller length scales (e.g., to image a single cell) in a technique called Magnetic Resonance Microscopy (MRM). MRM uses stronger constant magnetic fields (B˜10 Tesla), smaller rf coils, and smaller gradient coils, in an effort to resolve volume elements down to about (0.005 mm)³.

MRI and MRM signals of soft tissue are usually dominated by the NMR signal from the protons (¹H) of water in the tissue. Since hydrogen is abundant in biological tissues, and protons (¹H) have the largest NMR frequency/field ratio and soft tissues have long values of T₂, most imaging schemes exploit the protons (¹H) magnetic resonance signals from soft tissues to generate the images. The ability to extend MRI and MRM to the study of solids or solid tissues could provide a wealth of additional information about the samples. However, the magnetic resonance signals from solids in the presence of water is generally overshadowed by the greater magnetic resonance signals from the protons (¹H) as well as the much shorter time constant T₂ of isotopes in solids (i.e., T₂ ranging from 0.01 ms to less than 10 ms). An imaging technique directed at measuring solids, or mixtures of solids and liquids, would allow imaging using other nuclear isotopes, such as ³¹P, ¹⁹F, ¹³C, ²³Na, ¹⁵N, and ¹⁷O in the presence of ¹H, without resorting to longer signal acquisition times, or other conventional techniques for detecting small signals. While attempts have been made to carry out such “atypical” imaging, there is a need in the art for new techniques that greatly increase the spatial resolution for detection of other isotopes in the presence of ¹H, and as a result accelerate image acquisition. Such a novel solids-imaging technique could transform the role of atypical MRI/MRM measurements in biomedical research.

Previous attempts at applying MRI/MRM techniques to solids have provided less-than-satisfactory results due to the differences in the environments of the nuclear isotopes in a solid versus a liquid or gas. The behavior of the spin species in any material solid, liquid, or gas, in the absence of an externally applied pulse, is governed by an internal Hamiltonian energy (Hᵢₙₜ), which may be expressed as a sum of a Zeeman term (H_{z}), which is linear in the spin angular momentum, and a dipolar coupling term (H_{zz}), which is bilinear in the spin angular momentum. The attainable resolution in imaging techniques is limited by the contribution to the time constant T2 from the dipolar coupling term H_{zz}. The dipolar coupling terms in the Hamiltonian governing the motion of the nuclear spins plays different roles in solids versus in liquids or gases. In liquids or gasses, the motion of the molecules causes the dipolar coupling term to average to zero, therefore, the magnetic resonance signals from liquids exhibit longer values of T₂. In a solid, however, the dipolar coupling term H_{zz} is non-zero and causes shorter time constants T₂, which adversely affects both the signal to noise ratio and the spatial resolution of the MRI/MRM of solids. Therefore, control of the effects of H_{zz} becomes very important in any attempt to develop a technique for imaging solids, or solids in the presence of a liquid.

A technique optimized for imaging solids would need to exert some form of control over the effect of the dipolar coupling term H_{zz} on the time constant T₂ of the solid. But since the dipolar coupling term H_{zz} plays little role in the behavior of spin species of liquids, but a far greater role in the behavior of spin species in solids, known pulses sequences used for obtaining NMR signals from liquids fail or give poor results when applied to solid samples. For example, the well-known Carr-Purcell-Meiboom-Gill (CPMG) sequence is often used for NMR. The CPMG sequence involves (a) the application of a rf pulse to rotate the spins species by an angle of 90° (also referred to as a π/2 pulse) about the x-direction (where the direction of the externally-applied constant field defines the z-direction), and then a repeated series of rf pulses, each of which cause the spin species to rotate by 180° (also referred to as a π pulse) about the y-direction, each π pulse being separated from the other by a time interval of duration 2τ during which no rf pulse is applied. Spin echoes are acquired in the 2τ time interval after each π pulse during application of the CPMG sequence. As discussed in greater detail in Section 6.3, CMPG fails to control dephasing due to H_{zz} which causes difficulties in the NMR of solids. Li et al., Generating Unexpected Spin Echoes in Dipolar Solids with π Pulses, Physical Review Letters 98:190401 (2007); Li et al., The Intrinsic Origin of Spin Echoes in Dipolar Solids Generated by Strong Pi Pulses, Phys. Rev. B 77:214306 (2008). The Hamiltonian for other known sequences, such as the Alternating-Phase CPMG sequence (APCPMG) (90_{X}-{−Y,Y}^{N}), the Carr-Purcell sequence (CP) (90_{X}-{X,X}^{N}), and the Alternating-Phase Carr-Purcell sequence (APCP) (90_{X}-{−Y,Y}^{N}), have similar dipolar-coupling terms. Id. Therefore, the known sequences CPMG, APCPMG, CP, and APCP are not ideal for imaging many solids, and a pulse sequences that eliminates the effect of the dipolar coupling on NMR signals is desirable.

A known approach to solid-state imaging that attempts to improve upon the previously discussed sequences uses coherent averaging, i.e., applying a particular sequence of rf pulses in order to nullify the effect of H_{zz} over some time interval. In principle, the technique would make the NMR signal from a solid appear to be like that of a liquid. An example of such a technique is the Magic Sandwich Echo (MSE) sequence. Matsui, S., Solid-State NMR Imaging by Magic Sandwich Echoes, Chem. Phys. Lett. 179, 187 (1991); see also Rhim, W. K., Pines, A. & Waugh, J. S. Violation of the Spin-Temperature Hypothesis, Phys. Rev. Lett. 25, 218 (1970); Rhim, W. K., Pines, A. & Waugh, J. S., Time-Reversal Experiments in Dipolar-Coupled Spin Systems, Phys. Rev. B 3, 684 (1971); Takegoshi, K. & McDowell, C. A., A “Magic Echo” Pulse Sequence For The High-Resolution NMR Spectra of Abundant Spins in Solids, Chem., Phys. Lett. 116, 100 (1985). In the MSE sequence, an example of which is illustrated in FIG. 6A, in which a continuous rf field (−hω₁Iₓ_{_{T}}) applied along the ±x-direction is sandwiched between two 90° pulses, picks out the part of the dipolar coupling that is secular (i.e., time independent) in the strong transverse field, i.e.,

$${H}_{zz} \to - \frac{1}{2} {H}_{xx} ,$$

which is then rotated to

$$- \frac{1}{2} {H}_{ZZ} ,$$

corresponding to a negative dipolar evolution. That is, the MSE negative dipolar evolution during the MSE effectively reverses dephasing due to the dipolar coupling term in the Hamiltonian during free evolution periods (i.e., a period during which no rf pulse is applied). Sequences such as the MSE, however, require a small resonance offset, i.e., a small value of H_{z} such that ∥H_{z}∥<<∥H_{zz}∥, during the entire period labeled Burst “B” in FIG. 6A. The spatial encoding which is necessary for imaging is limited by the size of the H_{z} that can be turned on for the Free Evolution periods “C” and “A” in FIG. 6A, then turned off for Burst “B”. Pulsed gradient magnetic fields have been used to deal with this problem, but the experimental requirements are formidable, e.g., turning on and off applied components of H_{Z} in time intervals of less than 50 μs. Ideally, the MSE sequence should be applied repeatedly to the spin species to build up the rephasing, but the rapid pulsing required in the MSE is difficult to implement. Therefore, there is a need for a technique that provides for control of the influence of H_{zz} even in the presence of H_{Z} that is large enough to encode spatial information.

The Zeeman term H_{Z} may also limit the resolution attainable during imaging. The Zeeman term H_{Z} also contains a term Ω_{z}^{loc}I_{z}_{_{T}} which can differ in various areas of the sample, since Ω_{z}^{loc} can differ throughout a sample due to bulk diamagnetism and imperfections in the external magnetic field. The differing values of Ω_{z}^{loc} result in a Zeeman line broadening. Therefore, a technique that not only controls the influence of H_{zz}, but also controls the influence of varying Ω_{z}^{loc} in order to narrow the Zeeman linewidth would also help to improve imaging.

Finally, due to the short T₂ time constants for semisolids and solids, NMR measurements of solids requires the use of short or “hard” control pulses. A control pulse is “hard” if the amplitude of the pulse is much greater than the spectral linewidth and any resonance offset. When hard pulses have been used to control coherent evolution, they have often been approximated as instantaneous delta functions. Slichter, C. P., Principles of Magnetic Resonance (Springer, New York, ed. 3, 1996); Mehring, M., Principles of High-Resolution NMR in Solids (Springer-Verlag, Berlin, ed. 2, 1983); Ernst, R. R., Bodenhausen, G., & Wokaun, A. Principles of Nuclear Magnetic Resonance in One and Two Dimensions (Clarendon Press, Oxford, 1987). However, as the inventors of the present invention have discovered, while the corrections to this picture are quite small for a single hard pulse, the corrections can lead to larger effects in sequences having many π pulses, as will be explained herein. Li, et al. Generating Unexpected Spin Echoes in Dipolar Solids with π Pulses, Physical Review Letters 98, 190401 (2007); Li, et al. The Intrinsic Origin of Spin Echoes in Dipolar Solids Generated by Strong Pi Pulses, Phys. Rev. B 77:214306 (2008). For example, under the delta-function approximation, the repeated sequence of π pulses in the CPMG sequence would result in the same resonance signal from the spin species as the Alternating-Phase-Carr-Purcell-Meiboom-Gill (APCPMG) pulse sequence, in which each the π pulse is applied to cause rotation in alternating orientations along the y-direction (i.e., alternating between −y and +y). However, as discussed herein below, the inventors have observed that CPMG and APCPMG behave quite differently, and have found that the difference is due to magnetic field contribution that appear inside the π pulses of these sequences. Thus, a pulse sequence designed for use in imaging solids should preferably take into account the fact that the delta approximation breaks down for pulse sequences including several hard π pulses.

Therefore, in order to improve the imaging capabilities for solids, there is a need for pulse sequences that account for the differences between π pulses and their delta-function approximation, and provide for control of the influence of H_{zz}, and/or varying Ω_{z}^{loc}.

### 4. SUMMARY OF THE INVENTION

The invention provides a method for controlling coherence of a magnetic resonance signal of a sample in an external magnetic field applied in the positive z-direction, the sample comprising a plurality of spin species, the method comprising the following steps in the order stated:

(a) applying a first pulse sequence to the sample N/2 times, wherein N is an even integer greater than or equal to 2, the first pulse sequence comprising the following steps in the order stated:

(i) a first free-evolution period for a time duration τ₁;

(ii) a first approximate π pulse in the positive or negative x-direction applied for a time duration tₚ;

(iii) a second free-evolution period for a time duration 2τ₂;

(iv) a second approximate π pulse in the direction of the first approximate π pulse applied for the time duration tₚ; and

(v) a third free-evolution period for the time duration τ₃;

wherein the first approximate π pulse and the second approximate π pulse are each applied with an offset frequency ν having a magnitude greater than or equal to zero,

whereby the duration of the first pulse sequence is t_{c}≈τ₁+2τ₂+τ₃+2tₚ; and

(b) applying a second pulse sequence to the sample N/2 times, the second pulse sequence comprising the following steps in the order stated:

(i) a fourth free-evolution period for the time duration τ₄;

(ii) a third approximate π pulse in a second direction substantially opposite to the direction of the first approximate π pulse applied for the time duration tₚ;

(iii) a fifth free-evolution period for the time duration 2τ₅;

(iv) a fourth approximate π pulse in the direction of the third approximate π pulse applied for the time duration tₚ; and

(v) a sixth free-evolution period for the time duration τ₆;

wherein the third approximate π pulse and the fourth approximate π pulse are each applied with an offset frequency ν₁=±ν,

whereby the duration of the second pulse sequence is approximately t_{c}; whereby the coherence of the magnetic resonance signal is controlled.

In different aspects of the invention, the time durations have one or more of the following relationships: 2τ₂≈τ₁+τ₃, 2τ₅≈τ₄+τ₆, or 2τ₂≈τ₁+τ₃ and 2τ₅≈τ₄+τ₆.

In specific embodiments, the method is applicable to a sample where motion of the spin species is governed by a Hamiltonian having a Zeeman term H_{Z} and a dipolar-coupling term H_{ZZ}, and wherein ∥H_{Z}∥<∥H_{ZZ}∥.

In a first aspect according to the invention, the offset frequency is ν₁=−ν and time durations τ₁, τ₂, τ₃, τ₄, τ₅, and τ₆ are approximately equal to each other, and the method further comprises the steps of:

(c) after step (b), applying an approximate π/2 pulse to the sample:

(i) in the positive y-direction if ν≦0 and the first approximate it pulse is in the positive x-direction, or if ν≧0 and the first approximate π pulse is in the negative x-direction, or

(ii) in the negative y-direction if ν≧0 and the first approximate π pulse is in the positive x-direction, or if ν≦0 and the first approximate π pulse is in the negative x-direction; and

(d) after step (c), allowing free evolution of the plurality of spin species for a seventh free-evolution period; whereby the magnetic resonance signal reaches a maximum value at a time proportional to the magnitude of the offset frequency ν. The method may further comprise the step of measuring the magnetic resonance signal at a plurality of times during the seventh free-evolution period. The magnitude of the offset frequency ν may be zero or nonzero.

In a second aspect according to the invention, the offset frequency is ν₁=ν and time durations σ₁, σ₂, τ₃, τ₄, τ₅, and τ₆ are approximately equal to each other, said method further comprising:

(a) prior to step (a), allowing free evolution of the plurality of spin species for a seventh free-evolution time period of duration Δ+δ, wherein Δ=N t_{c}/4 and Δ≧|δ|;

(b) after step (c) but prior to step (a), applying a first approximate π/2 pulse to the sample in the positive or negative y-direction with an offset frequency ν;

(c) after step (b), applying a second approximate π/2 pulse to the sample in the positive or negative y-direction with an offset frequency ν; and

(d) after step (e), allowing free evolution of the plurality of spin species for an eighth free-evolution time period of duration Δ−δ; whereby performing steps (c), (d), (a), (b), (e), and (f) in the order stated results in substantially no net dipolar evolution of the plurality of spin species. The method may further comprise repeating steps (c), (d), (a), (b), (e), and (f) in the order stated, wherein, in said repeating, said first approximate π pulse is applied in the positive or negative x′-direction, and said first and second approximate π/2 pulses are applied in the positive or negative y′-direction, and wherein the x′-direction and the y′-direction are rotated in the x-y plane by an angle φ relative to the x-direction and the y-direction.

In another embodiment, the value δ=0 and the first approximate π/2 pulse and the second approximate π/2 pulse are both in the positive y-direction or are both in the negative y-direction, where the method further comprises:

(e) prior to step (c), applying a third approximate π/2 pulse in a first direction;

(f) repeating steps (c), (d), (a), (b), (e), and (0 in the order stated m−1 additional times, wherein in is an integer greater than or equal to 2; and

(g) measuring the magnetic resonance signal during at least one occurrence of step (c), during at least one occurrence of step (f), and/or at a time corresponding to a transition between an occurrence of step (c) and an occurrence of step (f). The first direction may be the positive or negative x-direction.

(h) In a specific embodiment, the first direction is the positive or negative y-direction, and the method further comprises:

(i) after step (h), repeating steps (c), (d), (a), (b), (e), and (f) in the order stated P times, wherein P is an integer greater than or equal to 1, wherein in a first occurrence of steps (c), (d), (a), (b), (e), and (f) in the order stated, the first approximate π pulse is in a second direction; wherein in said repeating steps (c), (d), (a), (b), (e), and (f) in the order stated in step (h), the first approximate π pulse is in either the second direction or a direction opposite to the second direction; and wherein in said repeating steps (c), (d), (a), (b), (e), and (f) in the order stated in step (j), the first approximate pi pulse is in the direction opposite to the second direction.

In accordance with the second aspect of the invention, the method may further comprise:

(a) prior to step (c), applying a pulse sequence consisting of the following steps in the order stated:

(i) a third approximate π/2 pulse in the positive or negative x-direction applied with an offset frequency ν;

(ii) a ninth free-evolution period for a time duration Δ+t₀, wherein Δ>|t₀|;

(iii) a fourth approximate π/2 pulse in the positive or negative y-direction applied with an offset frequency ν;

(iv) a tenth free-evolution period for the time duration τ,

(v) an fifth approximate π pulse in the positive or negative x-direction applied with the offset frequency ν;

(vi) an eleventh free-evolution period for the time duration 2τ,

(vii) a sixth approximate π pulse in the same direction as the fifth approximate π pulse applied with the offset frequency ν;

(viii) a twelfth free-evolution period for the time duration τ;

(ix) a thirteenth free-evolution period for the time duration τ,

(x) a seventh approximate π pulse in a direction substantially opposite to the direction of the fifth approximate π pulse applied with the offset frequency ν;

(xi) a fourteenth free-evolution period for the time duration 2τ,

(xii) an eighth approximate π pulse in the direction of the seventh approximate π pulse applied with the offset frequency ν;

(xiii) a fifteenth free-evolution period for the time duration τ;

(xiv) a fifth approximate π/2 pulse in the positive or negative y-direction applied with an offset frequency ν; and

(xv) a sixteenth free-evolution period for a time duration Δ−t₀;

(b) repeating steps (c), (d), (a), (b), (e), and (l) in the order stated m−1 additional times, wherein m is an integer greater than or equal to 2, wherein the first approximate π/2 pulse and the second approximate π/2 pulse are in opposite directions, and wherein the direction of the first approximate π/2 pulse in a first repetition is the same as or opposite to the direction of the first approximate π/2 pulse in any additional repetitions;

(c) measuring the magnetic resonance signal during at least one occurrence of step (c), during at least one occurrence of step (f), and/or at a time corresponding to a transition between an occurrence of step (c) and an occurrence of step (f).

According with this aspect of the invention, the method may further comprise a step of: (j) performing a Fourier transform on the measured time-domain magnetic resonance signal to provide a frequency-domain signal with a maximum value at a frequency proportional to the offset frequency ν. In another embodiment, the method may further comprise repeating steps (g), (c), (d), (a), (b), (e), (f), (h), (i), and (j) in the order stated one or more times, each said repeating being with a different value of offset frequency ν, thereby yielding a plurality of frequency-domain signals, each having a maximum value at a frequency proportional to the corresponding value of offset frequency ν. In yet another embodiment, the method further comprises

(d) repeating steps (g), (c), (d), (a), (b), (e), (f), (h), and (i) in the order stated, wherein in a first occurrence of performing steps (g), (c), (d), (a), (b), (e), (f), (h), and (i) in the order stated, t₀=0 and a first measured time-domain magnetic resonance signal is obtained, and wherein in said repeating steps (g), (c), (d), (a), (b), (e), (f), (h), and (i) in the order stated,

t₀=t₁>0 and a second measured time-domain magnetic resonance signal is obtained;

(e) superimposing the first measured time-domain magnetic resonance signal and the second measured time-domain magnetic resonance signal to provide a composite time-domain signal;

(f) performing a Fourier transform on the composite time-domain signal to provide a frequency-domain signal with a maximum value at a frequency value proportional to the offset frequency ν;

(g) repeating steps (j), (k), and (l) in the order stated one or more times, each said repeating being with a different value of offset frequency ν, thereby yielding a plurality of frequency-domain signals, each having a maximum value at a frequency proportional to the corresponding value of offset frequency ν.

In a specific embodiment,

$${t}_{1} = - ( \frac{Δ}{2} + \frac{1}{2 {ω}_{1}} )$$

and the approximate π pulses have a strength ω₁=π/tₚ.

In some embodiments according to the second aspect of the invention, the method further comprises:

(a) after step (j), but before step (l), repeating steps (g), (c), (d), (a), (b), (e), (f), (h), and (i) in the order stated, wherein in said repeating in step (n), t₀=t₂, t₂>0, and t₂≠t₁, and a third measured time-domain magnetic resonance signal is obtained; and wherein in said superimposing in step (k), the first measured time-domain magnetic resonance signal, the second measured time-domain magnetic resonance signal, and the third measured time-domain magnetic resonance signal are superimposed to provide the composite time-domain signal. A gradient magnetic field may be applied in the z-direction during at least one occurrence of step (c) and/or step (f), wherein the gradient magnetic field has a magnitude that varies across the sample, and obtaining a frequency-domain signal with a plurality of local maxima corresponding to magnetic resonance signals for a plurality of regions of the sample. The gradient magnetic field may be applied during at least one occurrence of step (a) and/or step (b). The method may further include applying a gradient magnetic field m, varying the gradient magnetic field with time during at least one occurrence of step (c) and/or step (f), and holding the gradient magnetic field constant in time and nonzero during at least one occurrence of step (a) and/or step (b).

In a third aspect of the invention, δ equals zero, and the method further comprising:

(a) prior to step (c), applying a pulse sequence consisting of the following steps in the order stated:

(i) a third approximate π/2 pulse in the positive x-direction;

(ii) a ninth free-evolution period for a time duration Δ+t₀, wherein Δ>|t₀|;

(iii) a fourth approximate π/2 pulse in the negative or positive y-direction applied with an offset frequency ν;

(iv) a tenth free-evolution period for the time duration τ,

(v) an fifth approximate π pulse in the positive or negative x-direction applied with the offset frequency ν;

(vi) an eleventh free-evolution period for the time duration 2τ,

(vii) a sixth approximate π pulse in the same direction as the fifth approximate π pulse applied with the offset frequency ν;

(viii) a twelfth free-evolution period for the time duration τ;

(ix) a thirteenth free-evolution period for the time duration τ,

(x) a seventh approximate π pulse in a direction opposite to the direction of the fifth approximate π pulse applied with the offset frequency ν;

(xi) a fourteenth free-evolution period for the time duration 2τ,

(xii) an eighth approximate π pulse in the direction of the seventh approximate π pulse applied with the offset frequency ν;

(xiii) a fifteenth free-evolution period for the time duration τ;

(xiv) a fifth approximate π/2 pulse in the negative y-direction applied with an offset frequency ν; and

(xv) a sixteenth free-evolution period for a time duration Δ−t₀;

(b) repeating steps (c), (d), (a), (b), (e), and (f) in the order stated m−1 additional times, wherein m is an integer greater than or equal to 2, wherein the first approximate π/2 pulse and the second approximate π/2 pulse are in the same direction, and wherein the direction of the first approximate π/2 pulse in a first repetition is the same as or opposite to the direction of the first approximate π/2 pulse in any additional repetitions;

(c) applying a gradient magnetic field, wherein the gradient magnetic field varies with time during at least one occurrence of step (c) and/or step (f) and the gradient magnetic field remains constant with time during step (a) and/or step (b), whereby performing steps (c), (d), (a), (b), (e), (f), (h), and (i) in the order stated results in a net Zeeman evolution due to a Hamiltonian term dependant on ν and no net Zeeman evolution due to local interactions;

(d) measuring the magnetic resonance signal during at least one occurrence of step (c), during at least one occurrence of step (f), and/or at a time corresponding to a transition between an occurrence of step (c) and an occurrence of step (f); and

(e) repeating steps (g), (c), (d), (a), (b), (e), (f), (h), (i), and (j) in the order stated one or more times, each said repeating being with a different value of offset frequency ν, thereby yielding a plurality of frequency-domain signals, each having a maximum value at a frequency proportional to the corresponding value of offset frequency ν.

In fourth aspect of the invention, τ₁=τ₂=τ₃, further comprises:

(f) prior to step (a), allowing free evolution of the plurality of spin species for a seventh free-evolution time period of duration Δ+δ, wherein δ>−Δ;

(g) after step (c) but prior to step (a), applying a first approximate π/2 pulse to the sample in the positive or negative y-direction;

(h) after step (b), applying a second approximate π/2 pulse to the sample in the same direction as the first approximate π/2 pulse; and

(i) after step (e), allowing free evolution of the plurality of spin species for an eighth free-evolution time period of duration Δ+δ; and

(j) measuring the magnetic resonance signal.

In a preferred embodiment, the motion of the spin species is governed by a Hamiltonian having a Zeeman term H_{Z} and a dipolar-coupling term H_{ZZ}, and wherein ∥H_{Z}∥≧∥H_{ZZ}∥.

The invention further provides a method of controlling coherence of a magnetic resonance signal of a sample in an external magnetic field applied in the positive z-direction, the sample comprising a plurality of spin species, the method comprising the following steps in the order stated:

(k) applying a pulse sequence to the sample N times, wherein N is an integer greater than or equal to 1, the pulse sequence consisting of the following steps in the order stated:

(i) a first free-evolution period for a time duration τ;

(ii) a first approximate π pulse in the negative x-direction applied for a time duration tₚ;

(iii) a second free-evolution period for a time duration 2τ,

(iv) a second approximate π pulse in the positive x-direction applied for the time duration tₚ; and

(v) a third free-evolution period for the time duration τ;

whereby the duration of the pulse sequence is t_{c}≈4τ+2tₚ; and

(l) applying an approximate π/2 pulse to the sample in the negative x-direction; and

(m) applying a third approximate π pulse to the sample in the positive or negative y-direction at a time t₁ selected to produce an echo at time t_{echo}>t₁, thereby controlling coherence of the magnetic resonance signal.

In some embodiments,

$${t}_{1} = ( \frac{α - β - 2 λ}{4} ) {Nt}_{c} , α = \frac{4 τ}{{t}_{c}} , β = \frac{{t}_{p}}{{t}_{c}} , and λ = \frac{4 {t}_{p}}{π {t}_{c}} .$$

In another aspect, the motion of a first subset of the plurality of spin species is governed by a first Hamiltonian H₁ having a first Zeeman term H_{Z1}, and a first dipolar-coupling term H_{ZZ1} and motion of a second subset of the plurality of spin species is governed by a second Hamiltonian H₂ having a second Zeeman term H_{Z2} and a second dipolar-coupling term H_{ZZ2}, wherein H_{Z1} is different from H_{Z2} causing the magnetic resonance signal to decohere and/or H_{ZZ1} is different from H_{ZZ2} causing the magnetic resonance signal to decohere, the method further comprising selecting t₁ so that coherence is substantially restored at time t_{echo}. In a specific embodiment, H_{Z1} is different from H_{Z2} and H_{ZZ1} is different from H_{ZZ2}, and wherein the decoherence due to the difference between H_{Z1} and H_{Z2} and the decoherence due to the difference between H_{ZZ1} and H_{ZZ2} are both substantially eliminated at time t_{echo}, thereby substantially restoring coherence at time t_{echo}.

The invention further provides a method of controlling coherence of a magnetic resonance signal of a sample in an external magnetic field applied in the positive z-direction, the sample comprising a plurality of spin species, the method comprising:

(n) applying a first pulse sequence N times, wherein N is an integer greater than or equal to 1, the first pulse sequence having the form {−X,X};

(o) applying a second pulse sequence M times, wherein M is an integer greater than or equal to 1, wherein the second pulse sequence is applied before or after the first pulse sequence, the second pulse sequence having the form {X,−X}; and

(p) applying, after the first pulse sequence and the second pulse sequence, an approximate π/2 pulse in the positive or negative x-direction, thereby producing an echo in the magnetic resonance signal.

The invention further provides a method of controlling coherence of a magnetic resonance signal of a sample in an external magnetic field applied in the positive z-direction, the sample comprising a plurality of spin species, wherein the motion of the spin species is governed by a Hamiltonian having a Zeeman term H_{Z} and a dipolar-coupling term H_{ZZ}, the method comprising applying a pulse sequence of the form {N, δ, Ψ₁, Ψ₂, Φ₁, Φ₂, Φ₃, Φ₄} to produce at least one echo, whereby the coherence of the magnetic resonance signal is controlled. In a preferred embodiment, ∥H_{Z}∥≧∥H_{ZZ}∥.

The invention further provides a method of controlling coherence of a magnetic resonance signal of a sample comprising a plurality of spin species, the method comprising applying an external magnetic field in a first direction, applying a pulse sequence comprising a plurality of approximate π pulses in at least one direction approximately perpendicular to the external magnetic field, the approximate π pulses having respective durations, the approximate π pulses separated by periods of free evolution having respective durations, wherein the durations of the approximate π pulses and the durations of the periods of free evolution are selected to control coherence in the magnetic resonance signal, whereby the pulse sequence is defined by a Hamiltonian having a quadratic effective-field term that depends on the durations of the approximate π pulses and the durations of the free periods of evolution, and the coherence of the magnetic resonance signal is controlled by an effect of the quadratic effective-field term.

The invention further provides a method of controlling coherence of a magnetic resonance signal of a sample comprising a plurality of spin species, the method comprising applying an external magnetic field in a first direction, applying a pulse sequence comprising a plurality of approximate π pulses in at least one direction approximately perpendicular to the external magnetic field, the approximate π pulses having respective durations, the approximate π pulses separated by periods of free evolution having respective durations, wherein the durations of the approximate π pulses and the durations of the periods of free evolution are selected to control coherence in the magnetic resonance signal, whereby the pulse sequence is defined by a Hamiltonian having a linear effective-field term that depends on the durations of the approximate π pulses and the durations of the free periods of evolution, and the coherence of the magnetic resonance signal is controlled by an effect of the linear effective-field term.

The invention further provides a method of controlling coherence of a magnetic resonance signal of a sample in an external magnetic field applied in the positive z-direction, the sample comprising a plurality of spin species, the method comprising:

(q) applying an approximate π/2 pulse in the positive or negative x-direction;

(r) applying a pulse sequence to the sample N times, wherein N is an integer greater than or equal to 1, the pulse sequence comprising the following steps in the order stated:

(i) a first free-evolution period for a time duration τ;

(ii) a first approximate π pulse in the positive or negative y-direction applied for a time duration tₚ;

(iii) a second free-evolution period for a time duration 2τ;

(iv) a second approximate π pulse in a direction opposite to the direction of the first approximate π pulse applied for the time duration tₚ; and

(v) a third free-evolution period for the time duration τ;

(s) applying a third approximate π pulse to the sample in the positive or negative y-direction; and

(t) applying the pulse sequence to the sample at least N times;

whereby an echo is produced in the magnetic resonance signal at a time occurring when the pulse sequence has been applied for a total of 2N times and coherence of the magnetic resonance signal is thereby controlled.

In some embodiments, the echo is an echo of an echo train. In another aspect, the magnitude of the echo grows before the total of 2N pulses is applied, and diminishes after said total of 2N pulses is applied.

The invention further provides a method of controlling coherence of a magnetic resonance signal of a sample in an external magnetic field applied in the positive z-direction, the sample comprising a plurality of spin species, the method comprising:

(u) applying an approximate π/2 pulse in the positive or negative x-direction;

(v) applying a first pulse sequence to the sample N times, wherein N is an integer greater than or equal to 1, the first pulse sequence comprising the following steps in the order stated:

(i) a first free-evolution period for a time duration τ;

(ii) a first approximate π pulse in the positive or negative y-direction applied for a time duration tₚ;

(iii) a second free-evolution period for a time duration 2τ;

(iv) a second approximate π pulse in a direction opposite to the direction of the first approximate π pulse applied for the time duration tₚ; and

(v) a third free-evolution period for the time duration τ;

(w) applying a second pulse sequence to the sample M times, wherein M is an integer greater than or equal to N, the second pulse sequence comprising the following steps in the order stated:

(i) a fourth free-evolution period for a time duration τ;

(ii) a third approximate π pulse in the direction of the second approximate π pulse applied for a time duration tₚ;

(iii) a fifth free-evolution period for a time duration 2τ;

(iv) a fourth approximate π pulse in the direction of the first approximate π pulse applied for the time duration tₚ; and

(v) a sixth free-evolution period for the time duration τ; and whereby an echo is produced in the magnetic resonance signal at a time occurring when the second pulse sequence has been applied N times and coherence of the magnetic resonance signal is thereby controlled. In a specific embodiment, M=2N, and the method further comprises the step of applying a third pulse sequence at least one time, wherein the third pulse sequence comprises:

(x) applying the first pulse sequence M times;

(y) applying the second pulse sequence M times; whereby an echo is produced during at least one occurrence of step (c) after the first pulse sequence has been applied M/2 times and an echo is produced during at least one occurrence of step (d) after the second pulse sequence has been applied M/2 times and coherence of the magnetic resonance signal is thereby controlled.

The invention further provides a method of controlling coherence of a magnetic resonance signal of a sample in an external magnetic field applied in the positive z-direction, the sample comprising a plurality of spin species, the method comprising:

(z) applying a pulse sequence to the sample N times, wherein N is an integer greater than or equal to 1, the pulse sequence consisting of the following steps in the order stated:

(i) a first free-evolution period for a time duration τ;

(ii) a first approximate π pulse in the positive or negative x-direction applied for a time duration tₚ;

(iii) a second free-evolution period for a time duration 2τ,

(iv) a second approximate π pulse in a direction opposite to the direction of the first approximate πpulse applied for the time duration tₚ; and

(v) a third free-evolution period for the time duration τ;

whereby the duration of the pulse sequence is t_{c}≈4τ+2tₚ; and

(aa) applying an approximate π/2 pulse to the sample in the positive or negative x-direction; and

(bb) allowing for free evolution of the plurality of spin species, whereby at a time during step (c) net evolution of the plurality of spin species due to dipolar coupling is zero; whereby coherence of the magnetic resonance signal is controlled.

The approximate π/2 pulse may be in the positive or negative x-direction, whereby at a time during step (c) net evolution of the plurality of spin species due to Zeeman interaction is zero.

The invention further provides a method of controlling coherence of a magnetic resonance signal of a sample comprising a plurality of spin species, the method comprising:

(a) applying an external magnetic field in a positive direction along a first axis to a sample comprising a plurality of spin species, wherein motion of said plurality of spin species, in the absence of any additional externally applied magnetic field or radio-frequency (rf) field, is governed by an internal Hamiltonian (Hᵢₙₜ) comprising a Zeeman term (H_{z}) and a dipolar term (H_{ZZ}); and

(b) applying two or more pulse sequences to said sample, each said pulse sequence comprising a plurality of hard approximate nπ pulses, wherein n is a positive odd integer, and a plurality of periods of free evolution having respective duration, said periods of free evolution separating each said hard approximate tin pulse from each other, each said hard approximate nπ pulse in each said pulse sequence being applied in a positive or negative direction along a second axis perpendicular to said first axis, each said hard approximate nπ pulse in each said pulse sequence having a respective duration of ntₚ, wherein tₚ is a duration of a hard approximate π pulse, and each said approximate hard nπ pulse in each said pulse sequence optionally differing in values of n and in direction along the second axis;

wherein, each said pulse sequence has a even number greater than zero of said hard approximate nπ pulses such that in a limit where each of said hard approximate nπ pulses in said pulse sequence is considered to have zero duration, said plurality of spin species are returned at the end of said pulse sequence to substantially the same orientation as said plurality of spin species had prior to applying said pulse sequence;

wherein, for each said pulse sequence, the number of said approximate nπ pulses in said pulse sequence, said values of n for said approximate nπ pulses in said pulse sequence, said directions of said approximate nπ pulses in said pulse sequence, and said durations of said periods of free evolution in said pulse sequence, are such that when each said hard approximate nπ pulse is considered to have nonzero duration, said motion of said plurality of spin species during said applying said pulse sequence is governed by a respective effective Hamiltonian for said pulse sequence comprising a nonzero term representing an effective magnetic field applied in a positive or negative direction along a third axis;

wherein said motion of said plurality of spin species during said applying a first pulse sequence of said two or more pulse sequences is governed by an effective Hamiltonian H_{eff1} and said motion of said plurality of spin species during said applying a second pulse sequence of said two or more pulse sequences is governed by an effective Hamiltonian H_{eff2}≠H_{eff1}; and

wherein applying said first pulse sequence and said second pulse sequence of said two or more pulse sequences causes said plurality of spin species to cohere at one or more times after said applying said first pulse sequence and said second pulse sequence of said two or more pulse sequences, thereby controlling said coherence of said magnetic resonance signal of said sample.

In some embodiments, the method further comprises allowing free evolution of said plurality of spin species for an additional period before or after said applying said two or more pulse sequences, whereby motion of said plurality of spin species during said additional period of free evolution is governed by Hᵢₙₜ, wherein said two or more pulse sequences are such that said applying said two or more pulse sequences causes a motion of said plurality of spin species opposite to a motion of said plurality of spin species caused by H_{z} and/or H_{zz} during said additional period of free evolution, whereby said plurality of spin species cohere at a time t after said applying said two or more pulse sequences, said time t occurring during or after said additional period.

In some embodiments, the respective effective Hamiltonians and Hᵢₙₜ are such that both Zeeman phases and dipolar phases of said motion of said plurality of spin species cohere substantially at time t. In some embodiments, said applying said first pulse sequence of said two or more pulse sequences causes a first motion of said plurality of spin species, said applying said second pulse sequence causes a second motion of said plurality of spin species, and said second motion of said plurality of spin species reverses said first motion of said plurality of spin species. In some embodiments, the plurality of spin species cohere to form an echo in said magnetic resonance signal. In some embodiments, said plurality of hard approximate nπ pulses and said durations of said periods of free evolution are selected such that the effective Hamiltonian of the pulse sequence is approximated by a unitary operator having a linear effective field term or a quadratic effective field term.

The sample may comprises a solid, a soft solid or a partially-aligned liquid.

In some embodiment, the first pulse sequence and said second pulse sequence are each repeated N/2 times, wherein N is an even integer greater than or equal to two. In some embodiments, the first pulse sequence and said second pulse sequence are such that applying said first pulse sequence and said second pulse sequence results in no net evolution due to H_{z} and/or H_{zz}. In some embodiments, said first axis is the z-axis, said second axis is the y-axis, and said first pulse sequence comprises a repeating block of the form {Y,−Y}, whereby said third axis is the x-axis and said respective effective Hamiltonian for said first pulse sequence has a term λΩ_{z}^{net}Iₓ_{_{T}}. In yet other embodiments, said first axis is the z-axis, said second axis is the y-axis, and said first pulse sequence comprises a repeating block of the form {−Y,Y}, whereby said third axis is the x-axis and said respective effective Hamiltonian for said first pulse sequence has a term −λΩ_{z}^{net}Iₓ_{_{T}}. In yet other embodiments, said first axis is the z-axis, the second axis is the y-axis, and said first pulse sequence comprises a repeating block of the form {±Y,±Y}, whereby said third axis is the y-axis and said respective effective Hamiltonian for said first pulse sequence has a term ±(κΩ_{z}^{net})²I_{y}_{_{T}}. In yet other embodiments, the third axis is perpendicular to the first axis.

The invention further provides a method of imaging a solid comprising executing the steps of any one of the methods disclosed herein that relate to spin species.

The invention further provides an apparatus for controlling an instrument for measuring a magnetic resonance signal of a sample in an external magnetic field applied in the positive z-direction, the sample comprising a plurality of spin species, the apparatus comprising:

(c) a processor; and

(d) a memory, coupled to the processor, the memory storing a module comprising:

(i) instructions for performing the steps of any of the methods that relate to spin species; and

(ii) instructions for outputting a measured magnetic resonance signal to a user interface device, a monitor, a computer-readable storage medium, a computer-readable memory, or a local or remote computer system, or for displaying the measured magnetic resonance signal.

The invention further provides a computer readable medium storing a computer program executable by a computer to control an instrument for measuring a magnetic resonance signal of a sample in an external magnetic field in the positive z-direction, the sample comprising a plurality of spin species, the computer program comprising:

(a) instructions for performing the steps of any of the methods that relate to spin species; and

(b) instructions for outputting a measured magnetic resonance signal to a user interface device, a monitor, a computer-readable storage medium, a computer-readable memory, or a local or remote computer system, or for displaying the measured magnetic resonance signal.

In some embodiments, the spin species is governed by a Hamiltonian having a Zeeman term H_{Z}, a dipolar-coupling term H_{ZZ}, and another term Hₒₜₕₑᵣ. In some embodiments, ∥H_{Z}+H_{ZZ}∥≧∥Hₒₜₕₑᵣ∥. In yet other embodiments, the sample is subjected to magic angle spinning.

The invention further provides a method of controlling coherence of a resonance signal of a sample comprising a plurality of pseudospin species whose motion, in the absence of any additional externally applied field, is governed by an equivalent Hamiltonian (Hᵢₙₜ) comprising an equivalent Zeeman term (H_{z}) and an equivalent dipolar term (H_{ZZ}), the method comprising:

applying two or more pulse sequences to said sample, each said pulse sequence comprising a plurality of hard approximate nπ pulses, wherein n is a positive odd integer, and a plurality of periods of free evolution having respective duration, said periods of free evolution separating each said hard approximate nπ pulse from each other, each said hard approximate nπ pulse in each said pulse sequence being applied along a first axis, each said hard approximate nπ pulse in each said pulse sequence having a respective duration of ntₚ, wherein tₚ is a duration of a hard approximate π pulse, and each said approximate hard nπ pulse in each said pulse sequence optionally differing in values of n and in direction along the second axis; wherein, each said pulse sequence has an even number greater than zero of said hard approximate nπ pulses such that in a limit where each of said hard approximate nπ pulses in said pulse sequence is considered to have zero duration, said plurality of pseudospin species are returned at the end of said pulse sequence to substantially the same state as said plurality of pseudospin species had prior to applying said pulse sequence; wherein, for each said pulse sequence, the number of said approximate nπ pulses in said pulse sequence, said values of n for said approximate nπ pulses in said pulse sequence, said directions of said approximate nπ pulses in said pulse sequence, and said durations of said periods of free evolution in said pulse sequence, are such that when each said hard approximate nπ pulse is considered to have nonzero duration, said motion of said plurality of pseudospin species during said applying said pulse sequence is governed by a respective effective Hamiltonian for said pulse sequence comprising a nonzero term representing an effective magnetic field applied in a positive or negative direction along a third axis perpendicular to the first axis; wherein said motion of said plurality of pseudospin species during said applying a first pulse sequence of said two or more pulse sequences is governed by an effective Hamiltonian H_{eff1} and said motion of said plurality of pseudospin species during said applying a second pulse sequence of said two or more pulse sequences is governed by an effective Hamiltonian H_{eff2}≠H_{eff1}; and wherein applying said first pulse sequence and said second pulse sequence of said two or more pulse sequences causes said plurality of pseudospin species to cohere at one or more times after said applying said first pulse sequence and said second pulse sequence of said two or more pulse sequences, thereby controlling said coherence of said resonance signal of said sample.

In some embodiments, the method further comprises allowing free evolution of said plurality of pseudospin species for an additional period, whereby motion of said plurality of pseudospin species during said additional period of free evolution is governed by Hᵢₙₜ, wherein said two or more pulse sequences are such that said applying said two or more pulse sequences causes a motion of said plurality of pseudospin species opposite to a motion of said plurality of pseudospin species caused by H_{z} and/or H_{zz} during said additional period of free evolution, whereby said plurality of pseudospin species cohere at a time t after said applying said two or more pulse sequences, said time t occurring during or after said additional period.

In some embodiments, the respective effective Hamiltonians and Hᵢₙₜ are such that both Zeeman phases and dipolar phases of said motion of said plurality of pseudospin species cohere substantially at time t. In other embodiments, said applying said first pulse sequence of said two or more pulse sequences causes a first motion of said plurality of pseudospin species, said applying said second pulse sequence causes a second motion of said plurality of pseudospin species, and said second motion of said plurality of pseudospin species reverses said first motion of said plurality of pseudospin species. In some embodiments, the sample comprises an array of pseudospin species. In other embodiments, said first pulse sequence and said second pulse sequence are each repeated N/2 times, wherein N is an even integer greater than or equal to two. In yet other embodiments, said first pulse sequence and said second pulse sequence are such that applying said first pulse sequence and said second pulse sequence results in no net evolution due to H_{z} and/or H_{zz}. In specific embodiments, the motion of the spin species is governed by a Hamiltonian having an equivalent Zeeman term H_{Z}, an equivalent dipolar-coupling term H_{ZZ}, and another term Hₒₜₕₑᵣ.

The invention further provides a method of imaging an array of pseudospin species comprising executing the steps of any one of the methods disclosed herein that relate to pseudospin species.

The invention further provides an apparatus for controlling an instrument for measuring a resonance signal of a sample, the sample comprising a plurality of pseudospin species, the apparatus comprising:

(a) a processor; and

(b) a memory, coupled to the processor, the memory storing a module comprising:

(i) instructions for performing the steps of any of the methods that relate to pseudospin species; and

(ii) instructions for outputting a measured magnetic resonance signal to a user interface device, a monitor, a computer-readable storage medium, a computer-readable memory, or a local or remote computer system, or for displaying the measured resonance signal.

The invention further provides a computer readable medium storing a computer program executable by a computer to control an instrument for measuring a resonance signal of a sample, the sample comprising a plurality of pseudospin species, the computer program comprising:

(a) instructions for performing the steps of any of the methods that relate to pseudospin species; and

instructions for outputting a measured magnetic resonance signal to a user interface device, a monitor, a computer-readable storage medium, a computer-readable memory, or a local or remote computer system, or for displaying the measured resonance signal.

### 5. BRIEF DESCRIPTION OF THE DRAWINGS

FIG. 1A shows the results of measurements made to compare the Carr-Purcell-Meiboom-Gill (CPMG) pulse sequence and the Alternating-Phase-Carr-Purcell-Meiboom-Gill (APCPMG) pulse sequence on a sample of C₆₀.

FIG. 1B shows measurements on a sample of C₆₀ obtained using the sequence 90_{X}-{−Y,Y}^{N1}-180_{Y}-{−Y,Y}^{N2}, where N₁ and N₂ are integers greater than or equal to one and represent the number of times each of the respective repeating blocks is repeated.

FIG. 1C shows a CPMG of the echo train. A CPMG of the echo train is induced by modifying the APCPMG sequence with eleven phase reversals (90_{X}-{−Y,Y}^{N1}{Y,−Y}^{N2}{−Y,Y}^{N3} . . . {Y,−Y}^{N12} where N1=10, and N2, N3, . . . , N12=20). τ=25 μs, and only the peak of each echo is shown.

FIG. 2A illustrates the APCPMG pulse sequence.

FIG. 2B illustrates the sequence 90_{X}-{−Y,Y}^{N1}-180_{Y}-{−Y,Y}^{N2}, where N₁ and N₂ are integers greater than or equal to one and represent the number of times each of the respective repeating blocks is repeated.

FIG. 2C illustrates the sequence 90_{X}-{−Y,Y}^{N1}-{Y,−Y}^{N2}, where N₁ and N₂ are integers greater than or equal to one and represent the number of times each of the respective repeating blocks is repeated.

FIG. 2D illustrates repeated application of the sequence of FIG. 2C.

FIG. 3A illustrates a general building block sequence in accordance with certain exemplary embodiments according to the methods.

FIG. 3B illustrates a more specific form of a building-block sequence in accordance with certain exemplary embodiments according to the methods.

FIG. 3C shows the building-block sequence of FIG. 3B with the additional constraint that δτ=0 and m=n=1.

FIG. 4A illustrates the dipolar and Zeeman phases of the spin species using the exemplary sequence {−X,X}^{N}-90_{-X}-t_{free}.

FIG. 4B illustrates the dipolar and Zeeman phases of the spin species using the exemplary sequence {−X,X}^{N}-90_{X}-t_{free}.

FIG. 4C illustrates the dipolar and Zeeman phases of the spin species using the exemplary sequence {−X,X}^{N}-90_{-X} t_{f}_{₁}-180_{Y}-t_{free}. In FIGS. 4A-C, representative values of Ω_{z}^{net}/h=+/−100 Hz and Ω^{D}/h=+/−15 Hz are shown.

FIG. 4D shows the results of measurements on a sample of C₆₀ obtained using the pulse sequences of illustrated in FIGS. 4A (spectrum A in FIG. 4D), 4B (spectrum B in FIG. 4D), and 4C (spectrum C in FIG. 4D) using τ=50 μs and N=200.

FIG. 5A illustrates an exemplary sequence of the form (Δ+δ)-90_{ψ}_{₁}{φ₁,φ₂}^{N/2}{φ₃,φ₄}^{N/2}-90_{ψ}_{₂}-(Δ−δ), which is represented by the notation {N, δ,ψ₁, ψ₂, φ₁, φ₂, φ₃, φ₄}

FIG. 5B illustrates an exemplary sequence of the form {N, δ, ψ, ÷Ψ, φ, φ, −φ, −φ}.

FIG. 6A illustrates the Magic Sandwich Echo (MSE) sequence.

FIG. 6B illustrates an exemplary pulse sequence applicable to MRI/MRM.

FIGS. 7A-B shows a comparison of the quadratic echoes produced for sample C₆₀ with Ω_{Z}^{net,±}=Ω_{Z}^{loc}±Ω_{offset}^{global}, where Ω_{offset}^{global}≡−hv_{offset} FIGS. 7A-B illustrate the dipolar and Zeeman phases of the spin species using the exemplary sequence {X,X}^{N/2}{−X,−X}^{N/2}-90_{Y}-tₜᵣₑₑ for ν_{offset}=0 Hz (FIG. 7A), −3 Hz (FIG. 7B).

FIGS. 7C-D show the dipolar and Zeeman phases of the spin species using the exemplary sequence {−X, X}^{N/2}{X,−X}^{N/2}-90_{X}-t_{free} for ν_{offset}=0 Hz (FIG. 7C), −1 Hz (FIG. 7D).

FIG. 7E shows measurements on C60 using the sequences in FIGS. 7A-D, with signal measurement beginning at the end of the burst (t=0 ms).

FIG. 7F shows is an image plot of 31 quadratic echoes as a function of Ω_{offset}^{global} for 0 Hz≦Ω_{offset}^{global}≦3 kHz in steps of 100 Hz. The black trend line indicates the Zeeman refocusing time predicted. τ=10μ and N=100.

FIG. 8 shows the results of measurements obtained using a time suspension sequence of the form 90_{X}-{2, 0, −Y, −Y, X, X, −X, −X}^{m}, showing The line-narrowing data from sample Si:Sb (˜10¹⁷/cm³) with N=2, τ=60 μs, ν_{offset}=2.5 kHz, and m=84000.

FIG. 9 shows the results of measurements obtained using exemplary sequences for differing values of the approximate 71 pulses. The slow exponential signal decay observed with the line narrowing sequence (FIG. 23) is similar even when there is an intentional uniform misadjustment of all pulse angles. FIG. 9(a-c) with N=2 and ν_{offset}=3.5 kHz; FIG. 7(d-f) with N=10 and ν_{offset}=0 Hz.

FIG. 10 shows the results from a series of applications of a particular sequence comprised of Zeeman-evolution blocks, applied with differing values of ν_{offset}, showing a reproduction of a top-hat lineshape using sequence 90X-{2, tₒ, −Y, −Y}-{2, 0, −Y, Y}^{m} for m=30, τ=22 μs, and tₒ=0. Each trace is the measured spectrum of a pseudo-FID with different ν_{offset}, for −4 kHz≦ν_{offset}≦+4 kHz in steps of 500 Hz. To obtain this full bandwidth, the pseudo-FID interleaves a second data set using the same sequence, but with

$${t}_{o} = - ( \frac{Δ}{2} + \frac{1}{2 {ω}_{1}} ) .$$

Signal amplitude and frequency are accurately reconstructed over the range 2π|ν_{offset}∥/ω₁≦16%, even with misadjustment of pulse angles.

FIG. 11 shows the results of measurements similar to FIG. 10, obtained using exemplary sequences for differing values of the approximate π pulses. The MRI top-hat lineshape in FIG. 10 uses optimized pulse angles (π=180°). FIG. 11(b,c) show an intentional uniform misadjustment of all pulse angles to 170° and 160° also leads to similar MRI top-hat lineshapes.

FIGS. 12A-F show the steps to obtain one spectrum for the MRI top-hat lineshape shown in FIG. 10. The resulting spectrum (FIG. 12F, dashed line) looks quite similar to the (˜260 Hz) normal spectrum obtained from the FID (FIG. 12F, solid line).

FIGS. 13A-13C show the steps in a method for creating and evaluating a candidate pulse sequence block for controlling the coherence of magnetic resonance signals.

FIG. 14 shows the steps in a method for creating and evaluating a candidate pulse sequence for controlling the coherence of the magnetic resonance signals

FIG. 15 shows an exemplary computer system.

FIG. 16 shows the results of measurements of phosphorus (³¹P) on a human deciduous tooth (FIG. 16A) and a cattle bone (FIG. 16B).

FIG. 17 shows the results of measurements obtained on Adamantane.

FIG. 18 shows measurements obtained using pattern of a +δ block (i.e., a block with a positive value of delta) followed by a −δ block (i.e., a block with a negative value of delta), and where the data obtained with the X-channel of the n^{th} echo is multiplied by (−1)^{th} before the data from the X- and Y-channels are interspersed. The data-processing steps are followed to obtain the Pseudo-Hahn echo in FIG. 22.

FIG. 19A illustrates the APCPMG pulse sequence with signal acquisition periods added during certain periods of free evolution.

FIG. 19B illustrates the sequence 90_{X}-{−Y,Y}^{N0}-{−Y,Y}^{N1}-180_{Y}-{−Y,Y}^{N2}, where N₀, N₁ and N₂ are integers greater than or equal to one and represent the number of times each of the respective repeating blocks is repeated, and with signal acquisition periods included during certain periods of free evolution.

FIG. 19C illustrates the sequence 90_{X}-{−Y,Y}^{N1}{Y,−Y}^{N2}, where N₁ and N₂ are integers greater than or equal to one and represent the number of times each of the respective repeating blocks is repeated, and with signal acquisition periods included during certain periods of free evolution.

FIG. 19D illustrates repeated application of the sequence of FIG. 19C.

FIG. 20 shows the results of measurements obtained in a Si:Sb sample.

FIGS. 21A-F show the slow exponential signal decay measured in C₆₀ with a line narrowing sequence (FIG. 23) is similar over a large range of Ω_{offset}^{global} (FIG. 21A-C), as well as over a range of N (FIG. 21D-F). FIGS. 21A-C show the results of measurements obtained using the time-suspension sequence block for differing values of Ω_{offset}^{global}. FIGS. 21D-F show the results of measurements obtained using the time-suspension sequence block 90_{X}-{N, 0, −Y, −Y, X, X, −X, −X}^{m} for differing values of N.

FIG. 22 shows direct measurement of Ω_{z}^{net} for δ≠0 and ψ₁=ψ₂, showing the pseudo-Hahn echo from sample C₆₀ produced by the sequence 90_{X}-{2, 0, −Y, Y}-{{2, −δ, −Y, −Y}{2, +δ, Y, Y}}^{m1}-{{2, +δ, −Y, −Y}{2, −δ, Y, Y}}^{m2}, for m₁=29, m₂=58, ν_{offset}=−2 kHz, τ=22 μs and δ=30 μs.

FIG. 23 shows the line narrowing sequence 90_{X}-{2, 0, −Y, −Y}^{m} applied to C₆₀ at room temperature.

FIG. 24A illustrates the exemplary sequence {−X,X}^{N}-90_{-X}-t_{free} used in FIG. 4A.

FIG. 24B illustrates the exemplary sequence {−X,X}^{N}-90_{X}-t_{free} used in FIG. 4B.

FIG. 24C illustrates the exemplary sequence {−X,X}^{N}-90_{-X}-t′-180Y-tₜᵣₑₑ. In the illustration in FIG. 4C and in the measurement taken in FIG. 4D (spectrum C), t′=t_{f}_{₁}.

FIG. 25A illustrates the exemplary sequence {X, X}^{N/2}{−X, −X}^{N/2}-90_{Y}-t_{free}

FIG. 25B illustrates the exemplary sequence {−X, X}^{N/2}{X,−X}^{N/2}-90_{X}.

FIGS. 26A-B show an exemplary combination sequence of the form

$${90}_{X} - {\{ \begin{matrix}\{ N , δ - Y , - Y , X , X , - X , - X \} - \{ N , δ - Y , - Y , X , X , - X , - X \} - \\ \{ N , δ , Y , Y , X , X , - X , - X \} - \{ N , δ , Y , Y , X , X , - X , - X \}\end{matrix} \}}^{N} .$$

FIG. 27 shows the results of measurements obtained with applying the sequence of FIGS. 26A-B.

FIG. 28 shows a block diagram of an exemplary NMR system.

FIG. 29 shows results of a ³¹P time-suspension measurement in a human deciduous tooth.

FIG. 30 shows the results of performing slice selection using the sequence block {N, δ, φ1, φ2, X, X, −X, −X} together with a DANTE 90 pulse.

FIG. 31 illustrates the pulse sequence used to get the five slices at −1500 Hz, −1000 Hz, −500 Hz, 0 Hz, 500 Hz, 1000 Hz, 1500 Hz in FIG. 30.

FIG. 32 illustrates a variation of the pulse sequence in FIG. 31, where both phase encoding and frequency encoding are included.

### 6. DETAILED DESCRIPTION OF THE INVENTION

Systems and methods for controlling the coherence of a magnetic resonance signal of a sample comprising a plurality of spin species are provided. The present invention is applicable to a system of spin species having integer or half-integer spin.

To analyze the magnetic resonance signal of the spin species of a sample, the sample is generally placed in an external magnetic field in what is taken to be the positive z-direction in a Cartesian coordinate system in the laboratory reference frame. The external magnetic field causes the net magnetization of the spin species to align along the positive z-axis, and the spin species to precess about the z-axis at the Larmor frequency in the laboratory frame of reference. It is often convenient to consider the system of spins in terms of a reference frame which rotates about the z-axis at the Larmor frequency (i.e., the rotating reference frame). In a magnetic resonance measurement, one or more radio-frequency (rf) pulses having a frequency νₚ are generally applied to the sample in the x-direction and/or y-direction. The rf pulses causes the net magnetization of the spin species to rotate away from the z-direction, and the evolution of the spin species is measured. The frequency νₚ of the rf pulse may be equal to the Larmor frequency ν_{L}. In certain embodiments, however, it is preferable for the rf pulse to be applied at frequency different from the Larmor frequency, thus resulting in a frequency offset ν_{offset}≡ν_{L}−νₚ. The systems and methods provided herein relate to controlling the coherence of the signal through the application of an advantageous sequences of rf pulses.

In a preferred embodiment, the behavior of the spin species in the sample is governed by an internal Hamiltonian energy (Hᵢₙₜ), which in a rotating frame, may be expressed as Hᵢₙₜ=H_{Z}+H_{zz}, where H_{z} is the Zeeman term and H_{zz} is the dipolar coupling term. The Zeeman term may be expressed as H_{Z}=(Ω_{z}^{loc}+Ω_{offset}^{global})I_{z}_{_{T}}=Ω_{z}^{net}I_{z}_{_{T}}, which includes a term due to a net resonance offset of the spin species Ω_{offset}^{global}≡−hv_{offset}, and a term due to the differing local environment of each spin species Ω_{z}^{loc}. The Zeeman term may also be expressed in terms of a net frequency Ω_{z}^{net} and the spin angular momentum I_{zT}, and is therefore a linear function of the spin angular momentum. The net resonance offset is produced by applying the rf pulses at frequency νₚ, which is different from the Larmor frequency ν_{L}. Macroscopic samples may be considered as an ensemble of mesoscopic clusters of spins species, and the spin species within each mesoscopic cluster may experience differing values of a local field Ω_{z}^{loc} due to bulk diamagnetism. These variations in the Ω_{z}^{loc} term cause Ω_{z}^{net} in the Zeeman Hamiltonian lead to a spread in precession angles that causes signal decay known as free-induction decay (FID). The dipolar coupling term (H_{zz}) is due to secular part of the homonuclear dipolar coupling and is expressed as

$${H}_{zz} = {\sum }_{i > j}^{N} {B}_{ij} ( 3 {I}_{{z}_{i}} {I}_{{z}_{j}} - {\vec{I}}_{i} \cdot {\vec{I}}_{j} ) .$$

The dipolar coupling term is therefore a bilinear function of the spin angular momentum. The dipolar coupling term averages to zero in liquids because of motion of the molecules. Solid samples, unlike liquid samples, have non-negligible H_{zz}. All of the systems, methods and apparatus disclosed herein are applicable to any system of spin species that is governed by an internal Hamiltonian that can be expressed in terms of a linear function of angular momentum (H_{z}) and a bilinear function of angular momentum (H_{zz}).

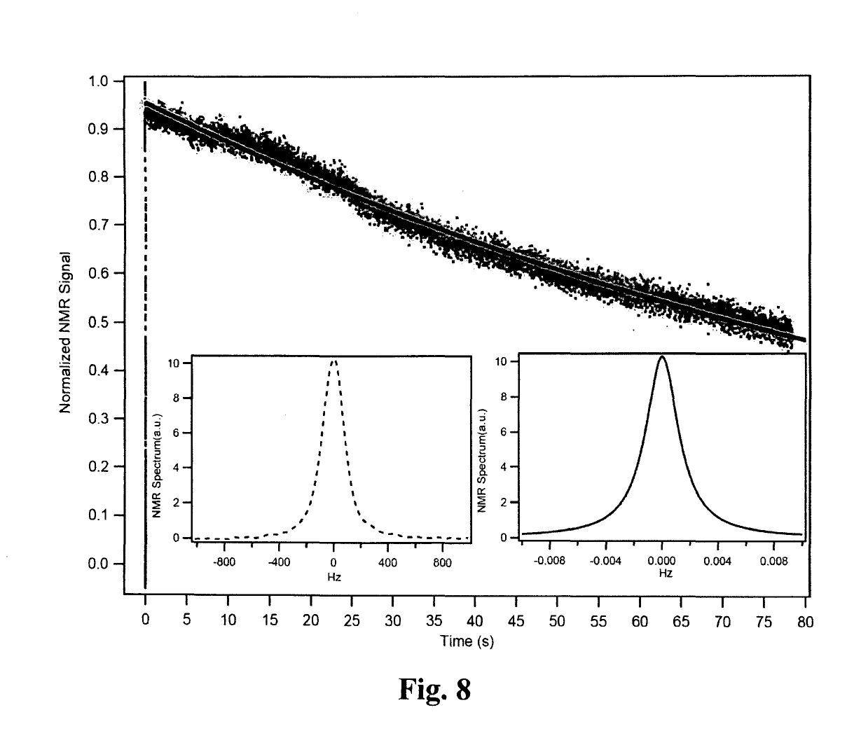

More broadly, all of the systems, methods and apparatus disclosed herein is applicable to spin species governed by an internal Hamiltonian that can be expressed as Hᵢₙₜ=(H_{Z}+H_{zz}Hₒₜₕₑᵣ) where Hₒₜₕₑᵣ are comparatively “small” terms for the \vec{I}ᵢ spins, e.g., ∥H_{Z}+H_{zz}∥≧∥Hₒₜₕₑᵣ∥. For example, Hₒₜₕₑᵣ could represent the weak coupling of the \vec{I}ᵢ spins to some other system of \vec{S}ⱼ spins. This kind of weak coupling term produces the slow decay of the signal observed in FIG. 8 (where the effective “T₂” approaches T₁). All methods, systems, and apparatus disclosed herein for spin species governed by the Hamiltonian Hᵢₙₜ=(H_{Z}+H_{zz}). can be used for spin species governed by the Hamiltonian Hᵢₙₜ=(H_{Z}+H_{zz}+Hₒₜₕₑᵣ).

All of the systems, methods and apparatus disclosed herein are also applicable to systems of spin species governed by mathematically similar forms of the internal Hamiltonian disclosed herein, such as systems of spin species governed by an internal Hamiltonian which includes:

a. an external (RF) pulse which has some variation (such as in strength and/or direction):

$${H}_{{P}_{φ}} = - ℏ {\sum }_{i}^{N} {ω}_{{1}_{i}} {I}_{{φ}_{i}} ,$$

b. a Zeeman term which has some variation from spin to spin:

$${H}_{Z} = {\sum }_{i}^{N} {Ω}_{{z}_{i}}^{net} {I}_{{z}_{i}} ,$$

c1. a Dipolar coupling term H_{zz} which is replaced by a generic Quadrupolar interaction:

$${H}_{{Q}_{generic}} = {\sum }_{i}^{N} {\vec{I}}_{i} \cdot {\vec{Q}}_{ij} \cdot {\vec{I}}_{i} ,$$

where \vec{Q}ᵢᵢ is a second-rank coupling tensor (R. Kimmich, et al., Quadrupolar Magic Echoes, Chem. Phys. Lett. 190, 503 (1992)), and/or

c2. a Dipolar coupling term H_{zz} which is replaced by a generic bilinear interaction:

$${H}_{{J}_{generic}} = {\sum }_{i > j}^{N} {\vec{I}}_{i} \cdot {\overleftrightarrow{J}}_{ij} \cdot {\vec{I}}_{j} ,$$

where \vec{J}ᵢⱼ is a second-rank coupling tensor.

All of the systems, methods and apparatus disclosed herein are also applicable to samples with restricted motion, such as “soft solids” (e.g., rubber), and partially aligned liquid samples (for example, liquid samples blended in with liquid crystals). In such samples, the dipolar coupling term H_{zz} (applicable to rigid solids) is replaced by a reduced magnitude version of H_{zz} (sometimes called the ‘residual dipolar coupling’). D. E. Demco, et al., “Residual Dipolar Couplings of Soft Solids by Accordion Magic Sandwich”, Chem. Phys. Lett. 375, 406 (2003). The pulse sequences disclosed herein could also be applied to the “soft solid” samples as well. All of the methods, systems, and apparatus disclosed herein for solids can be used for “soft solids.”

Furthermore, all of the systems, methods and apparatus described herein are broadly applicable to any physical system whose internal Hamiltonian contains a linear term (Zeeman-like) and a bilinear (coupling) term (dipolar-like) in the absence of a magnetic field. For instance, the Hamiltonian of certain two-level systems, such as certain quantum dots, may be described by an internal Hamiltonian having a linear term (Hₛ), e.g., representing the contributions to the total energy arising from the state of each two-level system (i.e, whether each system is in the higher level, the lower level, or a superposition of the two), and a bilinear term (Hₛₛ), representing a coupling, or cross term, that causes mixing of the otherwise isolated two-level systems. Such a system is referred to in the art as a system of pseudospins. More generally, any system with a finite dimensional Hilbert space (i.e., not only a two-level system, but any system having a finite number of levels) can be mapped onto, and be described as, a system of pseudospins. Various laser spectroscopy methods are known in the art which can cause the system of pseudospins to emit a resonance signal, such as under a laser pulse, and to behave similarly to a system of spin species under an rf pulse. The Hamiltonian for the pseudospin species may also include other terms Hₒₜₕₑᵣ, which are comparatively small terms, e.g., Hₛ+Hₛₛ≧Hₒₜₕₑᵣ.

An example of pseudospin species to which all of the methods disclosed herein are applicable is trapped polar molecules, such as diatomic molecules, wherein the electric dipole moments (EDMs) of the diatomic molecules is oriented along or against an external electric field in a quantum computer application. D. DeMille, “Quantum Computation with Trapped Polar Molecules”, Phys. Rev. Lett. 88, 067901 (2002). A further example of pseudospin species to which all methods disclosed herein are applicable is isolated polar molecules, e.g., those at an interface with mesoscopic superconducting resonators. A. Andre et al., A Coherent All-Electrical Interface between Polar Molecules and Mesoscopic Superconducting Resonators, Nature Physics 2, 636 (2006)). An array of pseudospins or pseudospin species herein refers to an ordered arrangement of the pseudospins or pseudospin species.

Another term applicable to pseudospins is a “local pulse Hamiltonian”, which is unique to Pseudo-spins (as opposed to magnetic resonance of real spins). The local pulse Hamiltonian may be written as:

$${H}_{{P}_{φ}} = - ℏ {\sum }_{i}^{m} {ω}_{{1}_{i}} {I}_{{φ}_{i}} ,$$

where m<N, and N is the total number of the \vec{I}ᵢ Pseudo-spins in the system. All of the systems, methods and apparatus disclosed herein also apply to samples comprising psudospin species governed by a Hamiltonian including a local pulse Hamiltonian. All of the methods disclosed herein can be applied to the complete Hamiltonian of the pseudospin species to provide the ‘optimal’ pulse sequences to use, and the range of applicability of these pulse sequences.

All of the systems, methods and apparatus provided herein may also be used for controlling the coherence of the resonance signal from such a system of pseudospins. In sum, the sequences and methods disclosed herein have application in MRI/MRM of solids, NMR, ESR, and laser spectroscopy, and in similar applications.

All methods, systems, and apparatus disclosed herein for spin species can be used for pseudospin species. The term “system” herein refers to apparatus as well as computer systems. Furthermore, methods, systems, and apparatuses, including the computer readable medium, described herein in connection with the NMR of spin species can be used in the techniques of MRI, MRM, and ESR. In addition, in a specific embodiment, all of the methods disclosed herein optionally include a step of outputting to a user interface device, a user-accessible computer readable storage medium, a monitor, a user-accessible local computer, or a user-accessible computer that is part of a network; or displaying, the information obtained by application of one or more steps of the methods. Moreover, all of the methods, apparatus and computer systems disclosed herein optionally include instructions for outputting to a user interface device, a user-accessible computer readable storage medium, a monitor, a user-accessible local computer, or a user-accessible computer that is part of a network; or displaying, the information obtained by application of one or more steps of the methods.

The novel pulse sequences and methods for creating pulse sequences according to certain embodiments of the presented invention are described infra.

### 6.1 DEFINITIONS

The “size” of an operator. References to the “size” of an operator herein refer to the square root of the trace of its matrix: ∥A∥≡{square root over ((Tr(A⁺A)))}.

“π” pulses, 180° pulses and “approximate π pulses”. The terms “π pulse” and “180° pulse” are used interchangeably. The π pulses considered herein are hard pulses, that is, pulses having magnitudes larger than or comparable with the linewidth of the resonance signal. Given a rf field strength ω₁, the duration of the π pulse is given by tₚ=π/ω₁, which is the duration of time over which the pulse is applied to effect a rotation of 180° In the alternative, for a desired pulse duration tₚ, the strength of the rf field that needs to be applied to effect a rotation of about 180° can be calculated by ω₁=π/tₚ. Section 6.5 discusses “approximate π pulses”, which are applications of a π-like pulses which does not necessarily result in an exact 180° rotation. The term “approximate π pulse” encompass rotations of 180° plus or minus about 5°, 180° plus or minus about 10°, 180° plus or minus about 15°, 180° plus or minus about 20°, or 180° plus or minus about 25°. In certain applications, the term “approximate π pulse” may encompass rotations of 180° plus or minus more than 25°. Furthermore, the term “π pulse” also encompasses nπ pulses, where n is an odd integer greater than zero. When the term “π pulse” or “180° pulse” is used herein, it is clear that “approximate π pulse” can be used in their place. In addition, by saying “π pulse” or “180° pulse” herein, it is also meant that “approximate π pulse” can be used. An “approximate π pulse” is to be considered applicable to any description herein relating to “π pulse” or “180° pulse”.

“π/2”, 90° pulses and “approximate π/2 pulses”. The terms “π/2 pulse” and “90° pulse” are used interchangeably. To effect a rotation of about 90°, the rf field is applied for roughly half the duration of time for the π pulse. The term “approximate π/2 pulse” encompass rotations of 90° plus or minus about 5° or 90° plus or minus about 10°. In certain applications, the term “approximate π/2 pulse” may encompass rotations of 90° plus or minus 15° or more. When the term “π/2 pulse” or “90° pulse” is used herein, it is clear that “approximate π/2 pulse” can be used in their place. In addition, by saying “π/2 pulse” or “90° pulse” herein, it is also meant that “approximate π/2 pulse” can be used. An “approximate π/2 pulse” is to be considered applicable to any description herein relating to “π/2 pulse” or “90° pulse”.

Coordinate system. The positive Z direction is taken to be the direction of the external DC magnetic field. The X and Y directions are in a plane substantially orthogonal to the Z direction, and are arbitrary provided the X, Y, and Z directions form a right-handed coordinate system. {φ₁, φ₂}. The general notation {φ₁, φ₂} represents the sequence (τ-180_{φ}_{₁}-2τ-180_{φ}_{₂}-τ), where 180_{φ}_{₁} and 180_{φ}_{₂} are 180° (or π) rotations (pulses) are about the φ₁-axis or the φ₂-axis, respectively, τ and 2τ represent periods of free evolution. In this notation, the CPMG pulse sequence is represented by the form 90_{X}-{Y,Y}^{N}, while the APCMG pulse sequence is represented by the form 90_{X}-{−Y,Y}^{N}, where N is an integers, and represent the number of times the sequence is repeated.

### 6.2 EXEMPLARY METHODS

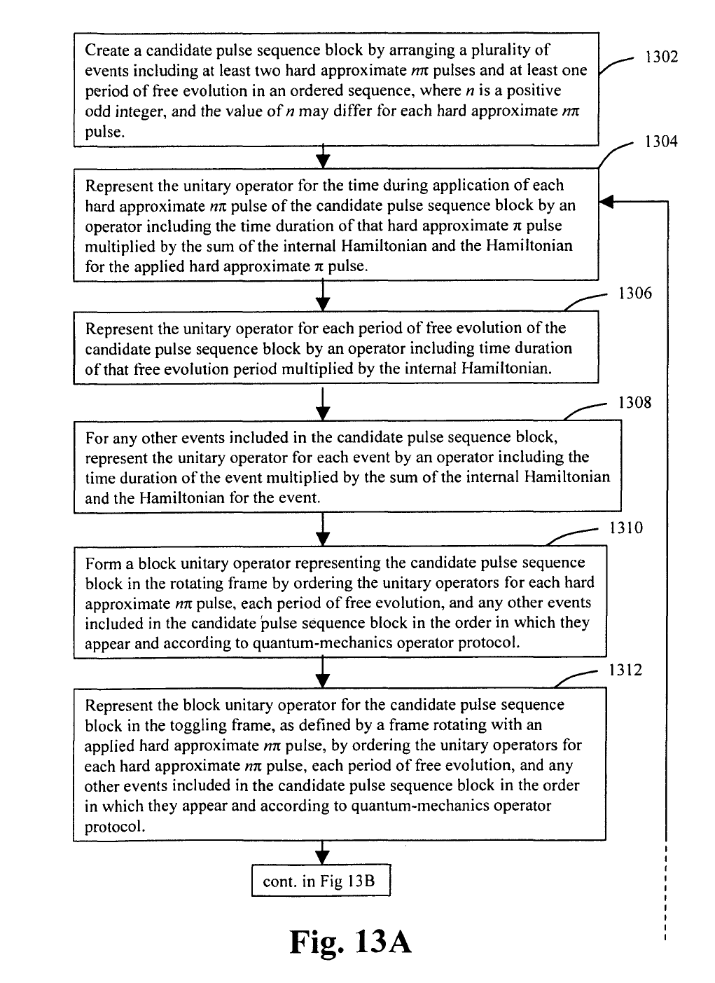

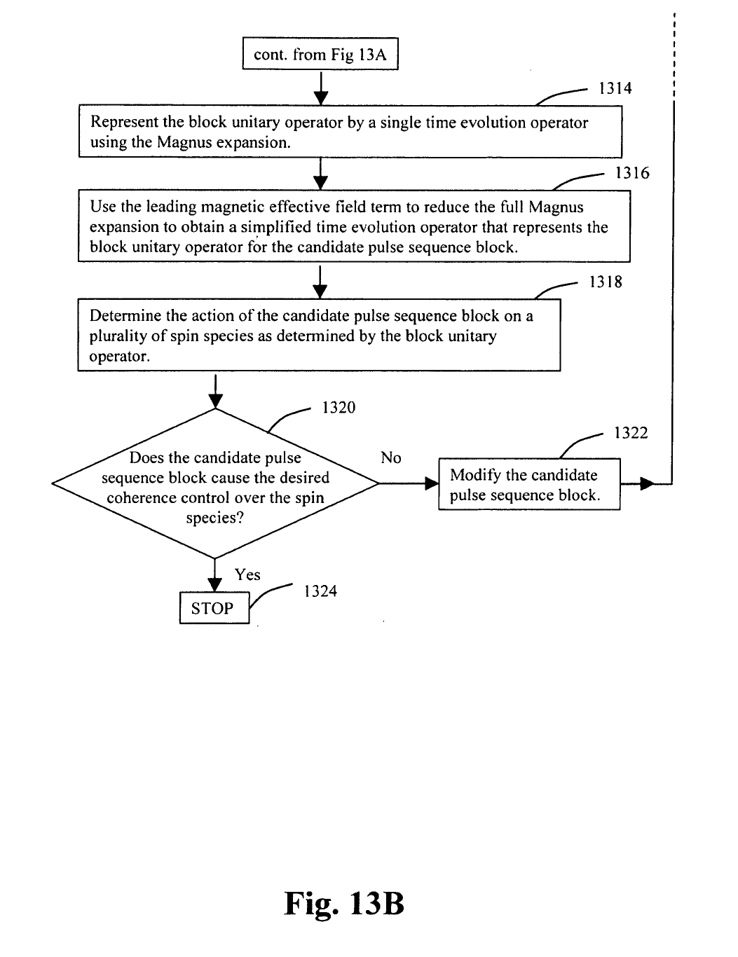

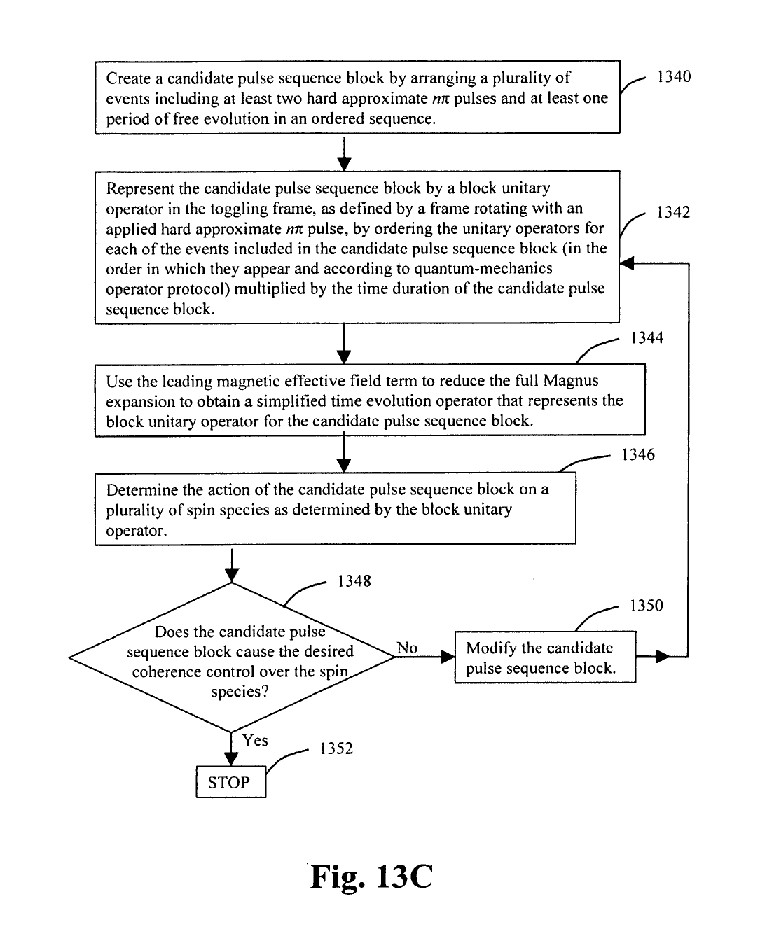

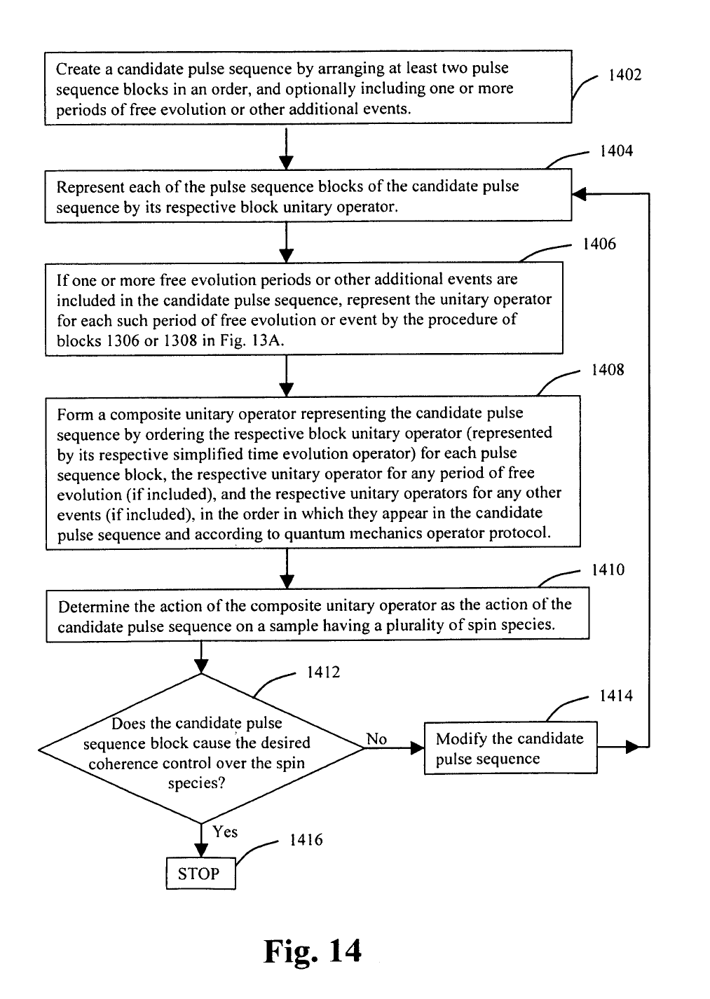

The methods and systems described herein can be used to control coherence of a resonance signal. In preferred embodiments, the resonance signal is a magnetic resonance signal, such as a nuclear magnetic resonance or electron spin resonance signal. In other embodiment, the resonance signal can be some other resonance signal, such a resonance signal from a system of pseudospins. As used herein, controlling coherence refers to actions performed on the spin species or pseudospins so that the species evolve in a deterministic, understandable fashion. In certain advantageous embodiments, coherence is controlled so as to produce one or more echoes in the signal. Exemplary methods in accordance with certain embodiments are shown in FIGS. 13A-13C and 14.

The steps 1302-1324 in a method for creating and evaluating a candidate pulse sequence block for controlling the coherence of the magnetic resonance signals from the spin species are shown in FIGS. 13A and 13B, and discussed below. It should be noted that steps 1302-1324 may also be followed for creating and evaluating a candidate sequence block for controlling the coherence of the resonance signals from pseudospin species.

Step 1302. A candidate pulse sequence block is created by arranging a plurality of events, including at least two hard approximate nπ pulses and at least one period of free evolution in an ordered sequence, where n is a positive odd integer, and the value of n may differ for each hard approximate nπ in pulse. The candidate pulse sequence block may be created in consideration of an intended coherence control. For example, a pulse sequence block may be created to cause an amount of control over the influence of dephasing due to the dipolar coupling term or one or more of the terms that contribute to dephasing in the Zeeman term (such as the varying local fields). In addition, the candidate pulse sequence may contain one or more π/2 pulses, one or more 2π pulses, or one or more of the novel pulse sequences disclosed herein whose control over the coherence of the spin species has been demonstrated.

A first step in the evaluation of the action of a candidate pulse sequence block on the spin species is the construction of the time evolution operator for each of the events in the candidate pulse sequence block.

Step 1304. The unitary operator for the time during application of each hard approximate nπ pulse of the candidate pulse sequence block is represented by an operator which includes the time duration of that hard approximate nπ pulse multiplied by the sum of the internal Hamiltonian and the Hamiltonian for the applied hard approximate nπ pulse. As shown in Tables IA and IIA in Section 6.4.2, during the application of a hard nπ pulse of duration ntₚ, the expression for the Hamiltonian in the rotating frame includes a term for the a hard nπ pulse that has a duration tₚ, as well as the internal Hamiltonian.

Step 1306. The unitary operator for each period of free evolution of the candidate pulse sequence block is represented by an operator which includes the time duration of that free evolution period multiplied by the internal Hamiltonian. Tables IA and IIA of Section 6.4.2 show that, during each period of free evolution, the motion of the spin species is governed by solely the internal Hamiltonian.

Step 1308. The unitary operator for events other than the hard nπ pulse and the periods of free evolution includes the time duration of the event multiplied by the sum of the internal Hamiltonian and the Hamiltonian for the event.

Step 1310. A block unitary operator representing the candidate pulse sequence block in a rotating frame rotating at or near the Larmor frequency is constructed by ordering the unitary operators for each hard approximate nπ pulse, each period of free evolution, and the other events included in the candidate pulse sequence block in the order in which they appear and according to quantum-mechanics operator protocol. That is, the time evolution operator for each of the events in the candidate pulse sequence block is ordered from right to left in the order in which it appears in the candidate pulse sequence block.

Step 1312. The block unitary operator for the candidate pulse sequence block is represented in the toggling frame, as defined by a frame rotating with an applied hard approximate nπ pulse, by ordering the unitary operators for each hard approximate nπ pulse, each period of free evolution, and any other events included in the candidate pulse sequence block in the order in which they appear and according to quantum-mechanics operator protocol. The toggling frame is a frame rotating with the hard approximate nπ pulse. Tables IA and IIA of Section 6.4.2 show in the fifth column the toggling frame Hamiltonian for each event in the exemplary pulse sequence blocks. As shown for these exemplary sequences, and would be appreciated by one of ordinary skill in the art, the Hamiltonian in the toggling frame for each event may introduce several terms that look like the effective magnetic field term.

Step 1314. The block unitary operator for the candidate pulse sequence block may be represented by a single time evolution operator using the Magnus expansion. The benefit of the Magnus expansion is that it allows the reduction of an ordered series of unitary operators to a single exponential as the time evolution operator. At this point the Magnus expansion yields single time evolution operator having an infinite summation of effective Hamiltonian terms in its exponential.

Step 1316. In this step, the leading effective magnetic field terms in the exponent of the single time evolution operator are used to reduce the full Magnus expansion to obtain a simplified time evolution operator that represents the block unitary operator for the candidate pulse sequence block. In a preferred embodiment, the zeroth order and the first order terms in the Magnus expansion are retained. In a more preferred embodiment, only some of the zeroth order and the first order terms in the Magnus expansion are retained.

Step 1318. The action of the candidate pulse sequence block on a plurality of spin species is ascertained by examining the motion that the simplified time evolution operator representing the block unitary operator would cause the spin species to undergo. As explained below in Section 6.4, expected motion of the spin species can be ascertained by the form of the effective magnetic field term in the simplified time evolution operator.

Step 1320. In order to ascertain whether the candidate pulse sequence block causes the desired coherence control over the spin species, the action of the candidate pulse sequence block on the spin species is evaluated based on the type of motion that the simplified time evolution operator derived in step 1316 would cause the spin species to execute. In preferred embodiments, the simplified time evolution operator would cause the spin species to execute an amount of reverse evolution to that caused by the dipolar coupling term and/or one or more contributions to the Zeeman term during periods of free evolution. In some embodiments, the motion that the simplified time evolution operator for the candidate pulse sequence block would ascribe to the spin species is ascertained through computer simulations. In some embodiments, the action of the candidate pulse sequence block on the spin species may be verified by applying the candidate pulse sequence block to the spin species in an NMR measurement on a sample containing the spin species, and analyzing the signals from measurements on the sample in view of the simplified time evolution operator derived for the candidate pulse sequence block.

Step 1322. If the result from step 1320 is that the candidate pulse sequence block does not exercise the desired coherence control over the spin species, then the candidate pulse sequence block is modified. In preferred embodiments, the candidate pulse sequence block is modified in a manner that would cause the candidate pulse sequence block to exercise the desired form or degree of coherence control over the spin species. In preferred embodiments, one or more of the pulse sequence blocks or pulse sequences disclosed in Section 6.3, 6.4, or 7 herein, or others pulse sequences known in the art, such as the CPMG or magic sandwich sequence, may be added to the candidate pulse sequence block to cause the modified candidate pulse sequence block to exert the desired coherence control over the spin species, given that the coherence control of these sequences over the spin species has been shown herein. In other embodiments, the candidate pulse sequence block may be modified by adding one or more hard approximate nπ pulses, one or more periods of free evolution, or other events, such as a π/2 rotation, a 2π rotation, or a gradient field, to the ordered sequence of the candidate pulse sequence block. The disclosure herein provides the effective magnetic field term(s) that would be introduced into the modified candidate pulse sequence by any additional hard approximate nπ pulse or period of free evolution.

Step 1324. If the result from step 1320 is that the candidate pulse sequence block does exercise the desired coherence control over the spin species, then the candidate pulse sequence block is retained.

In another embodiment of the method shown in FIG. 13C, steps 1340-1352 are performed for creating and evaluating a candidate pulse sequence block for controlling the coherence of the magnetic resonance signals from the spin species, as discussed below. Steps 1340-1352 may also be followed for creating and evaluating a candidate sequence block for controlling the coherence of the resonance signals from pseudospin species.

Step 1340. A candidate pulse sequence block is created by arranging a plurality of events, including at least two hard approximate nπ pulses and at least one period of free evolution in an ordered sequence, where n is a positive odd integer, and the value of n may differ for each hard approximate nπ pulse. The candidate pulse sequence block may be created in consideration of an intended coherence control. For example, a pulse sequence block may be created to cause an amount of control over the influence of dephasing due to the dipolar coupling term or one or more of the terms that contribute to dephasing in the Zeeman term (such as the varying local fields). In addition, the candidate pulse sequence may contain one or more π/2 pulses, one or more 2π pulses, or one or more of the novel pulse sequences disclosed herein whose control over the coherence of the spin species has been demonstrated.

Step 1342. The block unitary operator for the candidate pulse sequence block is represented in the toggling frame, as defined by a frame rotating with an applied hard approximate nπ pulse, by ordering the unitary operators for each hard approximate nπ pulse, each period of free evolution, and any other events included in the candidate pulse sequence block in the order in which they appear and according to quantum-mechanics operator protocol. Tables IA and IIA of Section 6.4.2 show in the fifth column the toggling frame Hamiltonian for each event in the exemplary pulse sequence blocks. As shown for these exemplary sequences, and would be appreciated by one of ordinary skill in the art, the Hamiltonian in the toggling frame for each event may introduce several terms that look like the effective magnetic field term.

Step 1344. The leading effective magnetic field terms in the exponent of the single time evolution operator are used to reduce the full Magnus expansion to obtain a simplified time evolution operator that represents the block unitary operator for the candidate pulse sequence block. In a preferred embodiment, only the first order and second order effective magnetic field terms in the Magnus expansion are retained.

Step 1346. The action of the candidate pulse sequence block on a plurality of spin species is ascertained by examining the motion that the simplified time evolution operator representing the block unitary operator would cause the spin species to undergo. As explained below in Section 6.4, expected motion of the spin species can be ascertained by the form of the effective magnetic field term in the simplified time evolution operator.

Step 1348. In order to ascertain whether the candidate pulse sequence block causes the desired coherence control over the spin species, the action of the candidate pulse sequence block on the spin species is evaluated based on the type of motion that the simplified time evolution operator derived in step 1344 would cause the spin species to execute. In preferred embodiments, the simplified time evolution operator would cause the spin species to execute an amount of reverse evolution to that caused by the dipolar coupling term and/or one or more contributions to the Zeeman term during periods of free evolution. In some embodiments, the motion that the simplified time evolution operator for the candidate pulse sequence block would ascribe to the spin species is ascertained through computer simulations. In some embodiments, the action of the candidate pulse sequence block on the spin species may be verified by applying the candidate pulse sequence block to the spin species in an NMR measurement on a sample containing the spin species, and analyzing the signals from measurements on the sample in view of the simplified time evolution operator derived for the candidate pulse sequence block.

Step 1350. If the result from step 1348 is that the candidate pulse sequence block does not exercise the desired coherence control over the spin species, then the candidate pulse sequence block is modified. In preferred embodiments, the candidate pulse sequence block is modified in a manner that would cause the candidate pulse sequence block to exercise the desired form or degree of coherence control over the spin species. In preferred embodiments, one or more of the pulse sequence blocks or pulse sequences disclosed in Section 6.3, 6.4, or 7 herein, or others pulse sequences known in the art, such as the CPMG or magic sandwich sequence, may be added to the candidate pulse sequence block to cause the modified candidate pulse sequence block to exert the desired coherence control over the spin species, given that the coherence control of these sequences over the spin species has been shown herein. In other embodiments, the candidate pulse sequence block may be modified by adding one or more hard approximate nπ pulses, one or more periods of free evolution, or other events, such as a π/2 rotation, a 2π rotation, or a gradient field, to the ordered sequence of the candidate pulse sequence block. The disclosure herein provides the effective magnetic field term(s) that would be introduced into the modified candidate pulse sequence by any additional hard approximate nπ pulse or period of free evolution.

Step 1352. If the result from step 1348 is that the candidate pulse sequence block does exercise the desired coherence control over the spin species, then the candidate pulse sequence block is retained.

The steps 1402-1416 in a method for creating and evaluating a candidate pulse sequence for controlling the coherence of the magnetic resonance signals from the spin species are shown in FIG. 14, and discussed below. It should be noted that steps 1402-1416 may also be followed for creating and evaluating a candidate sequence block for controlling the coherence of the resonance signals from pseudospin species.

Step 1402. A candidate pulse sequence is created by arranging at least two pulse sequence blocks in an order, and optionally including one or more periods of free evolution or other additional events. The candidate pulse sequence may include one or more of the novel pulse sequences disclosed herein whose control over the coherence of the spin species has been demonstrated. The candidate pulse sequence may include at least one other hard approximate nπ pulses, and/or at least one other period of free evolution. The candidate pulse sequence may be created in consideration of an intended coherence control. For example, a pulse sequence may be created to cause an amount of control over the influence of dephasing due to the dipolar coupling term or one or more of the terms that contribute to dephasing in the Zeeman term (such as the varying local fields). In addition, the candidate pulse sequence may contain one or more π/2 pulses, one or more 2π pulses, or one or more pulse sequences known in the art, such as the CPMG or magic sandwich echo sequence.

Step 1404. Each of the pulse sequence blocks of the candidate pulse sequence is represented by its respective block unitary operator. If the candidate pulse sequence contains one or more of the novel pulse sequence blocks disclosed herein, then the block unitary operator for that novel pulse sequence block is used. If one of the pulse sequences in the candidate pulse sequence was derived according to the methods disclosed above and illustrated in FIGS. 13A-13C, then the block unitary operator for that pulse sequence block derived according to the methods disclosed above is used. If one or more pulse sequences known in the art, such as the CPMG or magic sandwich echo sequence is used, then the block unitary operator for that sequence, which may be disclosed herein or may be derived according to the method disclosed in FIGS. 13A-13C, is used.

Step 1406. If one or more free evolution periods or other additional events are included in the candidate pulse sequence, the unitary operator for each such period of free evolution or event is represent by the procedure of blocks 1306 or 1308 in FIG. 13A.

Step 1408. A composite unitary operator representing the candidate pulse sequence is formed by ordering the respective block unitary operator (represented by its respective simplified time evolution operator) for each pulse sequence block, the respective unitary operator for any period of free evolution (if included), and the respective unitary operators for any other events (if included), in the order in which they appear in the candidate pulse sequence and according to quantum mechanics operator protocol.

Step 1410. The action of the candidate pulse sequence on a plurality of spin species is ascertained by examining the motion that the composite unitary operator would cause the spin species to undergo.

Step 1412. In order to ascertain whether the candidate pulse sequence causes the desired coherence control over the spin species, the action of the candidate pulse sequence on the spin species is evaluated based on the type of motion that the simplified time evolution operator derived in step 1408 would cause the spin species to execute. In preferred embodiments, the composite unitary operator would cause the spin species to execute an amount of reverse evolution to that caused by the dipolar coupling term and/or one or more contributions to the Zeeman term during a period of free evolution. In some embodiments, the motion that the composite unitary operator for the candidate pulse sequence would ascribe to the spin species is ascertained through computer simulations. In some embodiments, the action of the candidate pulse sequence on the spin species may be verified by applying the candidate pulse sequence to the spin species in an NMR measurement on a sample containing the spin species, and analyzing the signals from measurements on the sample in view of the composite unitary operator derived for the candidate pulse sequence.

Step 1414. If the result from step 1412 is that the candidate pulse sequence does not exercise the desired coherence control over the spin species, then the candidate pulse sequence is modified. In preferred embodiments, the candidate pulse sequence is modified in a manner that would cause the candidate pulse sequence to exercise the desired form or degree of coherence control over the spin species. In preferred embodiments, one or more of the pulse sequence blocks or pulse sequences disclosed in Section 6.3, 6.4, or 7 herein, or others pulse sequences known in the art, such as the CPMG or magic sandwich sequence, may be added to the candidate pulse sequence to cause the modified candidate pulse sequence block to exert the desired coherence control over the spin species, given that the coherence control of these sequences over the spin species has been shown herein. In other embodiments, the candidate pulse sequence may be modified by adding one or more hard approximate rπ pulses, one or more periods of free evolution, or other events, such as a π/2 rotation, a 2π rotation, or a gradient field, to the ordered sequence of the candidate pulse sequence. The disclosure herein provides the effective magnetic field term(s) that would be introduced into the modified candidate pulse sequence by any additional hard approximate nit pulse or period of free evolution.

Step 1416. If the result from step 1414 is that the candidate pulse sequence does exercise the desired coherence control over the spin species, then the candidate pulse sequence is retained.

In a specific embodiment, a method of controlling coherence of a magnetic resonance signal of a sample comprising a plurality of spin species is provided, the method comprising applying an external magnetic field in a first direction, applying a pulse sequence comprising a plurality of approximate π pulses in at least one direction approximately perpendicular to the external magnetic field, the approximate π pulses having respective durations, the approximate π pulses separated by periods of free evolution having respective durations. The durations of the approximate π pulses and the durations of the periods of free evolution are selected so as to control coherence in the magnetic resonance signal through an effect of a quadratic effective-field term that appears in the Hamiltonian due to the hard π pulses. The methods described in FIGS. 13A-13C and FIG. 14, and discussed in Section 6.3 and 6.4, may be used to select the durations of the approximate π pulses and the durations of the periods of free evolution for achieving the desired coherence control.

In another specific embodiment, a method of controlling coherence of a magnetic resonance signal of a sample comprising a plurality of spin species is provided, the method comprising applying an external magnetic field in a first direction, applying a pulse sequence comprising a plurality of approximate π pulses in at least one direction approximately perpendicular to the external magnetic field, the approximate π pulses having respective durations, the approximate π pulses separated by periods of free evolution having respective durations. The durations of the approximate π pulses and the durations of the periods of free evolution are selected so as to control coherence in the magnetic resonance signal through an effect of a linear effective-field term that appears in the Hamiltonian due to the hard π pulses. The methods described in FIGS. 13A-13C and FIG. 14, and discussed in Section 6.3 and 6.4, may be used to select the durations of the approximate π pulses and the durations of the periods of free evolution for achieving the desired coherence control.

### 6.3 LIMITATIONS OF THE DELTA-FUNCTION APPROXIMATION

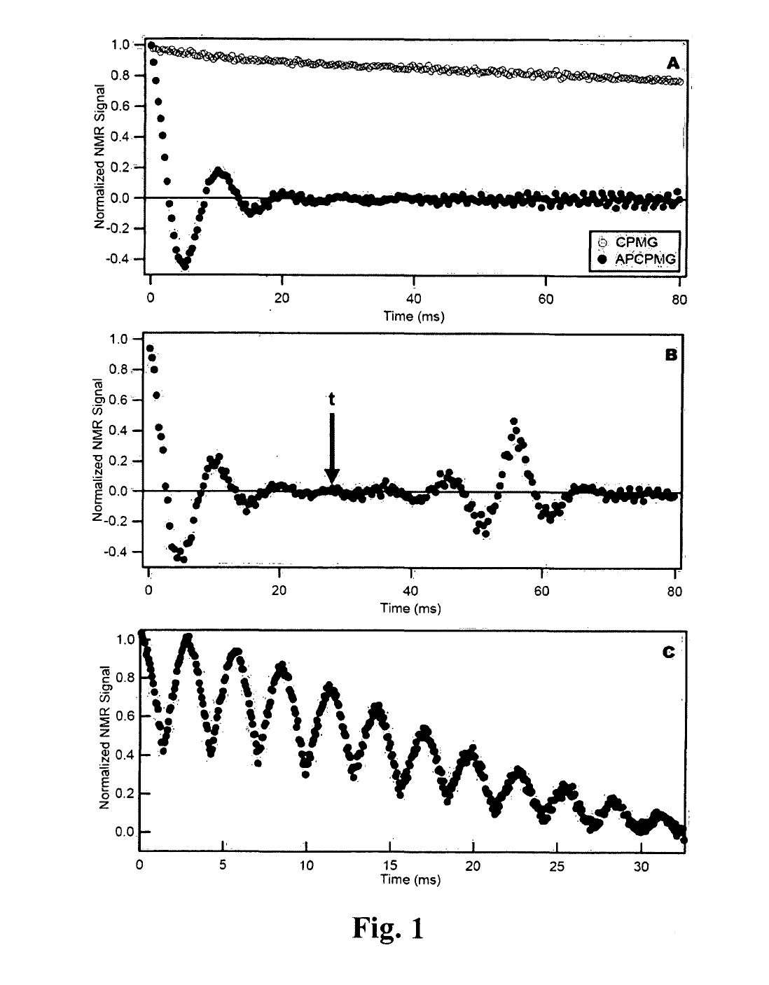

The novel pulse sequences disclosed herein result from the exploitation of the surprising discovery by the inventors that the commonly used delta approximation breaks down for pulse sequences comprising many hard 180° (π) pulses. Under a delta-function pulse approximation, application of repeated pulse blocks in the CPMG (90_{X}-{Y,Y}^{N}) and APCPMG (90_{X}-{−Y,Y}^{N}) sequences are expected to cause the spin species to exhibit the same behavior, and governed by a Hamiltonian H_{{±Y,Y}}^{delta}=H_{zz} (discussed in Section 6.4.2 below). However, in FIG. 1A, which shows the results of measurements made to compare these two sequences, it can be seen that while the CPMG sequence produced a long-lived train of spin echoes, while the train of spin echoes for APCPMG quickly decayed to zero. While this difference had previously been observed, it had commonly been attributed to misadjusted pulses and a sensitivity to pulse error in the APCMPG sequence.

To understand this dramatic difference between CPMG and APCPMG, and thereby the limitations of the delta-function approximation, Coherent Averaging Theory (discussed in Section 6.4.2 below) was applied to the repeating block {±Y, Y}, with 180° pulses of duration tₚ about the +Y or −Y axis and cycle time t_{c}=4τ+2tₚ. As explained in Section 6.4.2, in the hard-π-pulse, short t_{c} regime used with solids, the {Y,Y} block (CPMG) has H̅_{{Y,Y}}⁽⁰⁾=αH_{ZZ}−βH_{yy}, while the {−Y,Y} block (APCPMG) has a slightly different form: H̅_{{-Y,Y}}⁽⁰⁾= H̅_{{Y,Y}}⁽⁰⁾−λΩ_{z}^{net}Iₓ_{_{T}}, where

$$α = \frac{4 τ}{{t}_{c}} , β = \frac{{t}_{p}}{{t}_{c}} , λ = \frac{4 {t}_{p}}{π {t}_{c}} ,$$

and t_{c} is the cycle time.

The extra effective magnetic field term −λΩ_{z}^{net}Iₓ_{_{T}} that was discovered was analogized to a constant field in the X-direction, which, when acting alone, causes the spin species to nutate in the Y-Z plane (in a direction taken to be clockwise (CW)). Thus, this term is appropriately called an “effective magnetic field” or “effective transverse field.” Variation in Ω_{Z}^{net} values across the macroscopic sample leads to a spread in precession angles under the action of −λΩ_{z}^{net}Iₓ_{_{T}}, which causes the observed signal decay. In the well-known free induction decay FID), T*₂; arises from a spread in Ω_{z}^{net} of the original Zeeman Hamiltonian. The rapid decay of the spin echoes produced by APCPMG (90_{X}-{−Y,Y}^{N}) (FIG. 1A), therefore, can be thought of as an “FID of the echo train” due to the effective magnetic field.

To undo this T₂*-like decay, a single 180_{Y} pulse was inserted into the APCPMG sequence, forming, in accordance with certain embodiments of the present invention, the novel sequence 90_{X}-{−Y,Y}^{N1}-180_{Y}-{−Y,Y}^{N2}, which produces a striking second resonance signal, an “echo of the echo train” (FIG. 1B). N1 and N2 are integers, and represent the number of times the first and second repeating blocks are repeated, respectively. This sequence is discussed in more detail in Sections 6.4.1 and 7.1.1 below. The echo of the echo train is produced as follows: the dephasing caused by −λΩ_{z}^{net}Iₓ_{_{T}} (CW precession) over a time N₁ t_{c} is followed, after the 180_{Y} pulse, by a counter-clockwise (CCW) precession caused by +λΩ_{z}^{net}Iₓ_{_{T}} a time N₂ t_{c} (since the inserted 180_{Y} rotation changes the sign of the effective magnetic field term during interval N₂ t_{c}). This rephasing leads to the echo of the echo train when N₂=N₁. If a single flip-180_{X} is used instead, no echo of the echo train is observed, which is accounted for by the form of the effective magnetic field, because a perfect rotation along the x-axis does not change the sign of the term −λΩ_{z}^{net}Iₓ_{_{T}}. Thus, these measurements confirmed that the block unitary operator for CPMG and APCPMG, derived according to the methods of the invention, accounts for the observed differences in the resonance signal behavior for these two sequences. These measurements also demonstrated that the delta-function approximation breaks down in the hard π pulse regime, and the delta-function approximation does not explain the motion of the spin species during or “inside” the π pulses.

### 6.4 EXEMPLARY EMBODIMENTS

6.4.1 Exemplary building block sequence

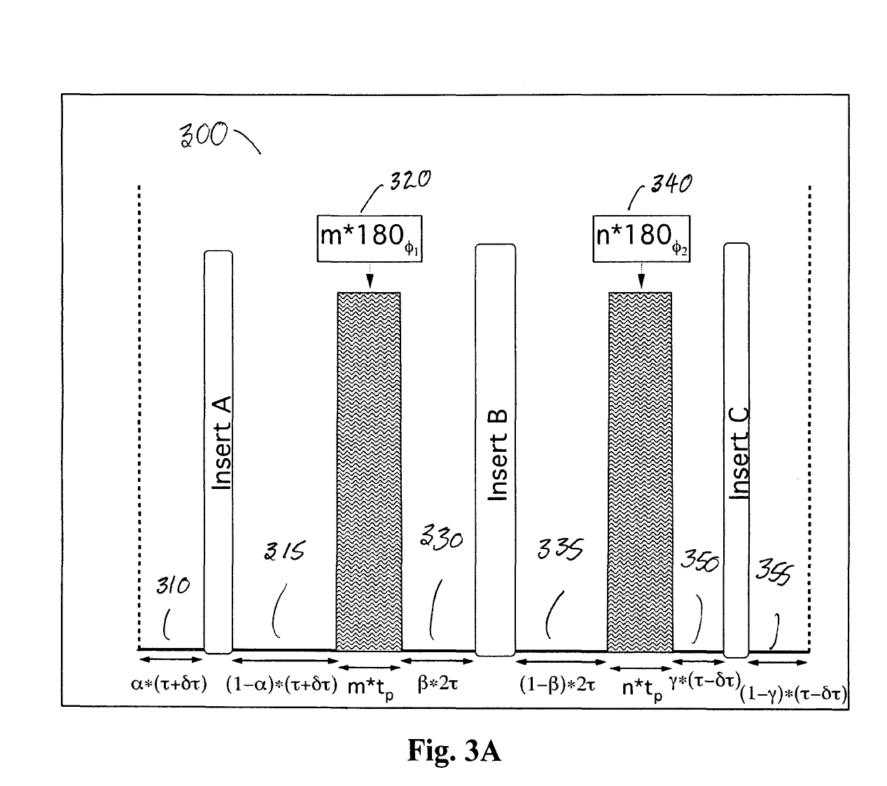

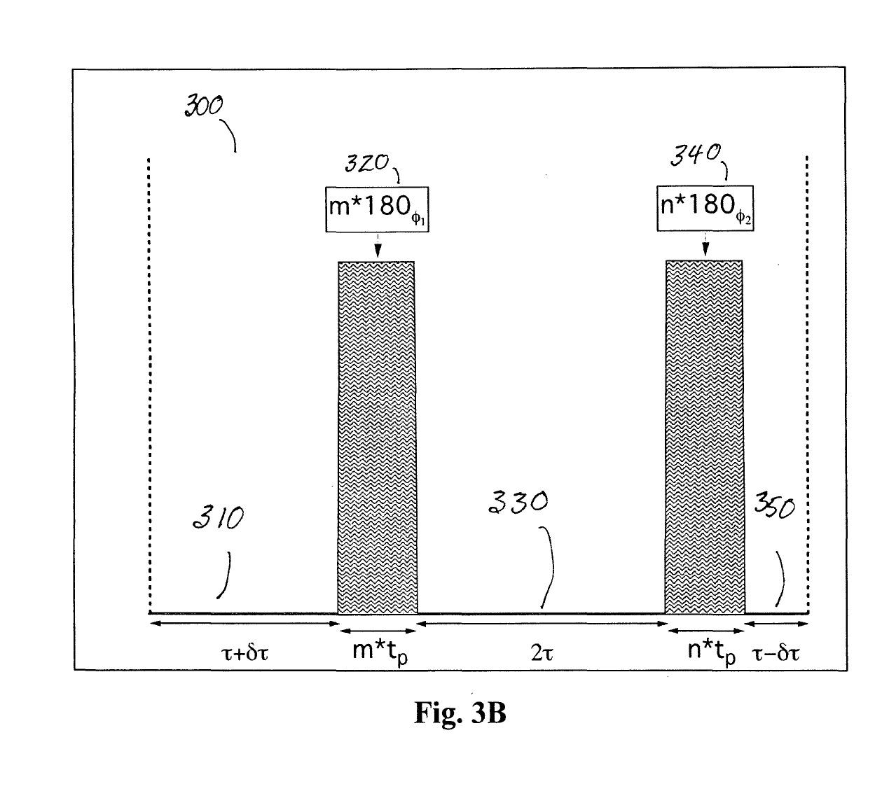

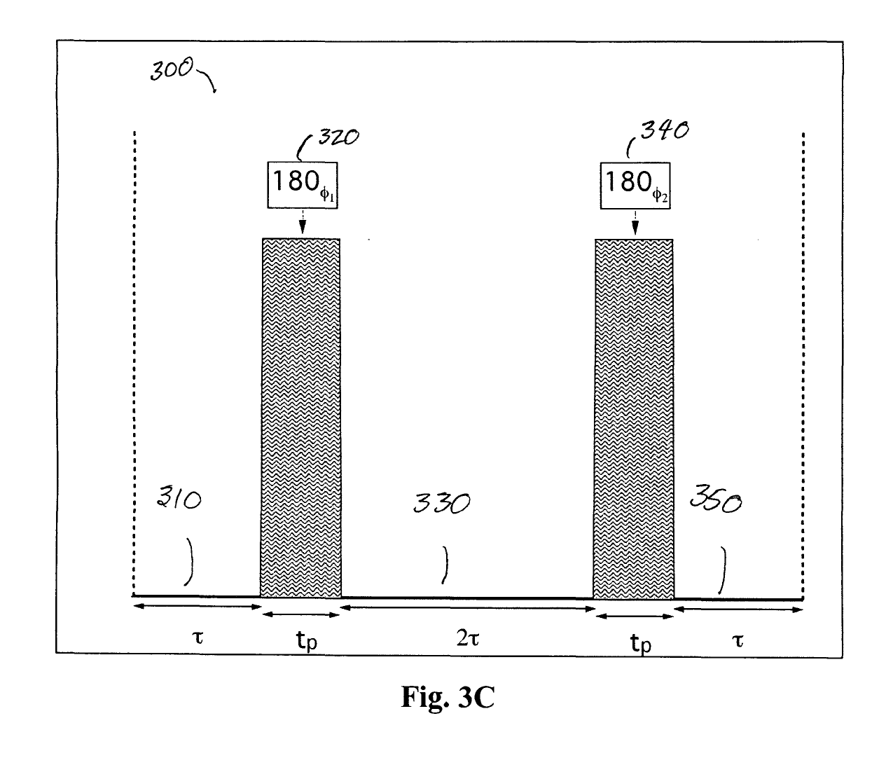

FIG. 3A illustrates a general building block sequence 300 in accordance with certain exemplary embodiments according to the methods discussed in Section 6.2 above. Building-block sequence 300 comprises, in the following order, a free-evolution period 305 of duration α(τ+δτ), an optional insert A, a free-evolution period 315 of duration (1−α)(τ+δτ), a mπ (i.e., m times 180) rotation 320 about the φ₁ axis having a duration m*tₚ, a free-evolution period 330 of duration β(2τ), an optional insert B, a free-evolution period 335 of duration (1−β)(2τ), an n*180 (nπ) rotation about the φ₂ axis, a free-evolution period 350 of duration γ(τ−δτ), an option insert C, and a free-evolution period of duration (1−γ)(τ−δτ). Optional inserts A, B, and C are such that sequence 300 is a complete cycle as considered under the average Hamiltonian theory (AHT). For example, in certain embodiments, each optional insert is itself a complete cycle (e.g., a 360 rotation or four 90 rotations), a copy of sequence 300 itself, or a period of free evolution. In other embodiments, optional inserts A, B, and/or C are partial cycles, but this constrains the pulses that can be used in order to ensure that sequence 300 remains a complete cycle according to AHT.

Sequence 300 can be conveniently expressed as α(τ+δτ)-A-(1−α)(τ+δτ)-m180 _{φ}_{₁}-β(2τ)-B-(1−β)(2τ)-n180_{φ}_{₂}-γ(τ−δτ)-C-(1−γ)(τ−δτ), wherein 0≦α, β, γ≦1, |δτ|≦τ, cycle time t_{c}=4τ+mtₚ+ntₚ+t_{A}+t_{B}+t_{C}, where t_{A}, t_{B}, and t_{C} are the times for optional inserts A, B, and C, respectively, and are equal to zero when the corresponding option insert is not used; φ₁ can be ±X or ±Y and φ₂ can be ±X or ±Y, where the selection of X or Y is the same for both φ₁ and φ₂, but the signs of φ₁ and φ₂ are chosen independently.

One exemplary form of a sequence having the form of sequence 300 is (τ-180_{φ}_{₁}-τ-360_{φ}_{₃}-τ-180_{φ}_{₂}-τ), where the parameters of sequence 300 have the following values: α=1, δτ=0, A=no optional insert, m=1, β=1/2, B=perform 360_{φ}_{₃}, n=1, γ=1, C=no optional insert). A second exemplary form of a sequence having the form of sequence 300 is (180_{φ}_{₁}-2τ-180_{φ}_{₂}-2τ), where the parameters of sequence 300 have the following values: α=0, δτ=−τ, A=no optional insert, m=1, β=1, B=no optional insert, n=1, γ=1, C=no optional insert). Other embodiments are discussed below.

A more specific form of building-block sequence 300 in accordance with some embodiments is illustrated in FIG. 3B. FIG. 3B shows building-block sequence 300 with α=β=γ=1 with no optional inserts A, B, and C.

A still more specific form of building block sequence 300 used with other embodiments is illustrated in FIG. 3C. FIG. 3C shows building-block sequence 300 as in FIG. 3B with the additional constraint that δτ=0 and m=n=1. The preferable building block of FIG. 3C is conveniently referred to by the notation {φ₁,φ₂} which represents the sequence (τ-180_{φ}_{₁}-2τ-180_{φ}_{₂}-τ), where 180° (π) rotations are applied about the φ₁ and φ₂-axes and the spins are allowed to evolve freely for periods of free evolution having duration τ or 2τ. The expected behavior of {φ₁, φ₂} building blocks is explained in Section 6.4.2 below. Many of the embodiments described herein use a building block of the form {φ₁,φ₂}; however, armed with the teachings herein, it is understandable to one of ordinary skill in the art how to generalize the exemplary sequences to use the more general building block shown in FIG. 3A.

6.4.2 Coherent Averaging

Using Coherent Averaging Theory, the behavior of building-block sequence 300 having the form of FIG. 3C can be determined. As explained in Section 6.4.1 above, φ₁ can be ±X or ±Y and φ₂ can be ±X or ±Y, where the selection of X or Y is the same for both φ₁ and φ₂. Starting with the four possible choices when Y is selected,

(a,b)={(+1,+1), (+1,−1), (−1,+1), or (−1,−1)}.

A detailed Coherent Averaging analysis of the repeating block {aY,bY}(which represents τ-180_{aY}-2τ-180_{bY}- [symbol] ) has been given elsewhere by the inventors See Li et al., The Intrinsic Origin of Spin Echoes in Dipolar Solids Generated by Strong Pi Pulses, Phys. Rev. B 77:214306 (2008), which is incorporated herein by reference. The main steps of the analysis are as follows. The unitary time evolution operator for the repeating block {aY,bY} is

$$\begin{matrix}{U}_{{t}_{c}}^{\{ aY , bY \}} = {e}^{- \frac{i}{ℏ} ( {H}_{int} ) τ} {e}^{- \frac{i}{ℏ} ( {H}_{{P}_{bY}} + {H}_{int} ) {t}_{p}} {e}^{- \frac{i}{ℏ} ( {H}_{int} ) 2 τ} {e}^{- \frac{i}{ℏ} ( {H}_{{P}_{aY}} + {H}_{int} ) {t}_{p}} \\ {e}^{- \frac{i}{ℏ} ( {H}_{int} ) τ} \\ = {e}^{- \frac{i}{ℏ} ( {\sum }_{i = 0}^{∞} {\overline{H}}_{\{ aY , bY \}}^{( i )} ) {t}_{c}} ,\end{matrix}$$

where the duration tₚ of each π pulse is adjusted so that ω₁tₚ=π, the cycle time t_{c}=4τ+2tₚ, and the Magnus expansion yields the H̅⁽ⁱ⁾ terms of the average Hamiltonian. For the conditions under which imaging of solids would be performed (i.e., strong π pulses, and short t_{c}), keeping just the first two terms

$${U}_{{t}_{c}}^{\{ aY , bY \}} ≅ {e}^{- \frac{i}{ℏ} ( {\overline{H}}_{\{ aY , bY \}}^{( 0 )} + {\overline{H}}_{\{ aY , bY \}}^{( 1 )} ) {t}_{c}}$$

appeared to be a very good approximation to the action of the {aY,bY} block. These terms are given by

$${\overline{H}}^{( 0 )} = \frac{1}{{t}_{c}} {\int }_{0}^{{t}_{c}} d t \tilde{H} ( t ) and$$

$${\overline{H}}^{( 1 )} = - \frac{i}{2 {t}_{c} ℏ} {\int }_{0}^{{t}_{c}} d {t}_{2} {\int }_{0}^{{t}_{2}} d {t}_{1} [ \tilde{H} ( {t}_{2} ) , \tilde{H} ( {t}_{1} ) ] ,$$

where \tilde{H}(t) is the effective Hamiltonian in the interaction frame of the pulses (i.e., the “toggling frame”). During the five events that make up the cycle time of the {aY,bY} block, \tilde{H}(t) has the form given in Table IA.

TABLE IA

| i | Tᵢ | Hₑₓₜ | Hᵢₙₜ | \tilde{H}(tᵢ) |
|---|---|---|---|---|
| 1 | τ | 0 | H_{Z} + H_{zz} | +H_{Z} + H_{zz} |
| 2 | tₚ | −aω₁I_{y}_{_{T}} | H_{Z} + H_{zz} | $\begin{matrix}+ {Ω}_{z}^{net} ( {I}_{{z}_{T}} {C}_{a θ} + {I}_{{x}_{T}} {S}_{a θ} ) - \\ \frac{1}{2} {H}_{yy} + {H}_{y}^{S} {C}_{2 a θ} + {H}_{y}^{A} {S}_{2 a θ}\end{matrix}$ |
| 3 | 2τ | 0 | H_{Z} + H_{zz} | −H_{Z} + H_{zz} |
| 4 | tₚ | −bω₁I_{y}_{_{T}} | H_{Z} + H_{zz} | $\begin{matrix}- {Ω}_{z}^{net} ( {I}_{{z}_{T}} {C}_{b θ} + {I}_{{x}_{T}} {S}_{b θ} ) - \\ \frac{1}{2} {H}_{yy} + {H}_{y}^{S} {C}_{2 b θ} + {H}_{y}^{A} {S}_{2 b θ}\end{matrix}$ |
| 5 | τ | 0 | H_{Z} + H_{zz} | +H_{Z} + H_{zz} |

Column 2 lists the durations Tᵢ of the i=1, . . . , 5 events of the {aY,bY} block, where signs of the π pulse phases can four possible states: (a,b)={(+1,+1), (+1,−1), (−1,+1), or (−1,−1)}. Column 3 shows the external rf pulse Hamiltonian in the rotating frame. Column 4 shows the internal Hamiltonian in the rotating frame. Column 5 lists the toggling frame Hamiltonian. As defined,

$${H}_{Z} = {Ω}_{z}^{net} {I}_{{z}_{T}} . , {H}_{y}^{S} = \frac{3}{2} {\sum }_{i > j}^{N} {B}_{ij} ( {I}_{{z}_{i}} {I}_{{z}_{j}} - {I}_{{x}_{i}} {I}_{{x}_{j}} ) , \\ {H}_{y}^{A} = \frac{3}{2} {\sum }_{i > j}^{N} {B}_{ij} ( {I}_{{x}_{i}} {I}_{{z}_{j}} + {I}_{{z}_{i}} {I}_{{x}_{j}} ) , \\ and {H}_{σσ} = {\sum }_{i > j}^{N} {B}_{ij} ( 3 {I}_{{σ}_{i}} {I}_{{σ}_{j}} - {\vec{I}}_{i} \cdot {\vec{I}}_{j} ) ,$$

for σ=x, y, or z. Moreover,

$${B}_{ij} ≡ \frac{1}{2} \frac{{γ}^{2} {ℏ}^{2}}{{\vert {\vec{r}}_{ij} \vert}^{3}} ( 1 - 3 {cos}^{2} {θ}_{ij} ) ,$$

where γ is the gyromagnetic ratio, and θᵢⱼ is the angle between and \vec{r}ᵢⱼ and \vec{B}ₑₓₜ∥ [symbol] In addition, C_{aθ}=Cos(aω₁t), C_{2aθ}=Cos(2aω₁t), S_{aθ}=Sin(aω₁t), and S_{2aθ}=Sin(2aω₁t), (and C_{bθ}=COS(bω₁t), etc.), where 0≦t≦Tᵢ.

Using \tilde{H}(t), the calculated H̅_{{aY,bY}}⁽⁰⁾ and H̅_{{aY,bY}}⁽¹⁾ corresponding to {aY,bY} are given in Table IIA.

TABLE IIA

| | {−(±Y), ±Y} | {±Y, ±Y} |
|---|---|---|
| H̅⁽⁰⁾ | αH_{zz} − βH_{yy} − (±λΩ_{z}^{net} Iₓ_{_{T}}) | αH_{zz} − βH_{yy} |
| H̅⁽¹⁾ | 0 | $\begin{matrix}\frac{- ( \pm i )}{2 {t}_{c} ℏ} \frac{{t}_{p}}{π} ( \begin{matrix}{t}_{p} [ {H}_{y}^{A} , {H}_{y}^{S} + {H}_{yy} ] + \\ ( 8 τ + 2 {t}_{p} ) [ {Ω}_{z}^{net} {I}_{{x}_{T}} , {Ω}_{z}^{net} {I}_{{z}_{T}} + {H}_{yy} ]\end{matrix} ) = \\ \frac{- ( \pm 1 ) {t}_{p} ( 8 τ + 2 {t}_{p} )}{2 {t}_{c} ℏ π} {( {Ω}_{z}^{net} )}^{2} {I}_{{y}_{T}} \pm {\overline{H}}_{\{ Y , Y \}}^{( 1 ) {,}_{non - {I}_{yT}}} = \\ - ( \pm 1 ) {( {κΩ}_{z}^{net} )}^{2} {I}_{{y}_{T}} \pm {\overline{H}}_{\{ Y , Y \}}^{( 1 ) {,}_{non - {I}_{yT}}}\end{matrix}$ |

The first two terms in the Magnus expansion for the repeating block {aY,bY}, where (a,b)={(+1,+1), (+1,−1), (−1,+1), or (−1,−1)}. As defined,

$$α = \frac{4 τ}{{t}_{c}} , β = \frac{{t}_{p}}{{t}_{c}} , λ = \frac{4 {t}_{p}}{π {t}_{c}} , and κ = \sqrt{\frac{{t}_{p} ( 8 τ + 2 {t}_{p} )}{2 {t}_{c} ℏπ}} .$$

Working through the same kind of treatment of the block {aX,bX} leads to the results presented in Tables IB and IIB.

TABLE IB

| i | Tᵢ | Hₑₓₜ | Hᵢₙₜ | \tilde{H}(tᵢ) |
|---|---|---|---|---|
| 1 | τ | 0 | H_{Z} + H_{zz} | +H_{Z} + H_{zz} |
| 2 | tₚ | −aω₁Iₓ_{_{T}} | H_{Z} + H_{zz} | $\begin{matrix}+ {Ω}_{z}^{net} ( {I}_{{z}_{T}} {C}_{a θ} - {I}_{{y}_{T}} {S}_{a θ} ) - \\ \frac{1}{2} {H}_{xx} + {H}_{x}^{S} {C}_{2 a θ} - {H}_{x}^{A} {S}_{2 a θ}\end{matrix}$ |
| 3 | 2τ | 0 | H_{Z} + H_{zz} | −H_{Z} + H_{zz} |
| 4 | tₚ | −bω₁Iₓ_{_{T}} | H_{Z} + H_{zz} | $\begin{matrix}- {Ω}_{z}^{net} ( {I}_{{z}_{T}} {C}_{b θ} - {I}_{{y}_{T}} {S}_{b θ} ) - \\ \frac{1}{2} {H}_{xx} + {H}_{x}^{S} {C}_{2 b θ} - {H}_{x}^{A} {S}_{2 b θ}\end{matrix}$ |
| 5 | τ | 0 | H_{Z} + H_{zz} | +H_{Z} + H_{zz} |

Column 2 lists the durations Tᵢ of the i=1, . . . , 5 events of the {aY,bY} block, where signs of the π pulse phases can four possible states: (a,b)={(+1,+1), (+1,−1), (−1,+1), or (−1,−1)}. Column 3 shows the external rf pulse Hamiltonian in the rotating frame. Column 4 shows the internal Hamiltonian in the rotating frame. Column 5 lists the toggling frame Hamiltonian. As defined,

$${H}_{Z} = {Ω}_{z}^{net} {I}_{{z}_{T}} , {H}_{x}^{S} = \frac{3}{2} {\sum }_{i > j}^{N} {B}_{ij} ( {I}_{{z}_{i}} {I}_{{z}_{j}} - {I}_{{y}_{i}} {I}_{{y}_{j}} ) , \\ {H}_{x}^{A} = \frac{3}{2} {\sum }_{i > j}^{N} {B}_{ij} ( {I}_{{y}_{i}} {I}_{{z}_{j}} + {I}_{{z}_{i}} {I}_{{y}_{j}} ) , \\ and {H}_{σσ} = {\sum }_{i > j}^{N} {B}_{ij} ( 3 {I}_{{σ}_{i}} {I}_{{σ}_{j}} - {\vec{I}}_{i} \cdot {\vec{I}}_{j} )$$

for σ=x, y, or z.

Moreover,

$${B}_{ij} ≡ \frac{1}{2} \frac{{γ}^{2} {ℏ}^{2}}{\vert {\vec{r}}_{ij} \vert} ( 1 - 3 {cos}^{2} {θ}_{ij} ) ,$$

where γ is the gyromagnetic ratio, and θᵢⱼ is the angle between and \vec{r}ᵢⱼ and \vec{B}ₑₓₜ∥ [symbol] In addition, C_{aθ}=COS(aω₁t), C_{2aθ}=Cos(2aω₁t), S_{aθ}=Sin(aω₁t), and S_{2aθ}=Sin(2aω₁t), (and C_{bθ}=Cos(bω₁t), etc.), where 0≦t≦Tᵢ.

TABLE IIB

| | {−(±X), ±X} | {±X, ±X} |
|---|---|---|
| H̅⁽⁰⁾ | αH_{zz} − βHₓₓ + (±λΩ_{z}^{net} I_{y}_{_{T}}) | αH_{zz} − βHₓₓ |
| H̅⁽¹⁾ | 0 | $\begin{matrix}\frac{- ( \pm i )}{2 {t}_{c} ℏ} \frac{{t}_{p}}{π} ( \begin{matrix}{t}_{p} [ {H}_{x}^{A} , {H}_{x}^{S} + {H}_{xx} ] + \\ ( 8 τ + 2 {t}_{p} ) [ {Ω}_{z}^{net} {I}_{{y}_{T}} , {Ω}_{z}^{net} {I}_{{z}_{T}} + {H}_{xx} ]\end{matrix} ) = \\ \frac{- ( \pm 1 ) {t}_{p} ( 8 τ + 2 {t}_{p} )}{2 {t}_{c} ℏ π} {( {Ω}_{z}^{net} )}^{2} {I}_{{x}_{T}} \pm {\overline{H}}_{\{ X , X \}}^{( 1 ) {,}_{non - {I}_{xT}}} = \\ - ( \pm 1 ) {( {κΩ}_{z}^{net} )}^{2} {I}_{{x}_{T}} \pm {\overline{H}}_{\{ X , X \}}^{( 1 ) {,}_{non - {I}_{xT}}}\end{matrix}$ |

The first two terms in the Magnus expansion for the repeating block {aX,bX}, where (a,b)={(+1,+1), (+1,−1), (−1,+1), or (−1,−1)}. As defined,

$$α = \frac{4 τ}{{t}_{c}} , β = \frac{{t}_{p}}{{t}_{c}} , λ = \frac{4 {t}_{p}}{π {t}_{c}} , and κ = \sqrt{\frac{{t}_{p} ( 8 τ + 2 {t}_{p} )}{2 {t}_{c} ℏπ}} .$$

6.4.3 Linear Effective Transverse Field

Section 6.3 above introduced the term −λΩ_{z}^{net}Iₓ_{_{T}} as a result of applying the repeating block {−Y,Y} in the APCPMG sequence. Section 6.4.2 above explained the appearance of this linear effective transverse field term using a Coherent Averaging Analysis. The term is a “linear” effective magnetic field term, because Iₓ_{_{T}} is linear in Ω_{z}^{net}, to be distinguished from the “quadratic” effective field discussed in Section 6.4.4 below. Some of the novel pulse sequences disclosed herein in accordance with certain embodiments of the present invention were constructed to take advantage of the linear effective magnetic field term −λΩ_{z}^{net}Iₓ_{_{T}}.

6.4.3.1 “Echo of the Echo Train”

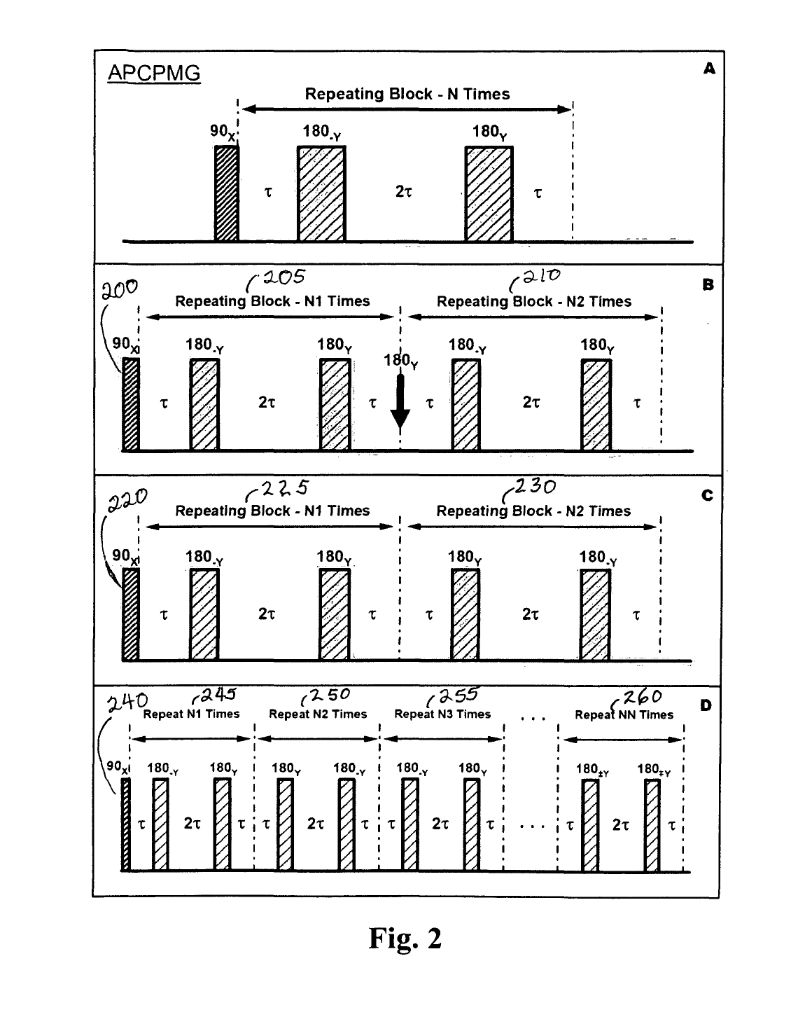

A novel pulse sequence 200, introduced in Section 6.3 above, is shown in FIG. 2B, while APCPMG is shown in FIG. 2A for comparison. Sequence 200 includes a single 180_{Y} pulse inserted into the APCPMG sequence between repeating blocks 205 and 210, and therefore has the form 90_{X}-{−Y,Y}^{N1}-180_{Y}-{−Y,Y}^{N2}, where N1 and N2 are integers, and represent the number of times to repeat the first and second repeating blocks respectively. As explained in Section 6.3 above, under the long-used delta-function approximation sequence 200 would behave the same as APCPMG, because the 180_{Y} pulse would not change the effect of the simple effective Hamiltonian H_{{±Y,Y}}^{delta}=H_{zz}. However, armed with the inventors' surprising discovery of the impact of the −λΩ_{z}^{net}Iₓ_{_{T}} term when repeating the {−Y,Y} block, the single 180_{Y} would be expected to—and did—reverse the direction of precession of the spin species. As seen in FIG. 1B, and described in more detail in Section 7.1.1, a measurement made using sequence 200 (FIG. 2B) produced a striking echo of the echo train. The effect of the 180_{Y} pulse followed by the Hamiltonian H̅_{{-Y,Y}}⁽⁰⁾ can be determined to be H̅₁₈₀_{_{Y}}_{-{-Y,Y}}⁽⁰⁾= H̅_{{Y,Y}}⁽⁰⁾+λΩ_{z}^{net}Iₓ_{_{T}}, (see Section 6.4.2). Thus, the dephasing caused by −λΩ_{z}^{net}Iₓ_{_{T}} (CW precession) during the first repeating block 205 in FIG. 2B over a time N₁t_{c} is followed by rephasing caused by +λΩ_{z}^{net}Iₓ_{_{T}} counter-clockwise (CCW) precession during the second repeating block 210 over a time N₂t_{c}. This rephasing leads to the echo of the echo train with a maximum occurring at a time when the second repeating block has been applied the same amount of times as the first repeating block (thus, the largest echo of the echo train will only appear if N₂>N₁). The echo train is characterized by echoes growing in magnitude as the number of repeating blocks applied approaches 2N₁, a maximum echo when the number of blocks applied equals 2N₁, and echoes of diminishing magnitude as additional blocks beyond 2N₁ are applied.

While sequence 200 (FIG. 2B) uses as building blocks the sequence 300 shown in FIG. 3C, with φ₁=−Y and φ₂=Y, it is apparent that the sequence can be generalized. In particular, sequences of the following form, of which sequence 200 is one, are contemplated: 90±_{X}-{(+ or −)±Y,(− or +)(±Y)}^{N1}-180±_{Y}-{(+ or −)±Y, (− or +) (±Y)}^{N2}. Here and elsewhere, unless otherwise specified, choosing the top (or bottom) sign of one “±” sign or “±” sign is a choice of the top (or bottom) sign for all such signs, e.g., choosing “+X” for the 90±_{X} pulse in the sequence above implies choosing (+ or −)(+Y) each repeating block. Similarly, here and elsewhere, unless otherwise specified, choosing the left (or right) sign of one instance of “(+ or −)” or “(− or +)” means choosing left (or right) sign for all such instances. Thus, choosing +(±Y) in the first block requires that the first and second blocks be {±Y,−(±Y)}. It is contemplated that in other embodiments, still more general sequences are used to achieve the effect of sequence 200, using sequence 300 of FIG. 3A as a building block, along with the knowledge gained from Section 6.4.2.

In still other embodiments of the invention, additional sequences are possible. FIG. 2C shows an example of such a sequence. Sequence 220 has the form 90_{X}-{−Y,Y}^{N1}-{Y,−Y}^{N2}, where N₁ and N₂ are integers greater than or equal to one and represent the number of times each of the respective repeating blocks is repeated. The results of a measurement made using N₁=200 and N₂=600 looked striking similar to the dataset depicted in FIG. 1B. Generally, an echo of the echo train is produced, wherein the echoes grow in magnitude until the number of applications of the second repeating block (i.e., N₂) approaches N₁, reach a maximum at the time that the number of applications of the second repeating block N₂ equals N₁, and decreasing in magnitude when the number of applications of the second repeating block N₂ is greater than N₁. Thus, it is preferable to have N₂≧N₁ and more preferable to have N₂>N₁.

Sequence 220 applies a similar control of coherence for similar reasons to sequence 200, as it also makes use of the λΩ_{z}^{net}Iₓ_{_{T}} term. In particular, as shown in Section 6.4.2, H̅_{{Y,-Y}}⁽⁰⁾= H̅_{{Y,Y}}⁽⁰⁾+λΩ_{z}^{net}Iₓ_{_{T}}. Thus, as before, the dephasing caused by −λΩ_{z}^{net}Iₓ_{_{T}} (CW precession) during the first repeating block 225 in FIG. 2C over a time N₁t_{c} is followed by counter-clockwise (CCW) precession caused by +λΩ_{z}^{net}Iₓ_{_{T}} during the second repeating block 230 in FIG. 2C for a period of N₂t_{c}. This rephasing leads to the echo of the echo train when N₂=N₁.

While sequence 220 (FIG. 2C) uses as building blocks the sequence 300 shown in FIG. 3C, with φ₁=−Y and φ₂=Y for the first repeated block 225, and φ₁=−Y and φ₂=Y for the second repeated block 230, it is apparent that the sequence can be generalized. For example, exemplary sequence 220 can be generalized to the following:

90_{±X}-{(+ or −)±Y, (− or +)(±Y)}^{N}-{(− or +)±Y,(+ or −)(±Y)}^{M},

where M and N are integers greater than or equal to 1, and M>N. It is contemplated that in other embodiments, still more general sequences are used to achieve the effect of sequence 220, using sequence 300 of FIG. 3A as a building block, along with the knowledge gained from Section 6.4.2.

FIG. 2D shows that the approach of FIG. 2C can be repeated, creating multiple echoes in the envelope of individual spin echo peaks, or a “CPMG of the echo train,” shown in FIG. 1C. Sequence 240 (FIG. 2D) has the form 90_{X}-{−Y,Y}^{N1}{Y,−Y}^{N2}{−Y,Y}^{N3}, . . . {Y,−Y}^{NN}, where N₁, N₂, . . . , N_{N} are integers greater than or equal to one and represent the number of times each of the respective repeating blocks is repeated. A measurement made using sequence 240 with twelve repeating blocks and N₁=10, N₂= . . . =N₁₂=20 provided the results shown FIG. 1C. For that selection of N₁, N₂, . . . , N₁₂, the peak echo occurs in the middle of each of the N₁ repeated block beginning with the N₂ repeated block. In general, such a pattern will occur for 2N₁=N₂= . . . =Nᵢ= . . . =N_{N}. Other values of N₁, N₂, . . . , N_{N} are contemplated. For example, in some embodiments, N₁=N₂= . . . =N_{N}; in that case, the peak echo would occur at the end of every other repeated block beginning, with the first peak echo occurring at the end of the N; repeated block, where i is an even integer greater than one.

Sequence 240 is analogous to the repeated-block-portion of sequence 220 (i.e., repeated blocks 225 and 230 of FIG. 2C) being repeated many times. The dephasing caused by −λΩ_{z}^{net}Iₓ_{_{T}} (CW precession) during the {−Y,Y} repeating blocks (e.g., blocks 245 and 255) in FIG. 2D is counteracted by counter-clockwise (CCW) precession caused by +λΩ_{z}^{net}Iₓ_{_{T}} during the {Y,−Y}repeating blocks (e.g., block 250) in FIG. 2D. As shown in FIG. 2D, the final repeating block 260 can have the form {−Y,Y} or {Y,−Y}. Just as sequence 220 can be generalized, sequence 240, which repeats the technique of sequence 220, can be generalized in the same fashion.

Using the expressions obtained in the discussion on Coherent Averaging in 6.4.2 above, the “echo of the echo train” sequences discussed so far in this section may be understood. The first sequence, 90_{X}-{−Y,Y}^{N1}-180_{Y}-{−Y,Y}^{N2} (sequence shown in FIG. 2B, effect shown in FIG. 1B) corresponds to the unitary operator U_{N}_{₂}ₜ_{_{c}}^{{-Y,Y}}U₁₈₀_{_{Y}}U_{N}_{₁}ₜ_{_{c}}^{{-Y,Y}U}₉₀_{_{X}}, which can be rewritten as

$${U}_{{180}_{Y}} {e}^{- \frac{i}{ℏ} ( {\overline{H}}_{\{ Y , Y \}}^{( 0 )} + {λΩ}_{z}^{net} {I}_{{x}_{T}} ) {N}_{2} {t}_{c}} {e}^{- \frac{i}{ℏ} ( {\overline{H}}_{\{ Y , Y \}}^{( 0 )} - {λΩ}_{z}^{net} {I}_{{x}_{T}} ) {N}_{1} {t}_{c}} {U}_{{90}_{X}}$$

if the “flip-180_{Y}” is treated as a pure rotation (i.e., U₁₈₀_{_{Y}}=e^{+i(π)I}^{_{yT}}). The second sequence, 90_{X}-{−Y,Y}^{N1}-{Y,−Y}^{N2} (sequence shown in FIG. 2C, effect similar to FIG. 1B), has

$${e}^{- \frac{i}{ℏ} ( {\overline{H}}_{\{ Y , Y \}}^{( 0 )} + {λΩ}_{z}^{net} {I}_{{x}_{T}} ) {N}_{2} {t}_{c}} {e}^{- \frac{i}{ℏ} ( {\overline{H}}_{\{ Y , Y \}}^{( 0 )} - {λΩ}_{z}^{net} {I}_{{x}_{T}} ) {N}_{1} {t}_{c}} {U}_{{90}_{X}}$$

where H̅_{{Y,-Y}}⁽⁰⁾= H̅_{{Y,Y}}⁽⁰⁾+λΩ_{z}^{net}Iₓ_{_{T}} was used. Thus, for the trace in FIG. 1B, the “FID of the echo train” caused by the CW precession due to −λΩ_{z}^{net}Iₓ_{_{T}} is followed by rephasing (i.e., CCW precession due to +λΩ_{z}^{net}Iₓ_{_{T}}) which results in an “echo of the echo train” when N₂=N₁. A technique well known in the art, referred to as the rotary echo (see I. Solomon, Phys. Rev. Lett. 2, 301 (1959)), also reverses an effective field along X, however, it is a spread in the applied pulse ω₁ that is responsible for the dephasing in the rotary echo technique. In the novel sequence disclosed herein, it is a spread in Ω_{z}^{net} rather than a spread in ω₁ that is responsible for the dephasing.

The treatment of the flip-180_{Y} as a delta-function pulse may seem to be inconsistent, because the effective transverse field exploited arises from the nonzero duration of the π pulses in {φ¹,φ₂} blocks. However, these corrections are small, and only manifest large effects after the coherent repetition of many {φ₁,φ₂} blocks. Therefore, treating the few 90° and 180° pulses outside of repeating block as delta-function rotations is a good approximation. Nonetheless, certain embodiments of the present invention perform a similar analysis on any initial or sandwich pulses, such as the single 90_{±X} of the sequences presently being discussed, as is performed on the plurality of 180_{±Y} pulses. This statement holds true for any sequences or embodiments of the invention discussed herein.

6.4.3.2 Controlling Zeeman and Dipolar Phase Wrapping

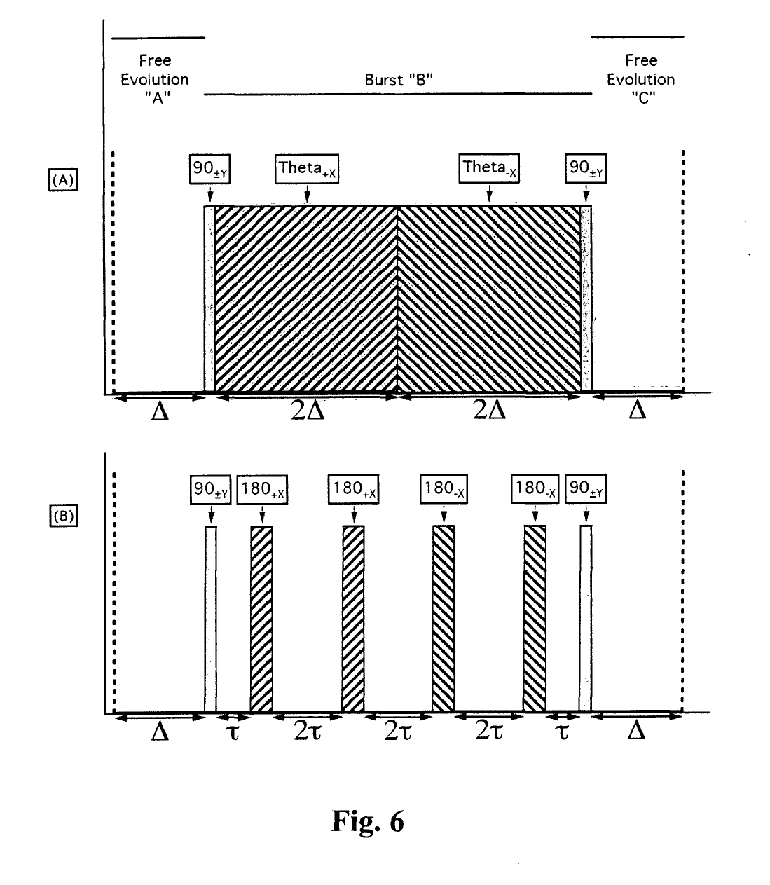

As discussed above, and demonstrated in FIG. 1C, sequence 240 successfully produces a series of echoes. However, the signal in FIG. 1C does decay, because the sign of the) dipolar-coupling part of H̅_{{-Y,Y}}⁽⁰⁾ (i.e., H̅_{{Y,Y}}⁽⁰⁾=αH_{zz}−βH_{yy}) is never reversed in sequence 240. In other embodiments of the invention, it would be preferable to prevent or reduce this decay using pulse sequences having a MSE-like effect. FIG. 6B shows an exemplary pulse sequence applicable to MRI/MRM which has an MSE-like effect. Using the pulse sequence of FIG. 6B, the gradients used for spatial encoding during MRI/MRM can be left on during the periods “A”, “B”, and “C” in FIG. 6A. Moreover, gradients can also be ramped up and down over longer timescales, provided that H_{z} is roughly constant during each burst “B” in FIG. 6A, enabling many liquid-like imaging strategies. In some of those embodiments, an effective magnetic field term λΩ_{z}^{net}I_{y}_{_{T}} in H̅_{{-X,X}}⁽⁰⁾ can be used to play the role of rotating

$${H}_{zz} \to - \frac{1}{2} {H}_{yy} to - \frac{1}{2} {H}_{zz} .$$

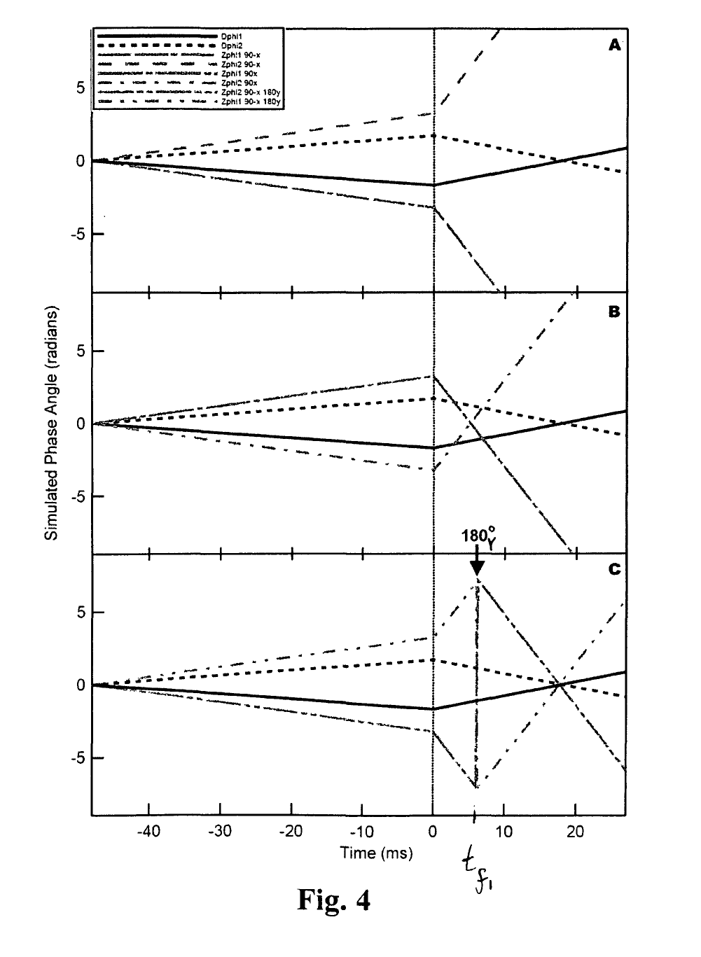

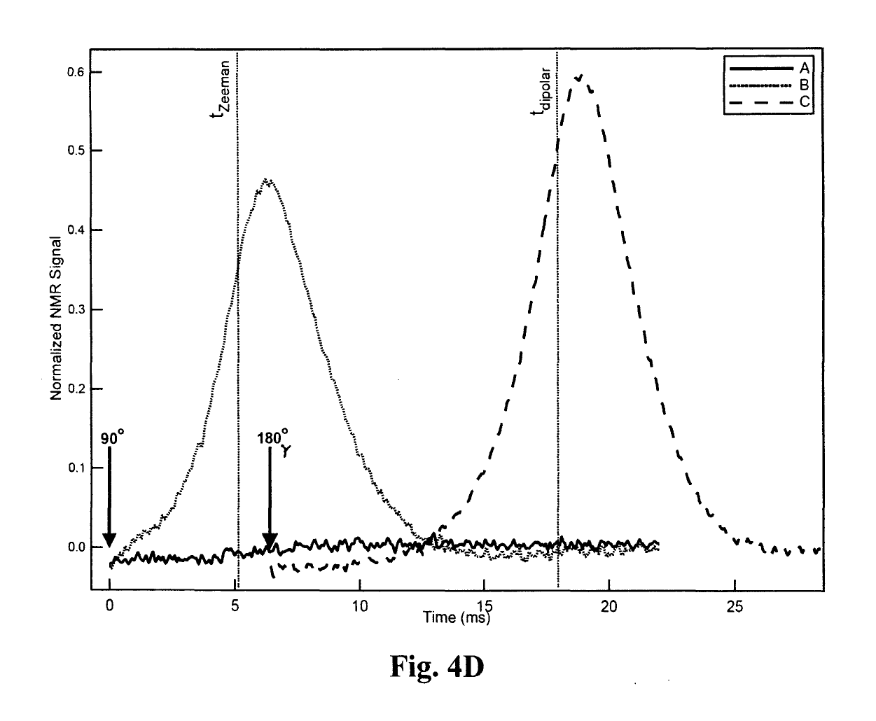

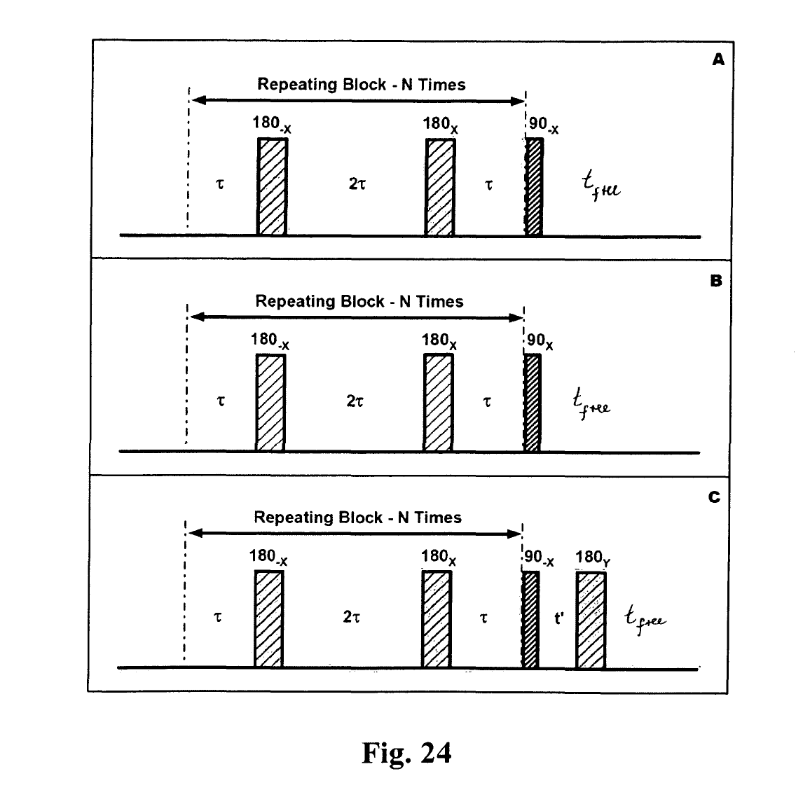

Three exemplary sequences in that category are: (a) {−X,X}^{N}-90_{-X}-t_{free}; (b) {−X,X}^{N}-90_{X}-t_{free}; and (c) {−X,X}^{N}-90_{-X}-180_{Y}-t_{free}. The expected influence of those sequences on the Zeeman and dipolar phases of two exemplary spin species among the plurality of spin species found in a given sample are shown in FIGS. 4A, 4B, and 4C, respectively, each of which figures depicts the use of an exemplary sequence having the form of sequence 300 as shown in FIG. 3C. The exemplary sequences themselves are shown in FIGS. 24A, 24B, and 24C, respectively.

For the −X choice (sequence of FIG. 24A), the Zeeman phase wraps in a CCW manner both during and after the burst (FIG. 4A, black), which spoils the dipolar echo that would otherwise form during the free evolution period (FIG. 4D, solid). For the +X choice (sequence of FIG. 24B), both Zeeman and dipolar terms switch from CW phase wrapping in the burst to CCW phase unwrapping during the free evolution period (FIG. 4B), resulting in a large echo (FIG. 4D, dotted). This echo is not optimized, since the refocusing time is different (FIG. 4B) for the dipolar and Zeeman phases (t_{dipolar}=(α−β)Nt_{c}/2, t_{Zeeman}=λNt_{c}). An optimized echo (FIG. 4D, dashed) is generated if a 180_{Y} is applied at time

$${t}_{{f}_{1}} = ( \frac{α - β - 2 λ}{4} ) {Nt}_{c} , ( where α = \frac{4 τ}{{t}_{c}} , β = \frac{{t}_{p}}{{t}_{c}} , and λ = \frac{4 {t}_{p}}{π {t}_{c}} )$$

after the failed sequence {−X,X}^{N}-90_{-X} (FIG. 4D, black). This sequence (shown in FIG. 24C) aims to synchronize the refocusing times of the dipolar and Zeeman phases (FIG. 4C) by using the fact that a 180_{Y} pulse flips the sign of the Zeeman term but does not change the dipolar term. Thus, using the sequence of FIG. 24C, if a first set spin species is governed by a Hamiltonian H₁=H_{Z1}+H_{ZZ1}, and a second set of spin species is governed by a Hamiltonian H₂=H_{Z2}+H_{ZZ2}, wherein H_{Z1}≠H_{Z2} causing the magnetic resonance signal to decohere and/or H_{ZZ1}≠H_{ZZ2} causing the magnetic resonance signal to decohere, coherence can substantially be restored at time t_{echo} given a selection of time t_{f}_{₁}, and an echo can be produced at t_{echo}. The measured echo happens at a slightly different time, due to the terms ignored in this model.

Compared to the MSE sequence discussed in Section 3 above, which works best if Ω_{z}^{net}=0, the exemplary sequences of the present invention based on the {−X,X}^{N} block have several clear differences: (1) both Zeeman and dipolar phases are wrapped during the burst (FIG. 4A-C); (2) a 90_{±X} is used instead of the 90_{Y}; and the 2τ gaps in between the π pulses of the {−X,X} block simplify implementation.

The differences in FIGS. 4A-C and the related exemplary sequences may be explained by considering the unitary operator for the three sequences in greater detail. The block {−X,X} has H̅_{{-X,X}}⁽¹⁾=0, and

$$\begin{matrix}{\overline{H}}_{\{ - X , X \}}^{( 0 )} = α {H}_{zz} - β {H}_{xx} + {λΩ}_{z}^{net} {I}_{{y}_{T}} \\ = \frac{- ( α - β )}{2} {H}_{yy} + {λΩ}_{z}^{net} {I}_{{y}_{T}} + {\overline{H}}_{\{ - X , X \}}^{( 0 ) , Nonsecular} .\end{matrix}$$

To simplify the theory, the nonsecular term H̅_{{-X,X}}^{(0),Nonsecular} is dropped altogether, as in second averaging. Pines et al. Quantitative Aspects of Coherent Averaging. Simple Treatment of Resonance Offset Processes in Multiple Pulse NMR. J. Mag. Res. 8, 354 (1972); Haeberlen et al., Resonance Offset Effects in Multiple-Pulse NMR Experiments. J. Chem. Phys. 55, 53 (1971). Since λΩ_{z}^{net}I_{y}_{_{T}} is not typically the largest term in

$${\overline{H}}_{\{ - X , X \}}^{( 0 )} ( e . g . , \frac{\vert {λΩ}_{z}^{net} \vert}{\vert {Ω}_{D} \vert} ∼ 0.7$$

in FIG. 4A-C, using the representative values

$$\frac{{Ω}_{z}^{net}}{h} = \pm 100 Hz , \frac{{Ω}_{D}}{h} = \pm 15 Hz ) ,$$

it is unexpected that this approximation works well.

Thus, a “burst” {−X,X}^{N}-90_{±X}, followed by a free evolution of duration t_{free}, has the unitary operator

$${e}^{- \frac{i}{ℏ} ( {H}_{zz} + {Ω}_{z}^{net} {I}_{{z}_{T}} ) {t}_{free}} {e}^{- \frac{i}{ℏ} ( \frac{- ( α - β )}{2} {H}_{zz} ∓ {λΩ}_{z}^{net} {I}_{{z}_{T}} ) {Nt}_{c}} {U}_{{90}_{\pm X}} ,$$

where the single 90_{±X} is treated as a pure rotation (i.e., U₉₀ _{_{±X}}=e^{±i(π/2)1}^{_{xT}})
and α>β in FIG. 4A-C. Rearranging terms,

$${e}^{- \frac{i}{ℏ} ( {H}_{zz} + {Ω}_{z}^{net} {I}_{{z}_{T}} ) {t}_{free}} {e}^{- \frac{i}{ℏ} ( \frac{- ( α - β )}{2} {H}_{zz} ∓ {λΩ}_{z}^{net} {I}_{{z}_{T}} ) {Nt}_{c}} = {e}^{+ {iΦ}_{D} ( {t}^{*} ) {\tilde{H}}_{zz}} {e}^{+ {iΦ}_{Z} ( {t}^{*} ) {\tilde{H}}_{z}} ,$$

where Ω_{D} is a representative dipolar energy scale, and the operators

$${\tilde{H}}_{zz} = \frac{{H}_{zz}}{{Ω}_{D}} , {\tilde{H}}_{z} = \frac{{H}_{z}}{{Ω}_{z}^{net}}$$

are dimensionless. At time t*=t_{free}+Nt_{c}, the dipolar phase angle is defined to be

$${Φ}_{D} ( {t}^{*} ) = \frac{- {Ω}_{D}}{ℏ} ( {t}_{free} - \frac{( α - β )}{2} {Nt}_{c} ) ,$$

while the Zeeman phase angle is defined to be

$${Φ}_{Z} ( {t}^{ *} ) = \frac{- {Ω}_{z}^{net}}{ℏ} ( {t}_{free} ∓ λ {Nt}_{c} ) .$$

FIGS. 4A-B show the evolution of Φ_{D}(t), Φ_{Z}(t) during the corresponding measurements. This shows that Zeeman dephasing (FIG. 4A) adversely affects the echo for the 90_{-X} choice (FIG. 4D, solid). The 90_{+X} choice refocuses both the Zeeman and the dipolar phases (FIG. 4B), although at two different times (t_{Zeeman}=λNt_{C},t_{dipolar}=(α−β)Nt_{c}/2). The echo (FIG. 4D, dotted) is closer to t_{Zeeman}. In contrast to the hard π pulse model of the present invention, if the {−X,X}^{N} used delta-function π pulses, then the 90_{X} and 90_{-X} both would produce an FID instead of the echo (or no echo) in real measurements.

If a 180_{Y} is applied at time t_{f}_{₁} after the failed sequence {−X,X}^{N}-90_{-X} (FIG. 2D, solid), Zeeman and Dipolar refocusing can be synchronized. The resulting unitary operator

$${U}_{{180}_{Y}} {e}^{- \frac{i}{ℏ} ( {H}_{zz} - {Ω}_{z} {I}_{{z}_{T}} ) {t}_{{f}_{2}}} {e}^{- \frac{i}{ℏ} ( {H}_{zz} + {Ω}_{z} {I}_{{z}_{T}} ) {t}_{{f}_{1}}} {e}^{- \frac{i}{ℏ} ( \frac{- ( α - β )}{2} {H}_{zz} + {λΩ}_{z} {I}_{{z}_{T}} ) {Nt}_{c}} {U}_{{90}_{- X}}$$

shows that the optimized echo should happen at

$${t}_{Zeeman} = {t}_{dipolar} = {t}_{{f}_{1}} + {t}_{{f}_{2}} = ( \frac{α - β}{2} ) {Nt}_{c} , for {t}_{{f}_{1}} = ( \frac{α - β - 2 λ}{4} ) {Nt}_{c} ,$$

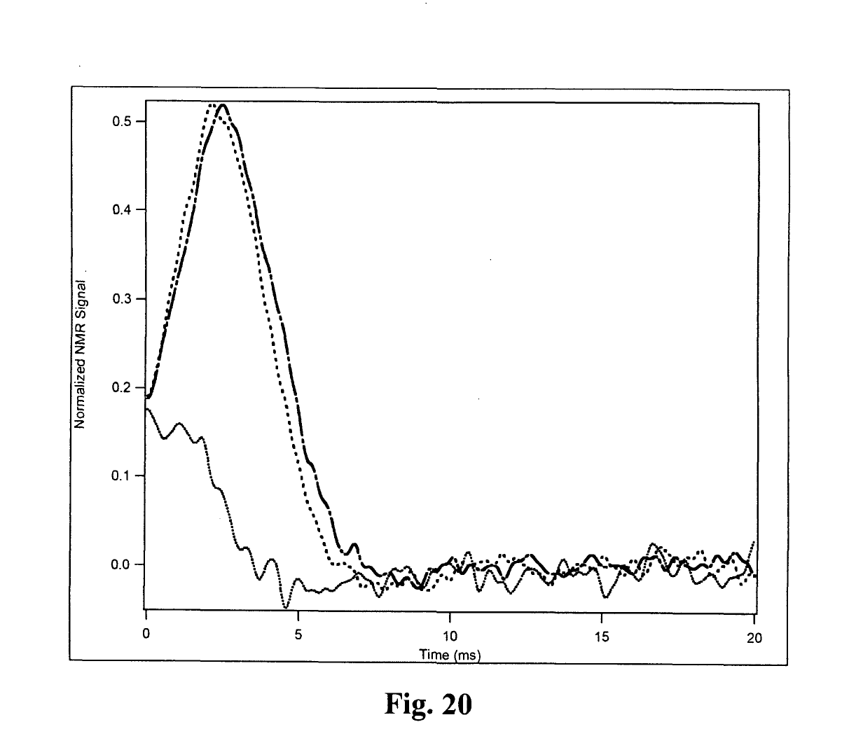

as in FIG. 2C. The measured echo (FIG. 2D, dashed) happens at a slightly different time, due to the terms ignored in this model. As explained in Section 7.1.2 below, very similar results have been obtained in a Si:Sb sample (see also FIG. 20).

The exemplary Zeeman-and-dipolar phase-wrapping sequences discussed in this subsection can be generalized. For example, instead of using the {−X,X} repeating block, a {X,−X} repeating block can be used.

6.4.4 Quadratic Effective Transverse Field

6.4.4.1 Quadratic Echo

The sequences discussed in Section 6.4.3 above use the building-block sequence {φ₁,φ₂} from FIG. 3C with φ₁=−φ₂. Those {φ₁,φ₂} blocks have a linear effective transverse field term (e.g., −λΩ_{z}^{net}Iₓ_{_{T}} for {−Y,Y}) in H̅_{{φ}_{₁},φ_{₂}_{}}⁽⁰⁾, and H̅_{{φ}_{₁}_{,φ}_{₂}_{}}⁽¹⁾=0. However, other embodiments instead use building block sequences from FIG. 3C with φ₁=φ₂=φ, i.e., building blocks of the form {φ,φ}. These advantageous embodiments make use of what will be referred to as a “quadratic” effective magnetic field term for reasons about to be described.

For the reasons to be described below, certain preferable sequences having {φ,φ} blocks combine those blocks with {−φ,−φ}, and therefore use a somewhat larger block having the form {φ,φ}^{N/2}{−φ,−φ}^{N/2}, where φ=±X or ±Y. More particular sequences of this form according to various embodiments of the invention will be described in more detail below after discussing the significance of the {φ,φ}^{N/2}{−φ,−φ}^{N/2} block.

The {φ,φ}^{N/2}{−φ,−φ}^{N/2} blocks were conceived of as follows and are used to form pulse sequences according to various embodiments of the invention for the following reasons. Consider, for example, the repeating block {X,X}. For {X,X}, H̅_{{X,X}}⁽⁰⁾=αH_{zz}−βHₓₓ; the first transverse field term is found in

$${\overline{H}}_{\{ X , X \}}^{( 1 )} = \frac{+ i}{2 {t}_{c} ℏ} \frac{{t}_{p}}{π} ( {t}_{p} [ {H}_{x}^{A} , {H}_{x}^{S} + {H}_{xx} ] + ( 8 τ + 2 {t}_{p} ) [ {Ω}_{z}^{net} {I}_{{y}_{T}} , {Ω}_{z}^{net} {I}_{{z}_{T}} + {H}_{xx} ] ) ,$$

or H̅_{{X,X}}⁽¹⁾=-(κΩ_{z}^{net})²Iₓ_{ᵣ}+ H̅_{{X, X}}^{(1), non-1}_{_{xT}},
where

$$κ = \sqrt{\frac{{t}_{p} ( 8 τ + 2 {t}_{p} )}{2 {t}_{c} ℏπ}}$$

and H̅_{{X, X}}^{(1), non-1}_{_{xT}} contains the many terms not proportional to Iₓ_{_{T}}. The term −(κΩ_{z}^{net})²Iₓ_{_{T}} is referred to as the “quadratic” effective field or “quadratic” transverse field term, because Iₓ_{_{T}} has a coefficient proportional to (Ω_{z}^{net})².

The quadratic effective field of H̅_{{φ}₁,φ₂}⁽¹⁾ is smaller than the linear effective field term discussed in Section 6.4.3 above (e.g.,

$$\frac{\vert {( {κΩ}_{z}^{net} )}^{2} \vert}{\vert {Ω}_{D} \vert} \sim 0.02$$

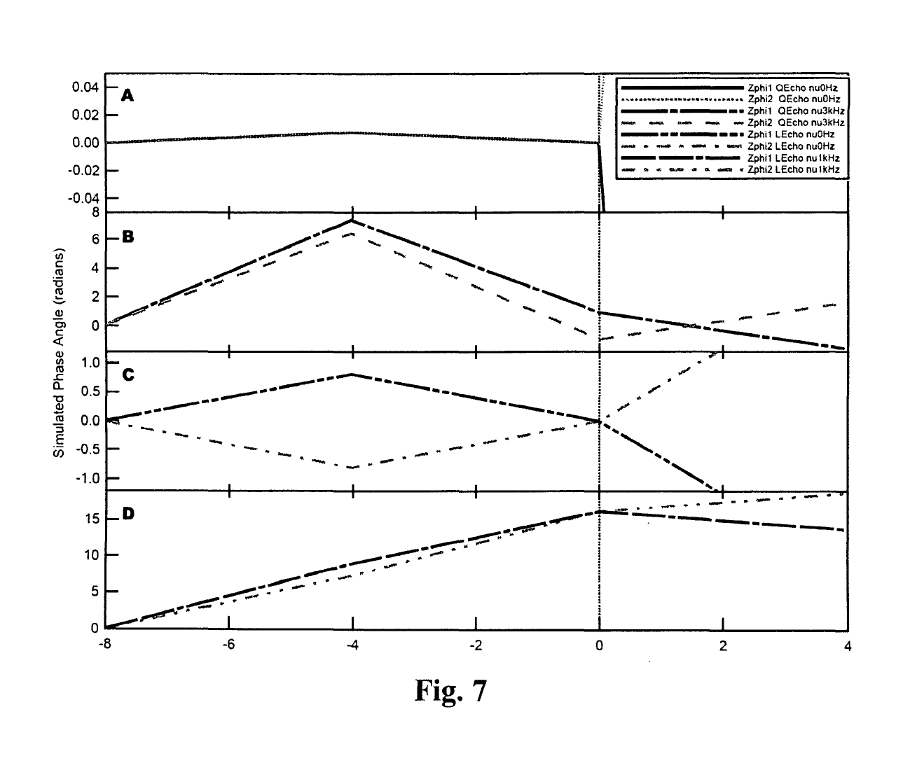

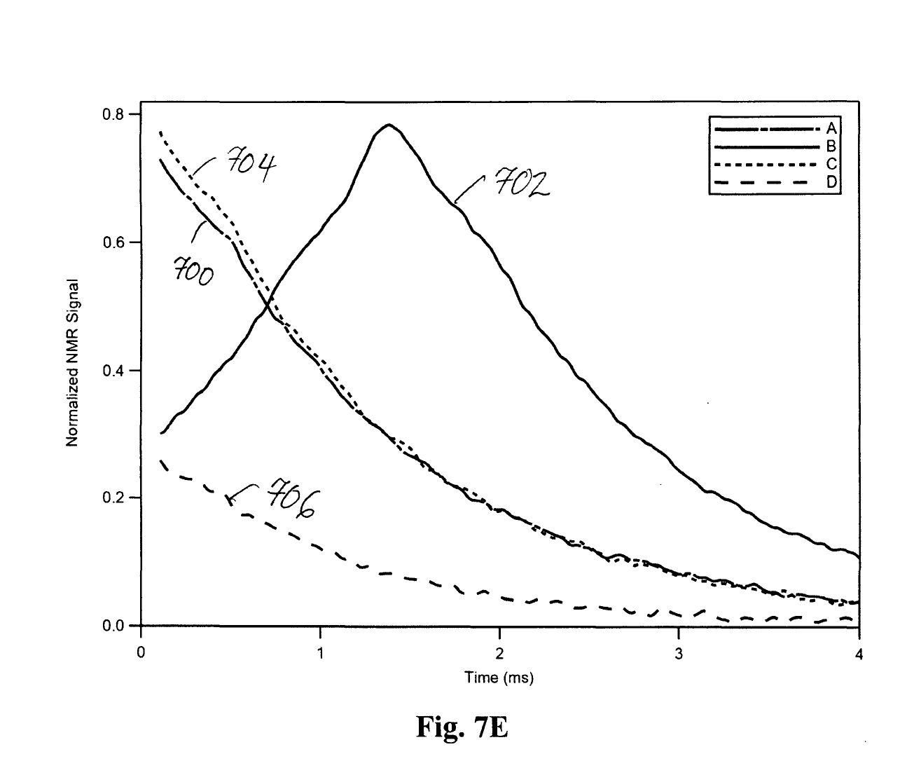

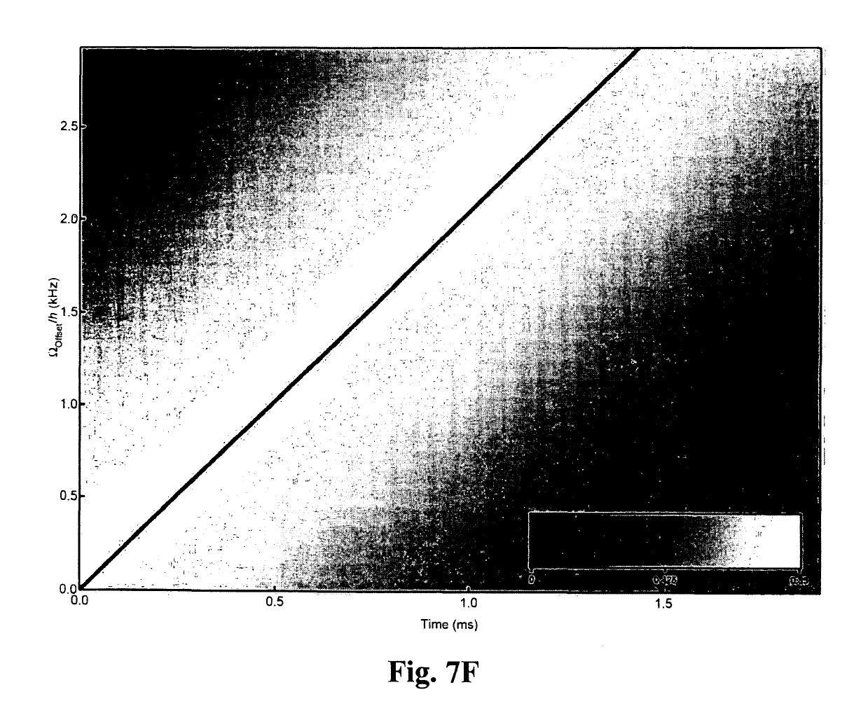

for FIGS. 7A-E, for representative values

$$\frac{{Ω}_{z}^{net}}{h} = \pm 100 Hz , \frac{{Ω}_{D}}{h} = \pm 15 Hz ) .$$

However, it is shown herein that the quadratic effective field could act like the linear field term found in H̅_{{φ,-φ}}⁽⁰⁾ and pick out a secular part of H̅_{{X,X}}⁽⁰⁾ along Iₓ_{_{T}}. In practice, the signal from a {X,X}^{N} decays rapidly, because of the terms in H̅_{{X, X}}^{(1), non-I}_{_{xT. However, using the fact that {−X,−X} has H̅}}_{{-X,-X}}⁽⁰⁾= H̅_{{X,X}}⁽⁰⁾ and H̅_{{-X,-X}}⁽¹⁾=− H̅_{{X,X}}⁽¹⁾, most of the signal is recovered by replacing {X,X}^{N} with the composite block {X,X}^{N/2}{−X,−X}^{N/2}, demonstrating that the effect of H̅_{{X, X}}^{(1), non-I}_{_{xT is cancelled out. Thus it is discovered that the complicated unitary operator}}

$${e}^{- \frac{i}{ℏ} ( {\overline{H}}_{\{ - X , - X \}}^{( 0 )} + {\overline{H}}_{\{ - X , - X \}}^{( 1 )} [ {Ω}_{z}^{net , -} ] ) \frac{{Nt}_{c}}{2}} {e}^{- \frac{i}{ℏ} ( {\overline{H}}_{\{ X , X \}}^{( 0 )} + {\overline{H}}_{\{ X , X \}}^{( 1 )} [ {Ω}_{z}^{net , +} ] ) \frac{{Nt}_{c}}{2}}$$

is well-approximated by the simplified unitary operator

$${e}^{- \frac{i}{ℏ} ( \frac{- ( α + 2 β )}{2} {H}_{xx} + {( κ {Ω}_{z}^{net , -} )}^{2} {I}_{{x}_{T}} ) \frac{{Nt}_{c}}{2}} {e}^{- \frac{i}{ℏ} ( \frac{- ( α + 2 β )}{2} {H}_{xx} - {( {κΩ}_{z}^{net , +} )}^{2} {I}_{{x}_{T}} ) \frac{{Nt}_{c}}{2}} .$$

In the general case, the values of Ω_{z}^{net,+} (or Ω_{z}^{net,-}) during {X,X}^{N/2} (or {−X,−X}^{N/2}) could be different. The simpler expression drops the many terms in H̅_{{±X,±X}}^{(0),Nonsecular} and H̅_{{±X, ±X}}^{(1), non-I}_{_{xT}} altogether. This simpler model makes quantitative predictions that describe the measurements shown in FIGS. 7A-E quite well, which is unexpected given the tiny effective transverse field scale (e.g.,

$$\frac{\vert {( {κΩ}_{z}^{net} )}^{2} \vert}{\vert {Ω}_{D} \vert} \sim 0.02$$

in FIGS. 7A-E, for representative values

$$\frac{{Ω}_{z}^{net}}{h} = \pm 100 Hz , \frac{{Ω}_{D}}{h} = \pm 15 Hz ) .$$

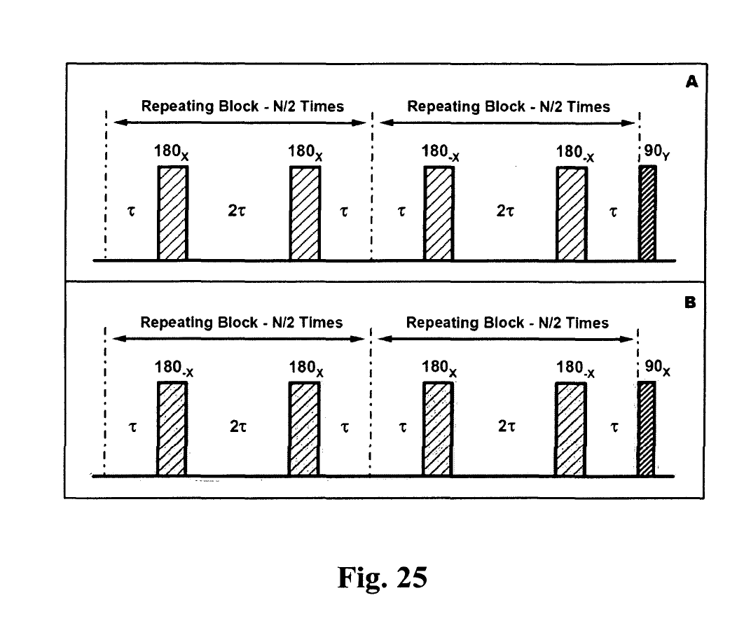

To illustrate “quadratic echo” sequences of the invention using the {X,X}^{N/2} {−X,−X}^{N/2} block, and a unique control over the echo location through use of an offset frequency, consider the exemplary sequence {X, X}^{N/2}{−X,−X}^{N/2}-90_{Y}-t_{free} (shown in FIG. 25A), with Ω_{z}^{net,±}=Ω_{z}^{loc}±Ω_{offset}^{global} (Ω_{offset}^{global}≧0) during {X, X}^{N/2}{−X,−X}^{N/2}-90_{Y}, followed by Ω_{offset}^{global}=0 during free evolution. As discussed below, measurements were made at a plurality of times during the t_{free}. The resulting unitary operator for the sequence is

$${e}^{- \frac{i}{ℏ} ( {H}_{zz} + {Ω}_{z} {I}_{{z}_{T}} ) {t}_{free}} {e}^{- \frac{i}{ℏ} ( - ( \frac{α + 2 β}{2} ) {H}_{zz} - ( 2 {κ}^{2} {Ω}_{z}^{loc} {Ω}_{offset}^{global} ) {I}_{{z}_{T}} ) {Nt}_{c}} {U}_{{90}_{Y}} .$$

Increasing Ω_{offset}^{global} increases Zeeman dephasing during the burst, pushing the quadratic echo peak out to a′off set later times in simulations (FIGS. 7A-B) and in measurements (FIG. 7E lines A and B and FIG. 7F). The measurement behind FIG. 7F is described in more detail in Section 7.3.1 below. Notably, FIG. 7F shows the strong agreement between the Zeeman refocusing time predicted by our model (the black trend line) and the quadratic echo peak measured over a range of Ω_{offset}^{global}. That is, the magnetic resonance signal reaches a maximum value at a time proportional to the magnitude of the offset frequency. In contrast, simulations (FIGS. 7C-D) and measurements (FIG. 7E lines C and D) show that the corresponding “linear” sequence {−X, X}^{N/2}{X,−X}^{N/2}-90_{X} (shown in FIG. 25B), with the unitary operator

$${e}^{- \frac{i}{ℏ} ( {H}_{zz} + {Ω}_{z}^{loc} {I}_{{z}_{T}} ) {t}_{free}} {e}^{- \frac{i}{ℏ} ( - ( \frac{α - β}{2} ) {H}_{zz} - {λΩ}_{offset}^{global} {I}_{{z}_{T}} ) Ntc} {U}_{{90}_{X}} ,$$

has a very different behavior. Because Ω_{offset}^{global} during the burst contributes only a trivial global phase factor, and the dominant Zeeman dephasing takes place during t_{free}, the largest signal occurs just after the burst, for all Ω_{offset}^{global}. Thus, controlling the offset of an echo (signal peak) in the frequency domain is a unique property of the quadratic echo of certain embodiments of the present invention.

In the above measurement, the sequence {X,X}^{N/2}{−X,−X}^{N/2}-90_{Y}-t_{free} (for Ω_{offset}^{global}>0) was applied to a sample. One of ordinary skill in the art could see that various other sequences are equivalent. For example, the 90_{Y} would become a 90_{-Y} if either Ω_{offset}^{global}≦0 or the IC rotations were performed about opposite axis (i.e., {−X,−X} block before {X, X} block). On the other hand, the 90_{Y} would be kept if both Ω_{offset}^{global}≦0 and the π rotations were performed about opposite axis. It should be noted that for Ω_{offset}^{global}=0, i.e., ν_{offset}=0, there are more options for equivalent pulse sequences than for ν_{offset}≠0.

While the particular sequence of this subsection used the block {X, X}^{N/2}{−X,−X}^{N/2}, other embodiments of the invention use other variations of the block {φ,φ}^{N/2}{−φ,−φ}^{N/2}. Certain other embodiments use a more generalized version of {φ,φ}^{N/2}{−φ,−φ}^{N/2} namely, {τ₁-180_{φ}_{₁}-2τ₂-180_{φ}_{₁}-τ₃}^{N/2}{τ₄-180_{φ}_{₂}-2τ₅-180_{φ}_{₂}-τ₆}^{N/2} (where φ₁=φ, and φ₂=−φ).

This sequence has two subsequences, each repeated N/2 times, where N is an even integer greater than or equal to two. The first subsequence includes the following events: a free-evolution period of duration τ₁, a first approximate π pulse of duration tₚ applied at an offset frequency ν having magnitude greater than or equal to zero along the positive or negative x-direction, a free-evolution period of duration 2τ₂, an approximate π pulse of duration tₚ applied at offset frequency ν in the same direction as the first approximate πpulse, and a free-evolution period of duration τ₃. The duration of the pulse sequence is t_{c} τ₁+2τ₂+τ₃+2tₚ. The pulse time tₚ and durations of the periods of free evolution all are approximate within the tolerances provided in Section 6.5 below. The second subsequence is analogous, but with approximate π pulses in the opposite direction; τ₄, τ₅, and τ₆ instead of τ₁, τ₂, and τ₃; and offset frequency ν₁=±ν. In certain preferable embodiments, 2τ₂≈τ₁+τ₃ and/or 2τ₅≈τ₄+τ₆. In other embodiments, τ₁, τ₂, τ₃, τ₄, τ₅, and τ₆ are all approximately equal to each other.

6.4.4.2 Controlling Zeeman and Dipolar Phase Wrapping

Guided by the above analysis, more specific sequences in accordance with various aspects of the present intention are now provided. In particular, in certain advantageous embodiments, both dipolar and Zeeman phase wrapping are controlled using H̅_{{φ}_{₁}_{,φ}_{₂}_{}}⁽¹⁾. This is a novel aspect of the quadratic echo.

Certain sequences using the {φ,φ}{−φ,−φ} block have the form (Δ+δ)-90_{ψ}_{₁}-{φ₁,φ₂}^{N/2}{φ₃, φ₄}^{N/2}-90_{ψ}_{₂}-(Δ−δ), where

$$Δ = \frac{{Nt}_{c}}{4} , \vert δ \vert \leq Δ , {t}_{c}$$

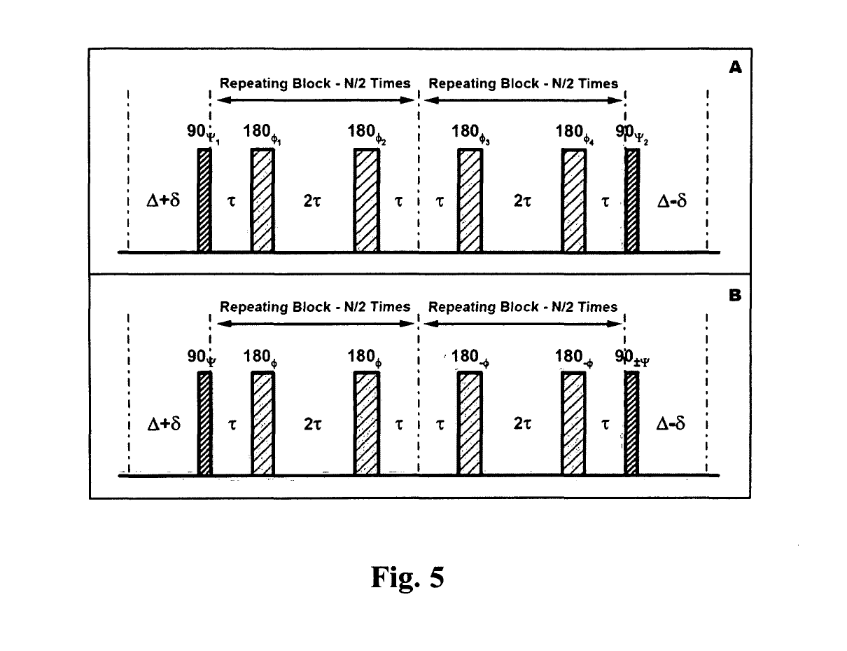

is the time of a {φ₁,φ₂} or {φ₃,φ₄} cycle, and N is an even integer greater than or equal to two. This sequence, represented by the notation {N, δ, ψ₁, ψ₂, φ₁, φ₂, φ₃, φ₄}, is shown in FIG. 5A and has the following steps: a free evolution period of duration Δ+δ, a 90° pulse about axis ψ₁, the block pulse sequence {φ₁,φ₂} repeated N/2 times, the block pulse sequence {φ₃,φ₄} repeated N/2 times, a 90° pulse about axis ψ₂, and a free evolution period of Δ−δ. The two 90° pulses are referred to as “wrappers,” while the entire subsequence 90_{ψ}_{₁}-{φ₁,φ₂}^{N/2}{φ₃,φ₄}^{N/2}-90_{ψ}_{₂} is referred to as the “burst.” The sequences described herein use a version of the sequence of FIG. 5A shown in FIG. 5B, where ψ₂=±ψ₁≡ψ, φ₁=φ₂≡φ, φ₃=φ₄=−φ. Using the compact notation, FIG. 5B depicts the sequence {N, δ, ψ, ±ψ, φ, φ, −φ, −φ}. In the sequences described herein either ψ=±X and φ=±Y, with the signs of the two “±” signs chosen independently, or ψ=±Y and φ=±X, again with the signs of the two “±” signs chosen independently. If multiple {N, δ, ψ, ±ψ, φ, φ, −φ, −φ} are used in a given pulse sequence, the definitions of X and Y can be different for each application, so long as X, Y, and Z (the unchanging direction of the external magnetic field) for any given application of a {N, δ, ψ, ±ψ, φ, φ, −φ, −φ} block are selected to form a right-handed coordinate system.

All such sequences {N, δ, ψ, ±ψ, φ, φ, −φ, −φ} have no net dipolar evolution; however, the sequences vary in behavior with respect to Zeeman evolution. Certain embodiments also have no net Zeeman evolution; for other embodiments, it is preferred to have a controlled Zeeman evolution related to an applied field. Based on a desired application and the exemplary forms of {N, δ, ψ, ±ψ, φ, φ, −φ, −φ} discussed herein, one of ordinary skill in the art could determine the more specific form the needed sequence should take. In certain applications, a given sequence {N, δ, ψ, ±ψ, φ, φ, −φ, −φ} is repeated. In other embodiments, more than one version of sequences of this form are combined into a single pulse sequence. In certain of those embodiments, one version of {N, δ, ψ, ±ψ, φ, φ, −φ, −φ} is applied based on coordinates X and Y, and another version of {N, δ, ψ, ±ψ, φ, φ, −φ, −φ} is applied based on coordinates X′, and Y′, where the X and Y axes are at an angle φ, 0°≦φ≦360° with respect to the X′ and Y′ axes.

This general category of sequences, therefore, can be used to express several more specific sequence forms, including three exemplary sequences forms to be called the “Zeeman-evolution block,” the “time-suspension block,” and the “External-Zeeman-evolution block.” As detailed below, each of these exemplary sequence forms provides a different useful effect. In determining which sequences to use for a particular application or in building larger sequences, one of ordinary skill in the art would consider the effects of the following sequence forms and use them appropriately. In certain embodiments, more than one of the various sequence forms are applied.

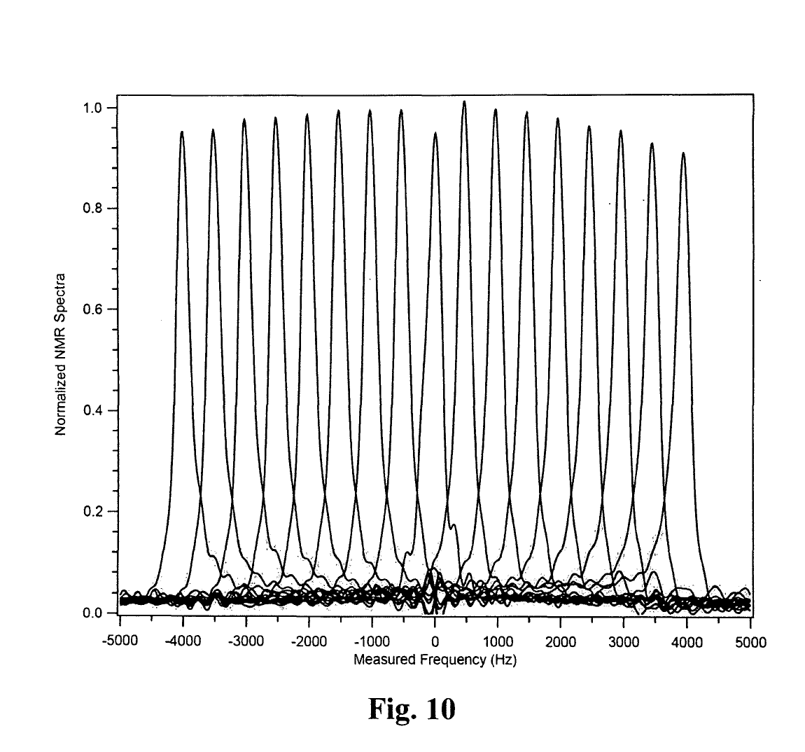

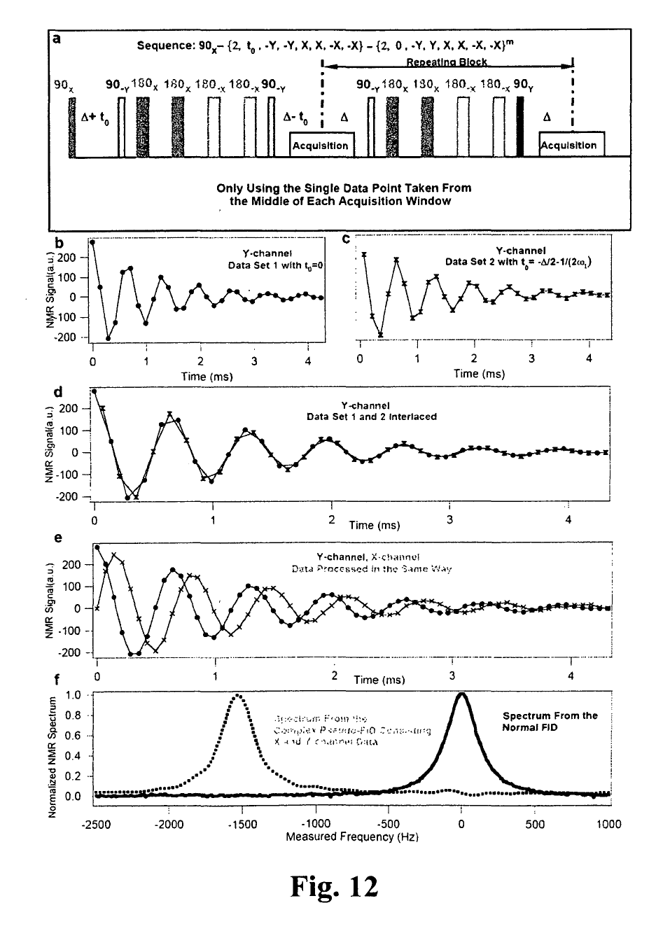

“Zeeman-evolution block”. This exemplary sequence provides a net Zeeman evolution due to constant Ω_{z}^{loc} and Ω_{offset}^{global} but no net dipolar evolution. It is created by blocks: {N, δ, X, −X, Y, Y, −Y, −Y}, {N, δ, X, −X, −Y, −Y, Y, Y}, {N, δ, −X, X, Y, Y, −Y, −Y}, {N, δ, −X, X, −Y, −Y, Y, Y}, {N, δ, Y, −Y, X, X, −X, −X}, {N, δ, Y, −Y, −X, −X, X, X}, {N, δ, −Y, Y, X, X, −X, −X}, {N, δ, −Y, Y, −X, −X, X, X}. Because the Zeeman-evolution block allows for evolution due to Ω_{offset}^{global}, it can be used to intentionally move a signal peak in the frequency domain by an amount proportional to Ω_{offset}^{global} (and ν_{offset}). This is shown in FIGS. 10 and 12A-F. FIG. 10 shows the results from a series of applications of a particular sequence comprised of Zeeman-evolution blocks, applied with differing values of ν_{offset}. FIG. 12A-F show the steps to obtain one of the peaks of FIG. 10. In particular, the sequence applied is shown in FIG. 12A, and is {2, t₀, −Y, −Y, X, X, −X, −X}-{2, 0, −Y, Y, X, X, −X, −X}^{m}. The second block in this sequence—the block that repeats—is a Zeeman-evolution block, and is used to offset the signal peak, as shown in FIG. 12F. Because of Zeeman evolution due to Ω_{z}^{loc}, however, the FWHM of the peak in FIG. 12F is larger than ideal. However, line-narrowing techniques pursuant to certain embodiments described herein can be applied to narrow the FWHM of the frequency spectrum, as discussed below in connection with the external-Zeeman-evolution block. Despite this issue, the value of the Zeeman-evolution block is clearly shown in FIGS. 10 and 12F.

The ability to obtain a number of peaks offset by ν_{offset} is important in imaging, where it is necessary to spatially divide up the sample and obtain signals for various spatial locations. For example, in the case of using an MRI on a person, one needs to obtain signals for various positions on the person in order to get the image for all locations. Other methods than the one shown in FIG. 12A-F can be used to obtain a plurality of signals such as those shown in FIG. 10. For example, instead of measuring the signal multiple times with varying ν_{offset}, it is contemplated that an additional external magnetic field in the z-direction may be applied. This additional external magnetic field, or gradient magnetic field, will have varying magnitude with at least one direction X, Y, or Z, or some other direction that is a linear combination of X, Y, and Z (i.e., for a gradient field B_{g}, ∂B_{g}/∂x, ∂B_{g}/∂y, and/or ∂B/∂z≠0). Applying such a gradient field creates a ν_{offset}(x,y,z) (or Ω_{offset}^{global}(x,y,z)) that varies with position. Running the process of FIG. 12A-F just once, then, would allow for the acquisition of a of multiple peaks offset from one another in the frequency domain by an amount proportional to ν_{offset}(x,y,z). The gradient field B_{g} is preferably applied during one or more of the periods of free evolution between two Zeeman-evolution blocks. However, one of the advantages of certain embodiments of the present invention compared to previous sequences is that leaving on the gradient field B_{g} for the periods between the 90° wrapper pulses does not hurt the signal. Therefore, in certain embodiments, B_{g} is also applied for one or more periods between 90° wrapper pulses.

“Time-suspension block”. This exemplary sequence provides no net dipolar evolution, and for Ω_{z}^{loc} and Ω_{offset}^{global} constant, it also provides no net Zeeman evolution. It is created by selecting same phase wrappers and letting δ=0. The following sequences qualify as time-suspension blocks: {N, 0, X, X, Y, Y, −Y, −Y}, {N, 0, X, X, −Y, −Y, Y, Y}, {N, 0, −X, −X, Y, Y, −Y, −Y}, {N, 0, −X, −X, −Y, −Y, Y, Y}, {N, 0, Y, Y, X, X, −X, −X}, {N, 0, Y, Y, −X, −X, X, X}, {N, 0, −Y, −Y, X, X, −X, −X}, and {N, 0, −Y, −Y, −X, −X, X, X}. In certain embodiments, the time-suspension block is applied at least one time following a 90° pulse in either the ±X or ±Y direction and the signal is measured during at least one period of free evolution occurring between the second 90° wrapper of a first time-suspension period and the first 90° wrapper of a following time-suspension period. In certain embodiments, the time-suspension blocks use π pulses in the ±X direction, and the 90° pulse preceding application of one or more time-suspension blocks is preferably in the ±X direction. In other embodiments, the preceding 90° pulse is in the ±Y direction; a first set of one or more time-suspension blocks is applied, wherein the first π pulse of that set is in the ±X direction, and a second set of one or more time-suspension blocks is applied, wherein the first π pulse of that set is in the ±X direction. In certain of those embodiments, the first set of one or more time-suspension blocks and the set of one or more time-suspension blocks are combined to form a bigger repeated double-time-suspension block. While the last series of sequences was discussed with π pulses in the ±X direction, analogous sequences exist with π pulses in the ±Y direction.

Because both Zeeman and dipolar phases are refocused after each time suspension block, the time-suspension block plays a major role in pushing out decay time. Applying appropriately several time-suspension blocks following a 90° tipping pulse yields a time suspension sequence. One such time suspension sequence is 90_{X}-{2, 0, −Y, −Y, X, X, −X, −X}^{m}. The results of applying such a sequence are shown in FIG. 8 and described in more detail in Section 7.2.2 below. The plot in the main portion of the figure extends well beyond the normal FID time, shown by the near vertical line at the way left of the plot. Upon transforming the signals into the frequency domain, this results in a corresponding “line narrowing.” The left inset is the transform of the FID signal while the right inset is the transform of the time-suspension-sequence signal. Clearly, the FWHM of the transformed time-suspension signal is much narrower, which can be useful in many applications.

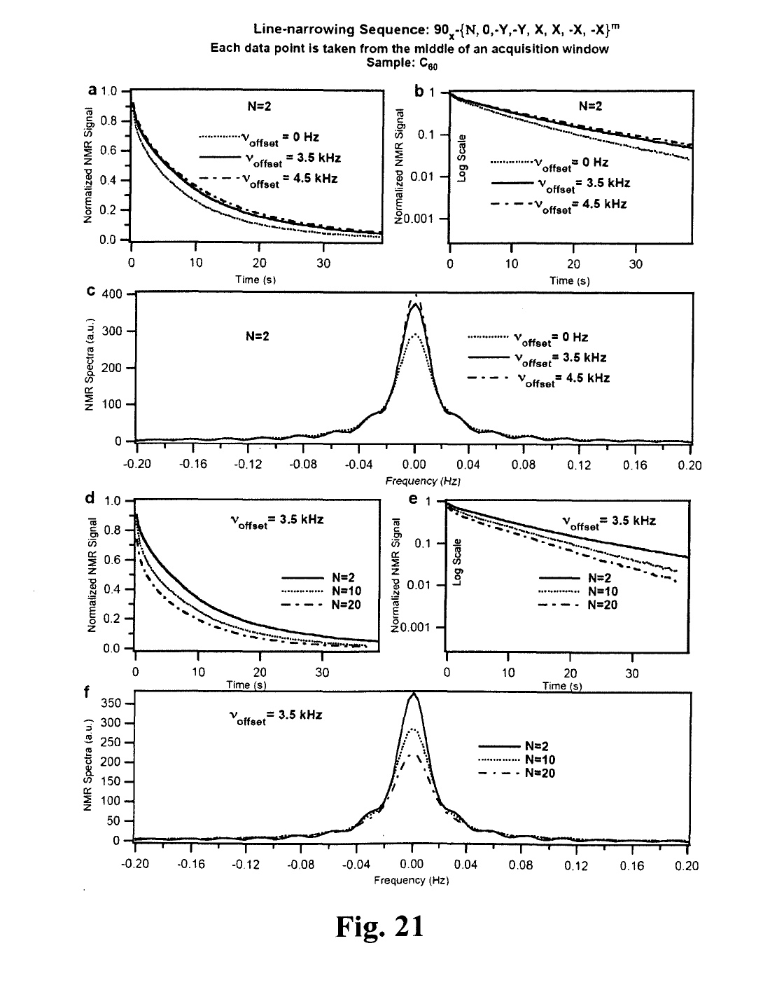

The time-suspension block also has a unique property that it is robust for changing values of Ω_{offset}^{global}. As seen in FIGS. 21A-C and described in more detail in Section 6.5 below, similar results were obtained for varying values of ν_{offset} for the sequence 90_{X}-{N, 0, −Y, X, X, −X, −X}^{m}, which contains a repeated time-suspension block. Also described in Section 6.5 below, the same sequence showed tolerance in N (FIGS. 21D-F).

“External-Zeeman-evolution block”. This exemplary sequence provides no net dipolar-coupling evolution and no Zeeman evolution due to constant Ω_{z}^{loc}, but provides a net Zeeman evolution by applying a time-varying offset Ω_{offset}^{global}(t). It uses same the phase wrappers. Preferably, δ is set to zero. A nonzero value of δ may be used, however, in applications which do not require removal of all contributions from Ω_{z}^{loc}. The offset Ω_{offset}^{global}(t) is varied through the application of a gradient magnetic field B_{g}, such that ∂B_{g}/∂t≠0. Preferably, Ω_{offset}^{global}(t) is varied during the period of free evolution occurring between the second 90° wrapper of a first external-Zeeman-evolution block and the first 90° wrapper of a following external-Zeeman-evolution block, but otherwise maintained constant. When the external-Zeeman-evolution block is applied more than two times, there will be more than one such free-evolution period, and Ω_{offset}^{global}(t) can be varied during any number of such periods. In certain embodiments, the gradient field varies by position at one or more times as well as varying with time. In other embodiments, the gradient only varies with time.

The external-Zeeman-evolution block has a significant advantage over prior pulse sequences. Because the external-Zeeman evolution block results in Zeeman evolution only due to a time-varying Ω_{offset}^{global}(t) the block permits a varying Ω_{offset}^{global}(t) without having to worry about creating a strong H_{Z} that will destroy the signal. On the other hand, a strong H_{Z} with prior pulse sequences (such as the MSE sequence) would destroy the signal, as explained in Section 3. Thus, while the MSE sequence may be effective in the regime νH_{Z}∥<<∥H_{zz}∥, the External-Zeeman-evolution block works in the complimentary regime, ∥H_{Z}∥≧∥H_{zz}∥. In particular, even if there is a large spread in Ω_{z}^{net} values across the sample, the external-Zeeman evolution block is still effective. As discussed below in Section 6.6.1, the external-Zeeman-evolution block and other embodiments of the present invention can still work for some ∥H_{Z}∥<∥H_{zz}∥, and an H_{Z} that is too small can be increased by increasing Ω_{offset}^{global}. This is an important result, because for imaging purposes, one often needs to vary Ω_{offset}^{global}.

The external-Zeeman evolution block can be used to improve upon the Zeeman-evolution-block portion of the sequence {2, t₀, −Y, −Y, X, X, −X, −X}-{2, 0, −Y, Y, X, X, −X, −X}^{m} discussed above in connection with the Zeeman-evolution block. As discussed above, while the Zeeman-evolution block successfully achieved signals with peaks in the frequency domain offset by an amount proportional to ν_{offset}, the FWHM of those peaks was widened due to the influence of Ω_{z}^{loc}. A narrowed FWHM can be achieved by replacing the repeating Zeeman-evolution block with a repeating external-Zeeman-evolution block and applying a time-varying gradient magnetic field. The time-varying magnetic field ensures that the resulting signal peak is still offset in the frequency domain by a value proportional to ν_{offset}. This new sequence (slightly generalized from the sequence previously discussed) has the form {2, t₀, −Y, −Y, ±X, ±X, ±X, ±X}-{2, δ, ±Y, ±Y,(+ or −)X , (+ or −)X , (− or +)X, (− or +)X}^{m}, where in the repeating external-Zeeman-evolution block, the signs for the Ys is chosen independently from the signs for the Xs. If the value of δ is small compared to Δ, then the sequence blocks should be repeated more times than if δ is large compared to Δ.

Another useful form of {N, δ, ψ, ±ψ, φ, φ, −φ, −φ}, one that does not fall into one of the three categories discussed, namely, the sequence block {N, t₀, ψ, −ψ, φ, φ, −φ, −φ} mentioned above, is taken advantage of in FIGS. 12A-F. In particular, as seen in FIG. 12A, the block used is {2, t₀, −Y, Y, X, X, −X, −X}. As seen in FIGS. 12A-F, two series of data were obtained for each signal channel (i.e., X and Y-channels). The two series of data were time shifted, so that they could be interlaced together to form a signal with twice as many data points. The signals being “time shifted” means the following: in FIG. 12B, the cosine-like signal began with a maximum near t=0, while in FIG. 12C, the maximum occurred at a later time. The increased sampling rate attainable with the different amounts of “time shift” provides for a larger bandwidth, or resolution of higher frequencies, in the frequency domain (i.e., after the signal is Fourier transformed from the time domain to the frequency domain). While in FIGS. 12A-F only two sets of data were interlaced together, in other embodiments, any number of data sets can be interlaced together.

The ability to obtain a time-shifted dataset is a result of the unique features of the {2, t₀, −Y, Y, X, X, −X, −X} block. To collect the first dataset (shown in FIG. 12B), t₀=0, and the cosine-like sequence had its maximum near t=0. To collect the second dataset (shown in FIG. 12C),

$${t}_{0} = - ( \frac{Δ}{2} + \frac{1}{2 {ω}_{1}} ) ,$$

and the cosine-like sequence had its maximum after t=0. Time delaying the sequence allows one to still take measurements at the advantageous acquisition times depicted in FIG. 12A, yet obtain different data points than for the undelayed signal. In this example, t₀ was selected so as to obtain a set of data points halfway between the first set of data points. In other embodiments, three or more data sets are obtained, and the values of t₀ used are selected so that, when interlaced, the data points of those sets are equally spaced. FIG. 12D shows the first and second set interlaced. (In other embodiments, no interlacing is performed, and the data from a single data set is Fourier transformed to obtain a frequency-domain signal.) Everything described in this paragraph so far for the embodiment of FIGS. 12A-F related to the Y channel; the same interlacing procedure was carried out with the X channel. FIG. 12E shows the data from both channels. Finally, FIG. 12F shows the Fourier transform of the signal. This process, with no interlacing or any amount of interlacing, can be carried out a plurality of times for a plurality values of ν_{offset}, thereby yielding a result such as the result shown in FIG. 10.

In certain embodiments, the Zeeman-evolution block, the time-suspension block, the external-Zeeman-evolution block, and/or other blocks of the form {N, δ, ψ, ±ψ, φ, φ, −φ, −φ} are combined to form sequences comprises more than one block type. Two embodiments of this form that have already been discussed are the sequences {2, t₀, −Y, −Y, X, X, −X, −X}-{2, 0,−Y, Y, X, X, −X, −X}^{m} and {2, t₀, −Y, −Y, ±X, ±X, ±X, ±X}-{2, δ,±Y,±Y,(+ or −)X, (+ or −)X ,(− or +)X ,(− or +)X}^{m}, which use a first block to time-shift the signal, and repeat a Zeeman-evolution or external-Zeeman-evolution block, respectively, to maintain control of the coherence the signal during the measurement period and obtain a measured signal in the frequency domain is shifted an amount proportional to ν_{offset}. Other combinations of the block {N, δ, ψ, ±ψ, φ, φ, −φ, −φ} are also contemplated, as is about to be described.

While there are few constraints on a single {N, δ, ψ, ±ψ, φ, φ, −φ, −φ} block, the non-zero duration of the 90_{ψ}_{ᵢ} pulses and H̅_{{±X,±X}}^{(0),}^{_{Nonsecular}} can have non-negligible effects after {N, δ, ψ, ±ψ, φ, φ, −φ, −φ} is repeated many times. In embodiments where it is advantageous to correct for those effects, the average Hamiltonian of more than one {N, δ, ψ, ±ψ, φ, φ, −φ, −φ} block is now considered. The {{N, 0, −Y, −Y, X, X, −X, −X}{N, 0, −Y, −Y, X, X, −X, −X}} of duration 12Δ+2tₚ is exemplary. The parameters of this block can then be picked to optimize the measurements in FIGS. 8, 22, and 10.

In FIGS. 8, 9, and 21A-F, and 23, application of the time-suspension sequence narrows the spectra (˜2 ppm) by a factor of ˜10⁴-10⁵. Because the measured T₂^{effective} approaches T₁/3, it may reflect the very weak dephasing due the environment of the spin system, which is normally obscured by the influence of Hᵢₙₜ=H_{Z}+H_{zz}^{~}.

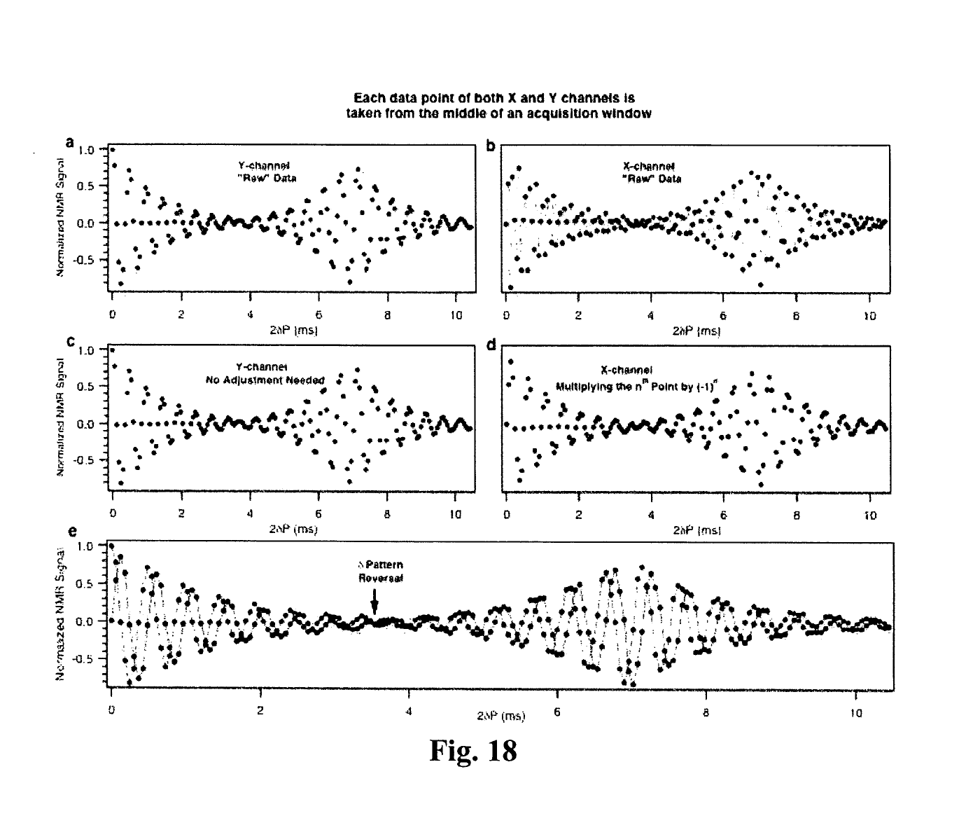

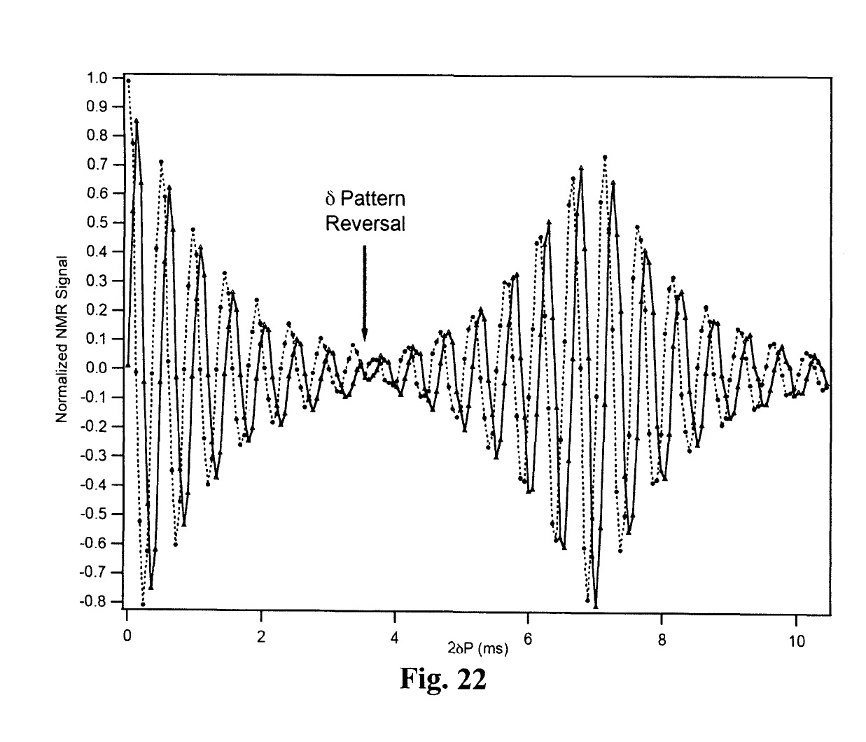

Theory suggests that Ω_{z}^{net} can be directly measured for δ≠0 and ψ₁=ψ₂, as demonstrated in FIG. 22. The signals oscillate as expected for v_{offset}^{global}=−2 kHz, and decay to zero during the first m₁ blocks, which we refer to as a “pseudo-FID”. This may be understood in theory, because (as discussed below) the {N, +δ, ψ₁, ψ₁, X, X, −X, −X} block has unitary operator

$${U}_{{180}_{Y}} {e}^{- \frac{i}{ℏ} ( {Ω}_{z}^{net} {I}_{{z}_{T}} ) ( + 2 δ )} ,$$

where the U₁₈₀_{_{Y}} inverts both Iₓ_{_{T}} and I_{z}_{_{T}}. To account for the effect of U₁₈₀_{_{Y}}, a pattern of a +δ block (i.e., a block with a positive value of delta) followed by a −δ block (i.e., a block with a negative value of delta) must be used, and also the X-channel of the n^{th} echo must be multiplied by (−1)ⁿ, as in FIG. 18. To reverse the sign of the Zeeman evolution, the +δ block, −δ block pattern is switched to a pattern of a −δ block followed by a +δ block at the start of the m₂ blocks, which induces a “pseudo-Hahn echo” just as predicted (FIG. 22). This appears to be a new kind of echo, since the role of the π pulse in the original Hahn echo (Hahn, E. L. Spin Echoes. Phys. Rev. 80, 580 (1950)) is now played by a discontinuity in the timing pattern of the bursts, which are located asymmetrically within the larger composite blocks.

Another exemplary combination sequence,

$${90}_{X} - {\{ \begin{matrix}\begin{matrix}\{ N , δ - Y , - Y , X , X , - X , - X \} - \\ \{ N , δ - Y , - Y , X , X , - X , - X \} -\end{matrix} \\ \begin{matrix}\{ N , δ , Y , Y , X , X , - X , - X \} - \\ \{ N , δ , Y , Y , X , X , - X , - X \}\end{matrix}\end{matrix} \}}^{N} ,$$

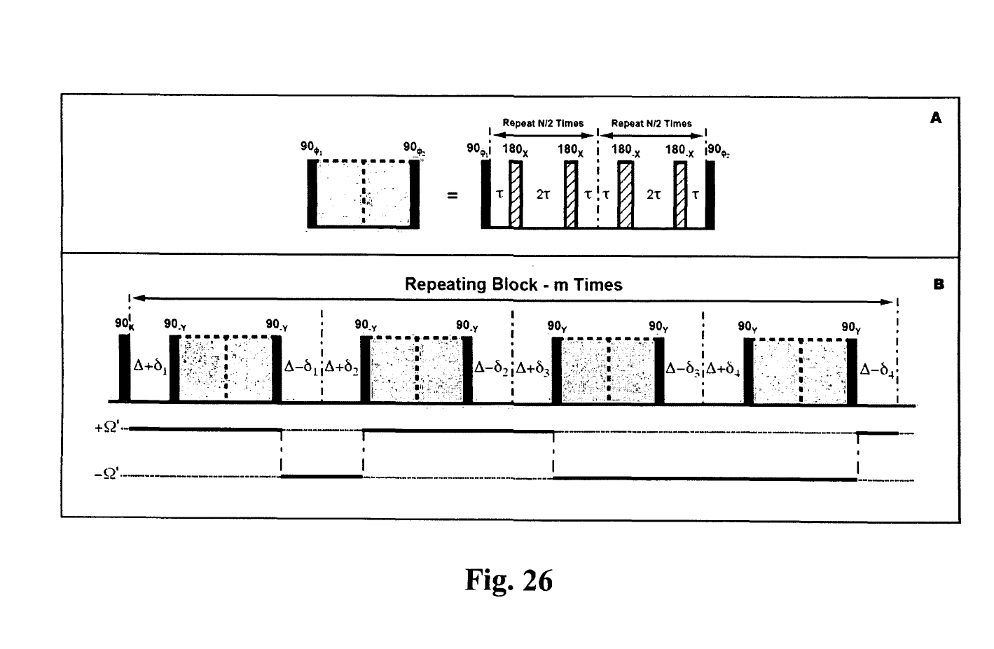

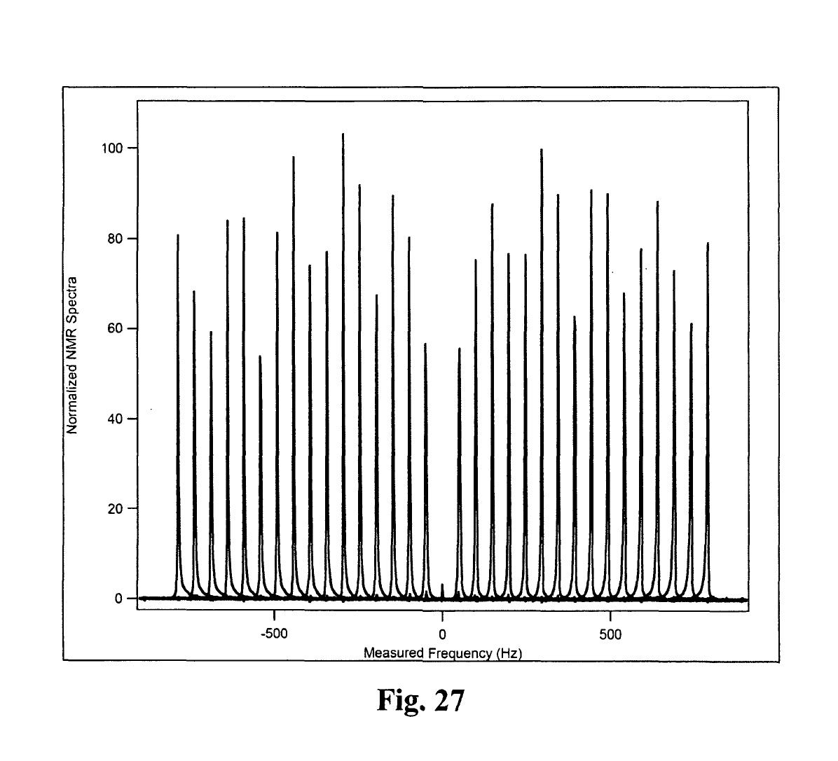

is shown in FIGS. 26A-B. This sequence is an alternative to the sequence used to obtain the results in FIG. 10. As can be seen in FIG. 26B, the sequence is applied with a gradient that changes with time. That is necessary in order to have the peaks offset by a value proportional to ν_{offset} in the frequency domain, because the repeated blocks are external-Zeeman-evolution blocks with same phase wrappers; this was not necessary for the sequence applied to obtain the results in FIG. 10, because the repeating block in that case was a Zeeman-evolution block with opposite phase wrappers. The results of applying this sequence are shown in FIG. 27. As can be seen in comparing FIG. 27 to FIG. 10, the linewidth in FIG. 27 is much narrow. In FIG. 10, the dipolar dephasing was eliminated, and the Zeeman dephasing gave rise to a linewidth of around 260 Hz for each spectrum centered at ν_{offset} (500 Hz spacing). In sequence of FIG. 26A-B, by using same phase wrappers and jumping from +Ω_{offset}^{global} to −Ω_{offset}^{global} at the particular free evolution periods, both the dipolar and Zeeman terms are canceled out over the course of a cycle. The linewidth obtained was around 7 Hz.

Other building blocks can also be used. For example, instead of using the block just discussed, other embodiments of the invention make use of a similar block, (Δ+δ)-90_{ψ}_{₁}-{φ₁,φ₂}^{N/2}{φ₃,φ₄}^{N/2}-90_{ψ}_{₂}-(Δ+δ), still with and with

$$Δ = \frac{{Nt}_{c}}{4} ,$$

and with δ>−Δ, with measurements occurring in the free-evolution periods between repeated blocks of this form. Note that in these embodiments, despite the same definition of Δ, the final free evolution is Δ+δ, unlike the final free evolution period of Δ−δ in certain embodiments discussed above.

6.4.4.3 Additional Theory Behind {N, δ, ψ, ±ψ, φ, φ, −φ, −φ}

The Zeeman-evolution block, the time-suspension block, the external-Zeeman-evolution block, and other blocks of the form {N, δ, ψ, ±ψ, φ, φ, −φ, −φ} are better understood by analyzing the unitary operators representing those blocks.

Consider as an exemplary burst the burst 90_{Y}-{X,X}^{N/2}{−X,−X}^{N/2}-90_{-Y}, which can be uses as a basis for a Zeeman-evolution block, and the case of constant Ω_{z}^{net}. The unitary operator for the burst 90_{Y}-{X,X}^{N/2}{−X,−X}^{N/2}-90_{-Y} is

$${U}_{{180}_{Y}} {e}^{- \frac{i}{ℏ} ( {Ω}_{z}^{net} {I}_{{z}_{T}} ) ( + 2 δ )}$$

for ψ₁=ψ₂, and

$${e}^{- \frac{i}{ℏ} ( {Ω}_{z}^{net} {I}_{{z}_{T}} ) ( + 2 Δ )}$$

for ψ₁≠ψ₂. For constant Ω_{z}^{net}, the “burst” 90_{Y}-{X,X}^{N/2}{−X,−X}^{N/2}-90_{-Y} has

$${U}_{90 - Y} {e}^{- \frac{i}{ℏ} ( \frac{- ( α + 2 β )}{2} {H}_{xx} + {( {κΩ}_{z}^{net} )}^{2} {I}_{{x}_{T}} ) \frac{{Nt}_{c}}{2}} {e}^{- \frac{i}{ℏ} ( \frac{- ( α + 2 β )}{2} {H}_{xx} - {( {κΩ}_{z}^{net} )}^{2} {I}_{{x}_{T}} ) \frac{{Nt}_{c}}{2}} {U}_{{90}_{Y}} = {e}^{- \frac{i}{ℏ} ( \frac{- ( α + 2 β )}{2} {H}_{zz} - {( {κΩ}_{z}^{net} )}^{2} {I}_{{z}_{T}} ) \frac{{Nt}_{c}}{2}} {e}^{- \frac{i}{ℏ} ( \frac{- ( α + 2 β )}{2} {H}_{zz} + {( {κΩ}_{z}^{net} )}^{2} {I}_{{z}_{T}} ) \frac{{Nt}_{c}}{2}} = {e}^{- \frac{i}{ℏ} ( - {H}_{zz} ) ( 2 Δ )} ,$$

where α+2β=1 and

$$Δ = \frac{{Nt}_{c}}{4} .$$

This burst, which works in the limit ∥H_{Z}∥≧∥H_{zz}∥, results in negative dipolar evolution, but no net Zeeman evolution.

A useful composite block is constructed by surrounding a more general burst with free evolution periods 90_{ψ}_{₁}-{X, X}^{N/2} {−X,−X}^{N/2}-90_{ψ}_{₂} or {N, δ, ψ₁, ψ₂, X, X, −X, −X}, where |δ|≦Δ, and ψᵢ±Y for i=1,2. The sequence {N, δ, ψ₁, ψ₂, X, X, −X, −X} has no net dipolar evolution over duration 6Δ, because the effective unitary operator is

$${U}_{{180}_{Y}} {e}^{- \frac{i}{ℏ} ( {Ω}_{z}^{net} {I}_{{z}_{T}} ) ( + 2 δ )}$$

for ψ₁=ψ₂, and

$${e}^{- \frac{i}{ℏ} ( {Ω}_{z}^{net} {I}_{{z}_{T}} ) ( + 2 Δ )}$$

for ψ₁≠ψ₂.

This model predicts that both Zeeman and dipolar phase are refocused after each {N, 0, ψ₁, ψ₁, X, X, −X, −X} block, yielding the time-suspension sequence discussed above. Indeed, using a Tecmag LapNMR “synth8” spectrometer, the sequence herein pushes the decay time out to ˜10¹⁰ periods of Larmor precession, or T₂^{effective}˜110 seconds, quite close to the spin-lattice relaxation time, T₁=290 seconds (the dots of FIG. 8). The normal linewidth (FIG. 8, inset dashed line spectrum) is thus reduced by a factor of ˜70,000 (FIG. 8, inset solid line spectrum). Next, for δ≠0, FIG. 22 shows how Ω_{z}^{net} may be detected by the Zeeman dephasing of a pseudo-FID, and subsequently by a pseudo-Hahn echo after a reversal of the δ-pattern (see FIGS. 18, 21A-F and 23).

6.4.5 The Novelty of the Exemplary Sequences and Methods

For all of the exemplary sequences and embodiments of the instant invention, taking the limit of delta-function pulses (tₚ→0) would eliminate the transverse field terms in H̅⁽⁰⁾+ H̅⁽¹⁾ exploited by the sequences disclosed herein (e.g., −λΩ_{z}^{net}Iₓ_{_{T}} and −(κΩ_{z}^{net})₂Iₓ_{_{T}}). Thus, the surprising discovery of the limitations of the delta-function approximation and corresponding significance of the internal structure of the hard π pulses allowed for the invention of the systems and methods disclosed herein which put the discovery of these transverse field terms to use.

### 6.5 TOLERANCE IN PULSE SEQUENCES

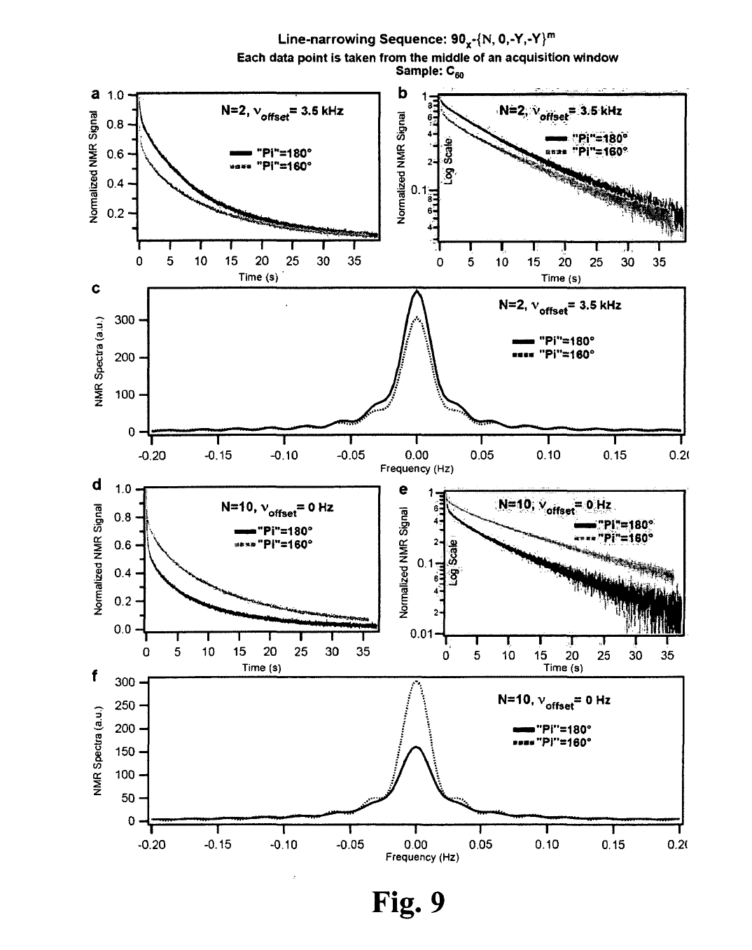

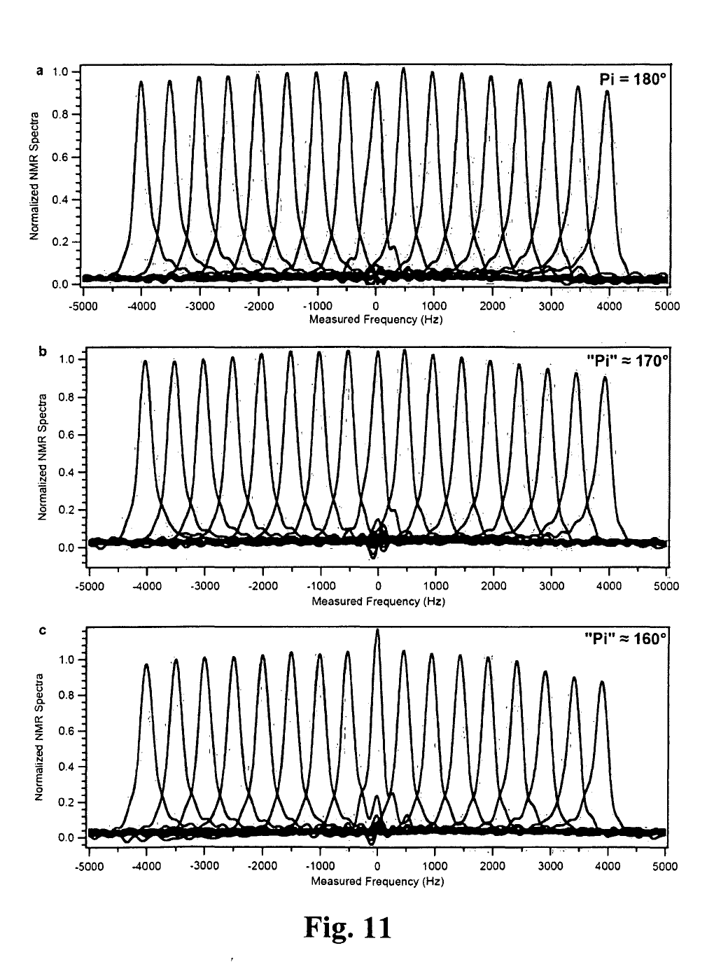

Tolerance in 180°(π) and 90°(π/2) pulses. An “approximate π pulse” is to be considered applicable to any description herein relating to “π pulse” or “180° pulse”. The approximate 180° pulses are preferably 160° to 200° and more preferably 170° to 190°. FIGS. 9 and 11 illustrate how exemplary sequences still work for approximate 180° pulses within the preferable and more preferable ranges. Similarly, an “approximate π/2 pulse” is to be considered applicable to any description herein relating to “π/2 pulse” or “90° pulse”. The approximate π/2 pulse is considered to have a similar amount of tolerance as the 180° pulses, i.e., the approximate 90° pulses are preferably from 80° to 100° and more preferably from 85° to 95°.

Tolerance in pulse times. Any duration of any 180 pulses are to be considered approximate with a similar amount of tolerance as the 180 pulse itself, i.e., for a pulse of length tₚ, the length of the pulse is preferably from 0.90 tₚ to 1.10 tₚ and more preferably from 0.95 tₚ to 1.05 tₚ.

Tolerance in durations of periods of free evolution. Any duration of any period of free evolution discussed herein are to be considered to be approximate durations. If in a sequence τ₁≈τ₂≈τ₃≈τ, then the value errors in the value of τ₁, τ₂, and/or τ₃ is preferably less than the duration of tₚ.

Tolerance in ν_{offset}. FIGS. 21A-C show the results of measurements obtained using the time-suspension sequence block for differing values of Ω_{offset}^{global}, namely, 0 Hz, 3.5 Hz and 4.5 Hz. The values of Ω_{offset}^{global} can be take on any value disclosed herein in connection with any embodiment. In different embodiments, Ω_{offset}^{global} may be any value between 0 Hz and 3 kHz, for example, the values of Ω_{offset}^{global} may vary in steps of 50 Hz, 100 Hz or 200 Hz between 0 Hz and 3 kHz. In other embodiments, may take on any value up to 4 kHz, up to 8 kHz, 16 kHz, 20 kHz, 25 kHz or greater than 25 kHz. In other applications, such as ESR, the value of Ω_{offset}^{global} may be even larger.

Selection of X, Y, Z. Positive Z is conventionally taken to be the direction of the external magnetic field. Given that, X and Y can be selected in any arbitrary direction so as to form a right-handed coordinate system Thus, for any sequence discussed herein, even if not explicitly stated, it is possible to substitute X with Y and Y with −X.

Tolerance in complete cycle property when sequences viewed through delta function approximation. Plurality of spin species are returned at the end of said pulse sequence to substantially the same orientation as said plurality of spin species had prior to applying said pulse sequence. The term “substantially the same orientation” encompasses deviations of up to 5°, 10°, 15°, 20°, or 25° or more, from the original orientation prior to application of the pulse sequence.

Tolerance in “N” within {N, δ, ψ₁, ψ₂, φ₁, φ₂, φ₃, φ₄} block. FIG. 21D-F show the results of measurements obtained using the time-suspension sequence block 90_{X}-{N, 0, −Y, −Y, X, X, −X, −X}^{m} for differing values of N, which shows the tolerance in values of N ranging from as low as 2, up to a value of N=20. The value of N can take on any positive even integer value greater than or equal to two. As non-limiting examples, N can be 2, 4, 8, 16, 50, 100, 150, 200, 300, 1000 or any even integer value in between. In certain embodiments, N can be an even integer value greater than 1000. In specific embodiments, N can take on any value disclosed herein for the number of times any sequence block disclosed herein is repeated.

Tolerance in pulse strength. Since pulse strength varies across a big sample, the uniform pulse assumption of our model contains some range of flexibility. An intentional uniform misadjustment of all pulse angles leads to similar MRI top-hat lineshapes (see, e.g., FIG. 11) and to similar line-narrowing performance (see, e.g., FIG. 9), indicating that these two sequences are robust.

### 6.6 EXEMPLARY SAMPLES

The methods and systems disclosed herein are applicable to imaging of a solid or a solid in the presence of a liquid, using any isotope that can be used for NMR analysis. The ¹³C isotope, which is measured in some of the examples herein, occurs in low percentages in natural carbon. The isotope ¹⁵N is also relatively commonly used, as it can be used for labeling compounds. The isotope ¹⁹F is also fairly commonly measured. The isotope ³¹P, measurements for which in bone is disclosed herein, occurs in 100% of natural phosphorus; it also may be probed in other biochemical studies. The isotope ⁴³Ca may be used in biochemistry to study calcium binding to DNA, proteins, etc. The isotope ¹⁹⁵Pt may be used in studies of catalysts and complexes. Other measurable nuclei include, usually used in the studies of their complexes and chemical binding, or to detect presence of the element ¹⁷O, ¹⁰B, ¹¹B, ³⁵Cl, ³⁷Cl, ³⁵Cl, ³⁷Cl, ¹⁹⁵Pt, ⁶Li, ⁷Li, ⁹Be, ¹⁹F, ²¹Ne, ²³Na, ²⁵Mg, ²⁷Al, ²⁹Si, ³¹P, ³³S, ³⁹K, ⁴⁰K, ⁴¹K, ⁴⁵Sc, ⁴⁷Ti, ⁴⁹Ti, ⁵⁰V, ⁵¹V, ⁵³Cr, ⁵⁵Mn, ⁵⁷Fe, ⁵⁹Co, ⁶¹Ni, ⁶³Cu, ⁶⁵Cu, ⁶⁷Zn, ⁶⁹Ga, ⁷¹Ga, ⁷³Ge, ⁷⁷Se, ⁸¹Br, ⁸⁷Rb, ⁸⁷Sr, ⁹⁵Mo, ¹⁰⁹Ag, ¹¹³Cd, ¹²⁵Te, ¹²⁷I, ¹³³Cs, ¹³⁵Ba, ¹³⁷Ba, ¹³⁹La, ¹⁸³W, and ¹⁹⁹Hg.

6.6.1 Spins and Pseudospins With Appropriate Hamiltonian

While working in the ∥Hz∥>=∥Hzz∥ range also to some extent for ∥Hz∥<|Hzz|. If ∥Hzz∥ is much larger than ∥Hz_int∥, one can increase ∥Hz∥ by applying a resonance offset or gradient field, and thereby enter the appropriate range. Related effects can occur for a wider variety of Hᵢₙₜ and Hₚ_{_{φ}} than we have treated here, provided that [H_{P}_{_{φ}}, Hᵢₙₜ]≠0. Shaped pulses, soft pulses, and strongly-modulated pulses have proven to be important elements of the NMR toolbox. Exploiting the internal structure of hard π pulses provides experimentalists with yet another technique to control the coherent evolution of quantum systems.

Pseudospins is an abstraction used to describe other systems that exhibit spin-like behavior if the Hamiltonian describing that system can be expressed as a Zeeman-like term (i.e., a term linear if a state) and a dipolar-like term (a term bilinear in a state). It has been shown in the art that a system such as quantum dots can act as a pseudospin ½. The methods described herein for spin species may be applied to pseudospins species.

6.6.2 Bones and Teeth

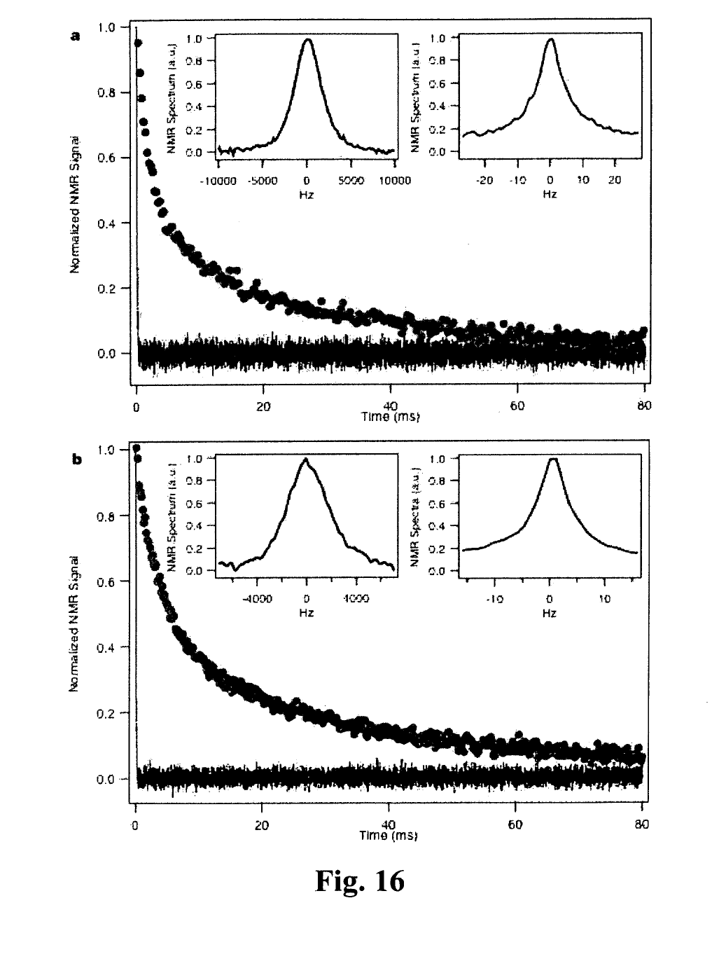

The sequences disclosed herein may assist in the study of some important biomaterials, since the Hᵢₙₜ assumed here is very similar to that of ³¹P in bones and teeth. Wu, et al., Multinuclear Solid-State Three-Dimensional MRI of Bone and Synthetic Calcium Phosphates. Proc. Natl. Acad. Sci. USA 96, 1574 (1999); Wu, et al., Nuclear Magnetic Resonance Spin-Spin Relaxation of the Crystals of Bone, Dental Enamel, and Synthetic Hydroxyapatites. J. Bone Miner. Res. 17, 472 (2002). FIG. 16 shows the results of measurements of phosphorus (³¹P), which show the utility of the instant invention.

6.6.3 Protons

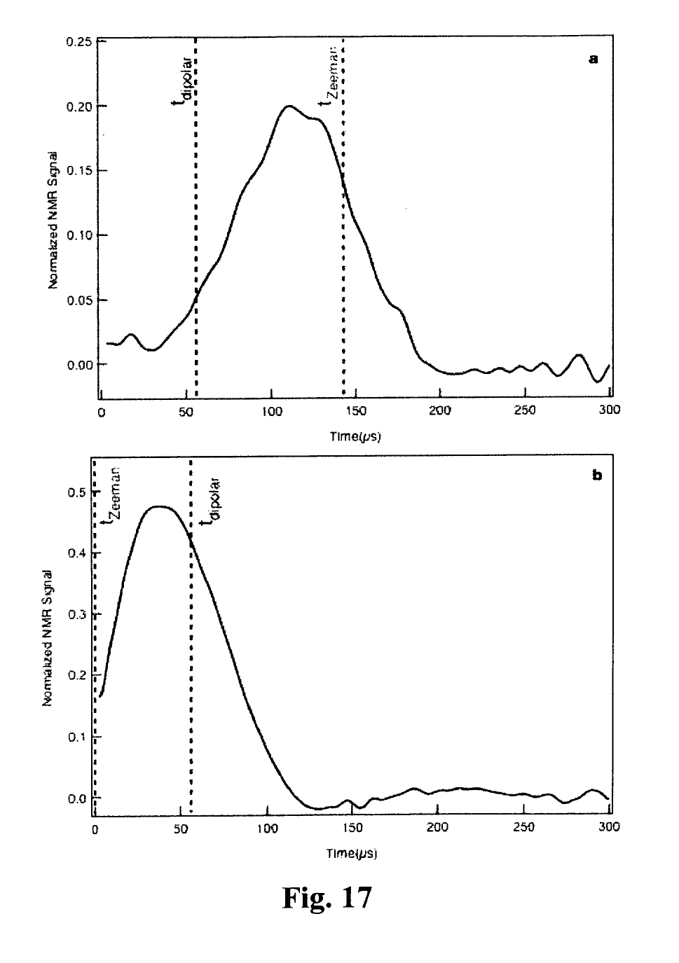

These sequences also have potential applications in proton (¹H) NMR. While the dipolar linebreadth dominates most ¹H spectra, a large Ω_{offset}^{global} can be used to reach the ∥H_{Z}∥≧∥H_{zz}∥ limit of our model, as demonstrated in preliminary results on Adamantane (FIG. 17). The use microcoils would allow even shorter tₚ (and thus t_{c}), which should improve the utility of the methods disclosed herein for proton NMR experiments. Peck, et al., Design and Analysis of Microcoils for NMR Microscopy, J. Magn. Reson. B 108, 114 (1995); Yamauchi, et al., Implementing Solenoid Microcoils for Wide-Line Solid-State NMR, J. Magn. Reson. 167, 87 (2004); Sakellariou, et al., High-resolution, high-sensitivity NMR of nanolitre anisotropic samples by coil spinning. Nature 447, 694 (2007).

6.6.4 Mixed Solid and Liquid Samples

The methods disclosed herein are applicable to imaging or microscopy of a solid sample even in the presence of a liquid. Thus, the methods of the invention are applicable to measurements on human tissue and structure, where a solid (such as bone or teeth), is to be measured in the presence of a liquid (body fluids and tissue). The methods are also applicable to polymer systems which include a solid material imbedded therein.

### 6.7 EXEMPLARY APPLICATIONS

6.7.1 MRI/MRM of Solid

Eliminating dipolar dephasing in order to measure Ω_{z}^{net} in applied magnetic field gradients enables the magnetic resonance imaging (MRI) or microscopy of solids. Measuring the spectrum in a field gradient is the first step toward imaging using the back-projection technique. FIG. 10 shows a faithful reproduction of an input top-hat spectrum, where each spectrum is the Fourier transformation of the pseudo-FID resulting from two interlaced data sets (FIG. 12A-F). It should be noted that both the signal amplitude and the ν_{offset} values have been quite accurately reconstructed in this approach. Compared to existing approaches for the MRI of solids, our approach does not need to switch off the applied Zeeman gradient inside the bursts, which enables the application of large field gradients at moderate cost. It should also be possible to implement standard frequency- and phase-encoding methods using this approach.

Since pulse strength varies across a big sample, the uniform pulse assumption of our model is a potential concern. An intentional uniform misadjustment of all pulse angles leads to similar MRI top-hat lineshapes (FIG. 11) and to similar line-narrowing performance (FIG. 9), suggesting that these two sequences are robust.

FIG. 27 shows a novel MRI boxtop with much narrower linewidth centered at different values of ν_{offset} (with 50 Hz spacing). FIGS. 26A-B illustrate the pulse sequence used in FIG. 27. FIG. 27 is a variation of FIG. 10. In FIG. 10, the dipolar dephasing is eliminated and the Zeeman dephasing gives rise to the linewidth of around 260 Hz for each spectrum centered at ν_{offset} (with a 500 Hz spacing). In FIG. 27, by using the π/2 wrapper pulses in the +Y and −Y direction as shown in FIG. 26B, and jumping from +Ω_{offset}^{global} to −Ω_{offset}^{global} during different periods of the sequence as shown in FIG. 26B, both the dipolar and Zeeman terms are canceled out on the cycle basis. Each trace in FIG. 27 should be extremely narrow; the real data gives each peak a linewidth of around 7 Hz.

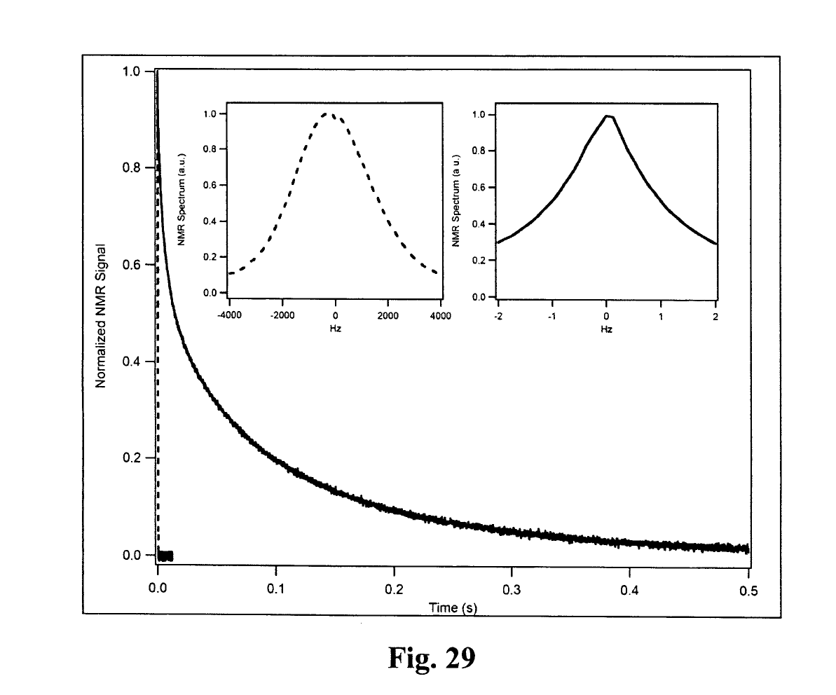

FIG. 29 shows results of a ³¹P time-suspension measurement in a human deciduous tooth. Line narrowing sequence 90_{X}-{2, 0, −Y, −Y}^{m} was applied, with τ=5 μs, m=15000, ν_{offset}=7 kHz and ω₁/(2π)=50 kHz. The normal linewidth of the free induction decay (FID) spectrum (3.6 kHz) is narrowed by a factor of 1200 down to 3 Hz.

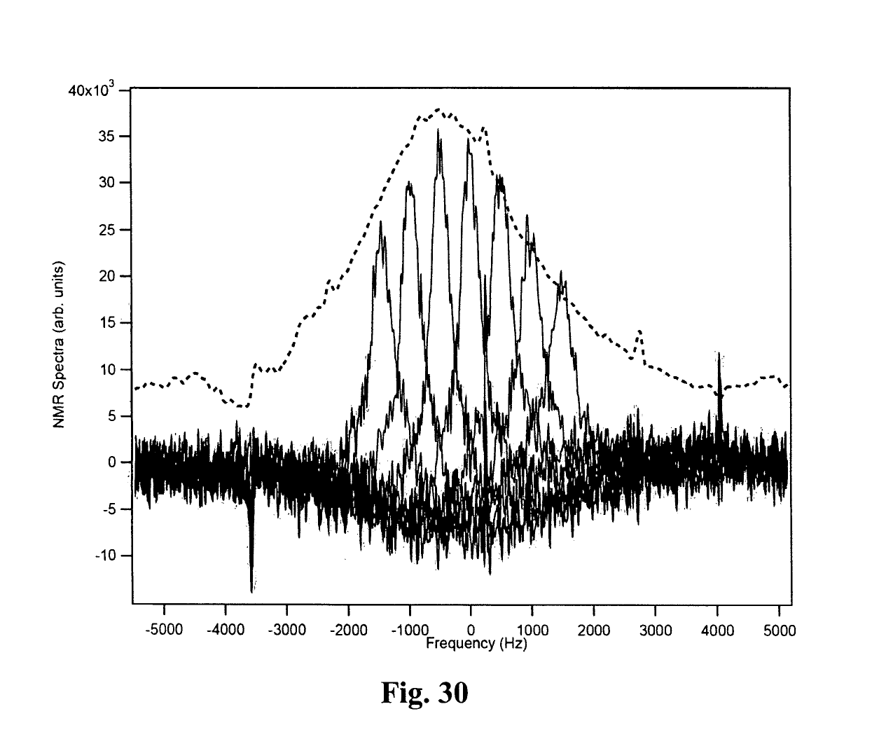

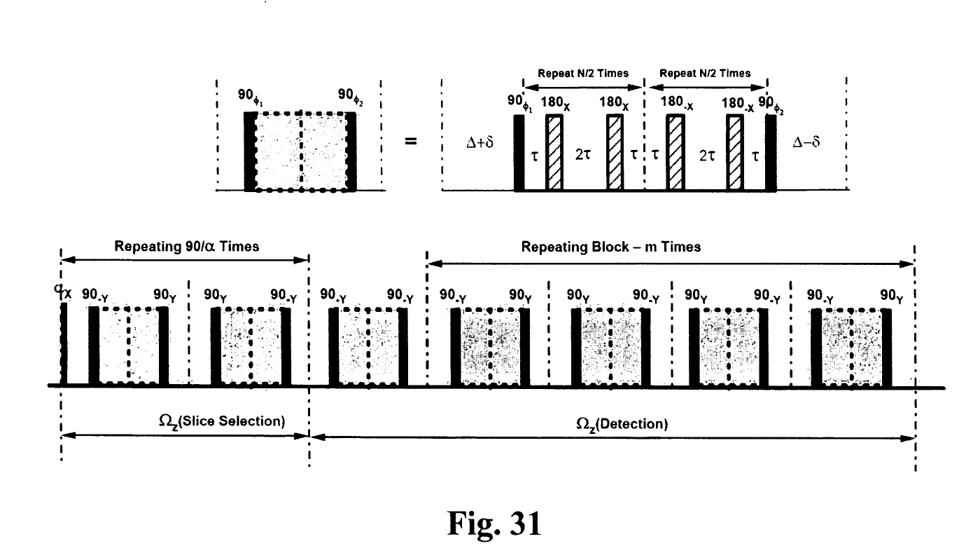

FIG. 30 demonstrates the possibility of doing slice selection using the block {N, δφ1, φ2, X, X, −X, −X} together with a DANTE 90 pulse. In a DANTE 90 pulse, a pulse is applied to the spin species which rotates the spin species by an angle α (which is a fraction of the 90° angle), followed by a pulse block or pulse sequence, followed by another rotation by angle α, followed by a pulse block or pulse sequence, the sequence being repeated the number of times for the rotations by angle α to total 90°. FIG. 31 illustrates the pulse sequence used to get the five slices at −1500 Hz, −1000 Hz, −500 Hz, 0 Hz, 500 Hz, 1000 Hz, 1500 Hz (the solid lines in FIG. 30), where the αₓ-{2, 0, −Y, Y, X, X, −X, −X}-{2, 0, −Y, Y, X, X, −X, −X} is repeated 90/α times to get DANTE 90 pulse (α=4.5° in FIG. 31). The dashed line in FIG. 30 shows the spectrum obtained by replacing the DANTE 90 pulse by a hard 90° pulse, and its magnitude is scaled down by a factor of 2 to match the five solid line slices.

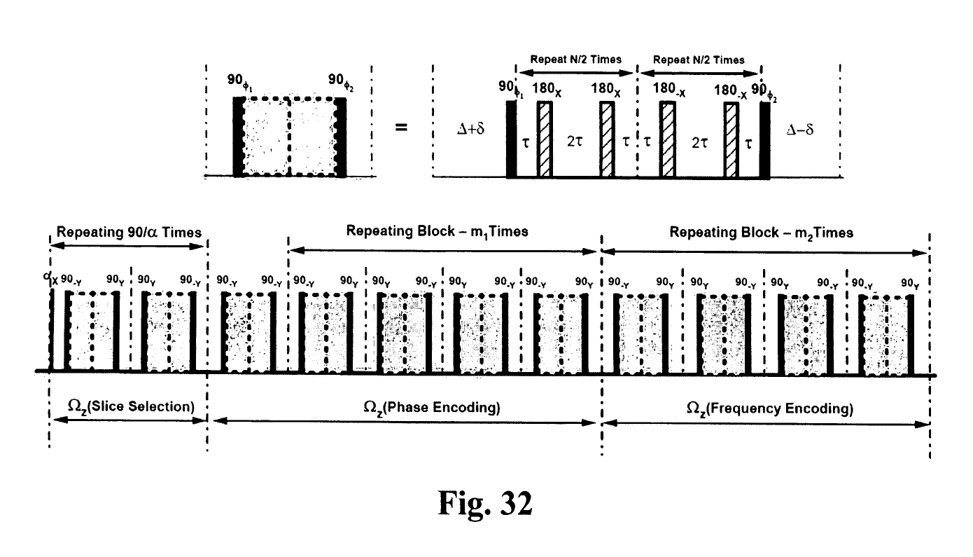

In a general 3D imaging measurement, the steps include applying slice selection (Gz=dBz/dz), phase encoding (Gx=dBz/dx), and then frequency encoding (Gy=dBz/dy), where G_{χ}.=dBz/dx is a magnetic field gradient (χ=x, y or z). A slice selection pulse sequence is applied in presence of Gz first, then Gz is turned off and Gx is turned on for a time to do phase encoding (which basically involves moving spins in x-y plane, but not measuring them yet), then Gy is turned on for a time while measuring signal to do frequency encoding. The last step could also be phase encoding, if Gy is turned off before measuring. According to an embodiment of the invention, after the slice selection step, one or more pulse sequence blocks could be applied during the Gx and Gy gradient intervals. FIG. 32 illustrates a variation of the pulse sequence in FIG. 31, where both Phase Encoding and Frequency Encoding are included.

6.7.2 Magic Angle Spinning

All methods, systems, and apparatus disclosed herein may also be used to supplement, modify, or to improve the performance of the well-known “Magic Angle Spinning” (MAS) measurements, an invaluable tool in solid-state NMR. The value of combining pulsed control of coherence with MAS has been demonstrated previously for other classes of pulse sequences (S. Hafner, et al., “Advanced Solid-State NMR Spectroscopy of Strongly Dipolar Coupled Spins Under Fast Magic Angle Spinning”, Concepts Magn. Reson. 10, 99 (1998)) including the magic sandwich echo (D. E. Demco et al., “Rotation-Synchronized Homonuclear Dipolar Decoupling,” J. Magn. Reson. A 116, 36 (1995)), and the same ideas apply to the methods, systems, and apparatus disclosed herein. For example, pulses that are applied synchronously with the period of sample rotation may be used to either improve upon the MAS reduction of the dipolar linewidth (also referred to as improving decoupling), or can be used to intentionally reintroduce dipolar contributions to the spin evolution (also referred to as recoupling). Combining the methods, systems, and apparatus disclosed herein with MAS enables the generation of new classes of effective Hamiltonians.

6.7.3 Electron Spin Resonance

Electron spin resonance (ESR) spectroscopy (or electron paramagnetic resonance (EPR)) is used for studying chemical species that have one or more unpaired electrons, such as organic and inorganic free radicals or inorganic complexes possessing a transition metal ion. Although it is electron spins that are excited instead of spins of atomic nuclei, the basic physical concepts of ESR are analogous to those of nuclear magnetic resonance (NMR). The ESR technique is less widely used than NMR, because most stable molecules have all their electrons paired. The limitation to species with unpaired spins, i.e., paramagnetic species can also be beneficial, since the ESR technique is one of great specificity (ordinary chemical solvents and matrices do not give rise to ESR spectra).

### 6.8 EXEMPLARY EQUIPMENT

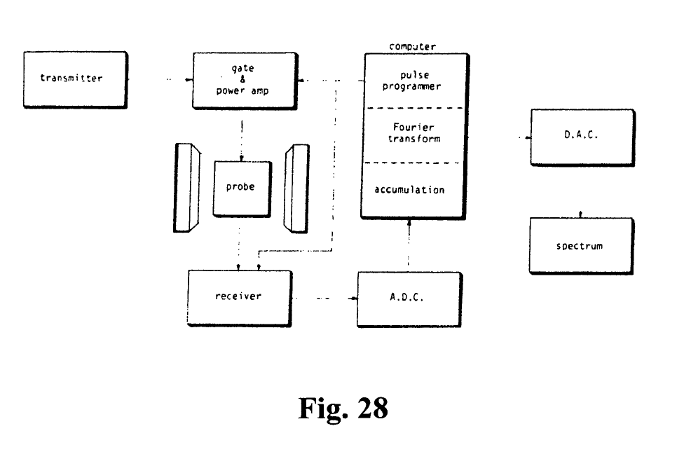

FIG. 28 shows a block diagram of an exemplary NMR system, which includes a spectrometer, a data system, and software. The spectrometer includes the magnet which provides the constant external magnetic field, the probe which contains the sample to be measured, RF circuitry, a pulse transmitter and receiver circuit connected to probe. The data system includes the computer interface, the central processing unit (CPU), and any peripheral devices which are connected to the CPU. Most magnets are of the superconducting type, however, various systems may use electromagnets.

The probe is a key component of the spectrometer. It is positioned within the bore of the magnet, and contains the sample within the bore during measurements. The probe also provides necessary hardware to permit the sample temperature to be varied, and when necessary, to spin the sample (such as during magic angle spinning). The probe also houses one or more excitation coils and associated electronics for providing the excitations to the sample (e.g., the RF excitation pulses) and one or more receiver coils for detection of the NMR signal.

From the frequency generation module, the RF frequency is fed into the transmitter, whose function is to amplify the signal and apply it to the transmitter coil. The transmitter includes a RF switch or gate, whose function is to switch on and off the RF pulse at the desired times, and a pulse amplifier which amplifies the signal to the probe.

The computer comprises a CPU which includes pulse programmer, optionally a module for applying a Fourier transform algorithm, and physical storage media for the accumulated signal. The pulse programmer provides the timing for the pulses, such as the RF pulses. The pulse programmer sends control signals to the transmitter to switch the gates for the timing of the pulses. The pulse programmer controls the duration of application of the pulses, as well as the time durations between the pulses.

The precession of the nuclei following an excitation induces a voltage in the receiver coil which is detected. An analog to digital converter (A.D.C.) produces a digital presentation of the signal measured (e.g., a free-induction-decay, an echo signal, etc.). The NMR system may also comprise a digital to analog converter (D.A.C.) if the processed NMR spectrum is displayed on an oscilloscope. Alternatively, the D.A.C. is absent and the spectrum is displayed from the computer to a user interface device.

Major NMR instrument makers include Oxford Instruments, Bruker, General Electric, JEOL, Kimble Chase, Philips, Siemens AG, Varian, Inc. and SpinCore Technologies, Inc.

Magnetic Resonance Imaging/Microscopy (MRI/MRM) Instrumentation

A MRI instrument typically includes a magnet for producing a constant external magnetic field Bₒ field for the imaging procedure, and gradient coils located within the magnet for producing a gradient in Bₒ in the X, Y, and Z directions. One or more RF coils, located within the gradient coils, produce the RF pulse magnetic fields for rotating the spin species by π, π/2, or any other value selected by the pulse sequence applied. The RF coil also detects the signal from the spin species within a patient's body. The patient is positioned within the bore of the magnet, gradient coils, and RF coil by a computer controlled patient table.

A computer controls the RF components of the MRI/MRM, including a RF source and the pulse programmer. The pulse programmer shapes the RF pulses into apodized sinc pulses, while the RF amplifier increases the RF pulses power. The computer also controls the gradient pulse programmer which sets the shape and amplitude of each of the three gradient fields (i.e., the X, Y, and Z directions). A gradient amplifier increases the power of the gradient pulses to a level sufficient to drive the gradient coils.

Some imagers may include an array processor, which array processor is capable of performing a two-dimensional Fourier transform faster than the computer. Thus, in these systems, the computer would send the data to the array processor for the Fourier transform analysis.

An operator of the MRI/MRM gives input to the computer through a user interface device, such as a control console. An imaging sequence comprising a set of RF pulse sequences is selected and customized from the console. The operator can see the images on a video display located on the console or can make hard copies of the images on a film printer.

### 6.9 EXEMPLARY APPARATUS AND COMPUTER-PROGRAM IMPLEMENTATIONS

The methods of the present invention can preferably be implemented using a an apparatus, e.g., a computer system, such as the computer system described in this section, according to the following programs and methods. Such a computer system can also preferably store and manipulate measured signals obtained in various experiments or measurements that can be used by a computer system implemented with the analytical methods of this invention. Accordingly, such computer systems are also considered part of the present invention.

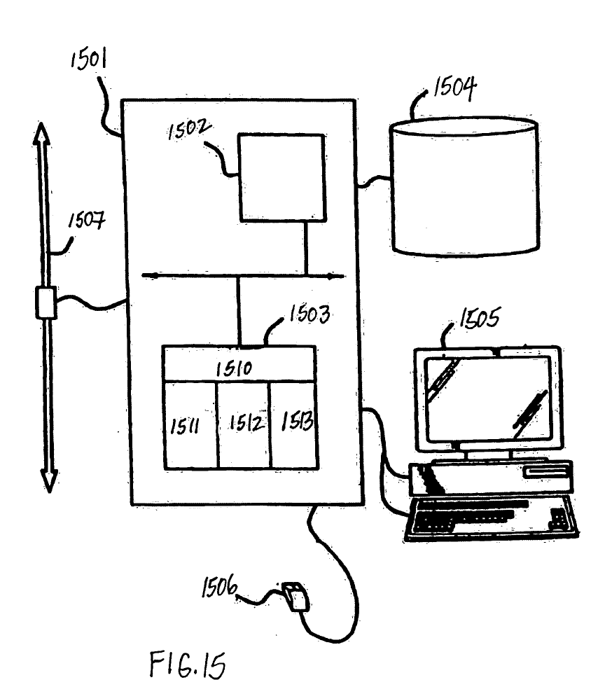

An exemplary computer system suitable from implementing the methods of this invention is illustrated in FIG. 15. Computer system 1501 is illustrated here as comprising internal components and as being linked to external components. The internal components of this computer system include one or more processor elements 1502 interconnected with a main memory 1503. For example, computer system 1501 can be an Intel Pentium IV®-based processor of 2 GHZ or greater clock rate and with 256 MB or more main memory. In a preferred embodiment, computer system 1501 is a cluster of a plurality of computers comprising a head “node” and eight sibling “nodes,” with each node having a central processing unit (“CPU”). In addition, the cluster also comprises at least 128 MB of random access memory (“RAM”) on the head node and at least 256 MB of RAM on each of the eight sibling nodes. Therefore, the computer systems of the present invention are not limited to those consisting of a single memory unit or a single processor unit.

The external components can include a mass storage 1504. This mass storage can be one or more hard disks that are typically packaged together with the processor and memory. Such hard disk are typically of 10 GB or greater storage capacity and more preferably have at least 40 GB of storage capacity. For example, in a preferred embodiment, described above, wherein a computer system of the invention comprises several nodes, each node can have its own hard drive. The head node preferably has a hard drive with at least 10 GB of storage capacity whereas each sibling node preferably has a hard drive with at least 40 GB of storage capacity. A computer system of the invention can further comprise other physical, user-accessible mass storage units including, for example, one or more floppy drives, one more CD-ROM drives, one or more DVD drives or one or more DAT drives.

Other external components typically include a user interface device 1505, which is most typically a monitor and a keyboard together with a graphical input device 1506 such as a “mouse.” The computer system is also typically linked to a network link 1507 which can be, e.g., part of a local area network (“LAN”) to other, local computer systems and/or part of a wide area network (“WAN”), such as the Internet, that is connected to other, remote computer systems. For example, in the preferred embodiment, discussed above, wherein the computer system comprises a plurality of nodes, each node is preferably connected to a network, preferably an NFS network, so that the nodes of the computer system communicate with each other and, optionally, with other computer systems by means of the network and can thereby share data and processing tasks with one another.

Loaded into memory during operation of such a computer system are several software components that are also shown schematically in FIG. 15. The software components comprise both software components that are standard in the art and components that are special to the present invention. These software components are typically stored on mass storage such as the hard drive 1504, but can be stored on other physical, user-accessible computer readable media as well including, for example, one or more floppy disks, one or more CD-ROMs, one or more DVDs or one or more DATs. Software component 1510 represents an operating system which is responsible for managing the computer system and its network interconnections. The operating system can be, for example, of the Microsoft Windows™ family such as Windows 95, Window 98, Windows NT, Windows 2000 or Windows XP. Alternatively, the operating software can be a Macintosh operating system, a UNIX operating system or a LINUX operating system. Software components 1511 comprises common languages and functions that are preferably present in the system to assist programs implementing methods specific to the present invention. Languages that can be used to program the analytic methods of the invention include, for example, C and C++, FORTRAN, PERL, HTML, JAVA, and any of the UNIX or LINUX shell command languages such as C shell script language. The methods of the invention can also be programmed or modeled in mathematical software packages that allow symbolic entry of equations and high-level specification of processing, including specific algorithms to be used, thereby freeing a user of the need to procedurally program individual equations and algorithms.

Software component 1512 comprises any methods of the present invention described supra, preferably programmed in a procedural language or symbolic package. For example, software component 1012 preferably includes programs that cause the processor to implement steps of accepting a plurality of measured resonance signals and storing the measured resonance signals in the memory. For example, the computer system can accept commands for generating the pulse sequences that are manually entered by a user (e.g., by means of the user interface). More preferably, however, the programs cause the computer system to retrieve measured resonance signals from a database. Such a database can be stored on a mass storage (e.g., a hard drive) or other computer readable medium and loaded into the memory of the computer, or the compendium can be accessed by the computer system by means of the network 1507.

In addition to the exemplary program structures and computer systems described herein, other, alternative program structures and computer systems will be readily apparent to the skilled artisan. Such alternative systems, which do not depart from the above described computer system and programs structures either in spirit or in scope, are therefore intended to be comprehended within the accompanying claims.

### 7. EXAMPLES

FIGS. 1A-C, 4D, 7E, 7F, 8, 9, 10, 11, 12, 16, 17, 18, 20, 21, 22, 23, 27, 29 and 30 represent examples of certain embodiments of the invention that were carried out, and which are discussed hereinabove or hereinbelow. Certain examples of embodiments of the present invention have been discussed previously. This section provides additional examples or further discusses some of the examples already discussed hereinabove.

### 7.1 Echo

7.1.1 Echo of the Echo Train

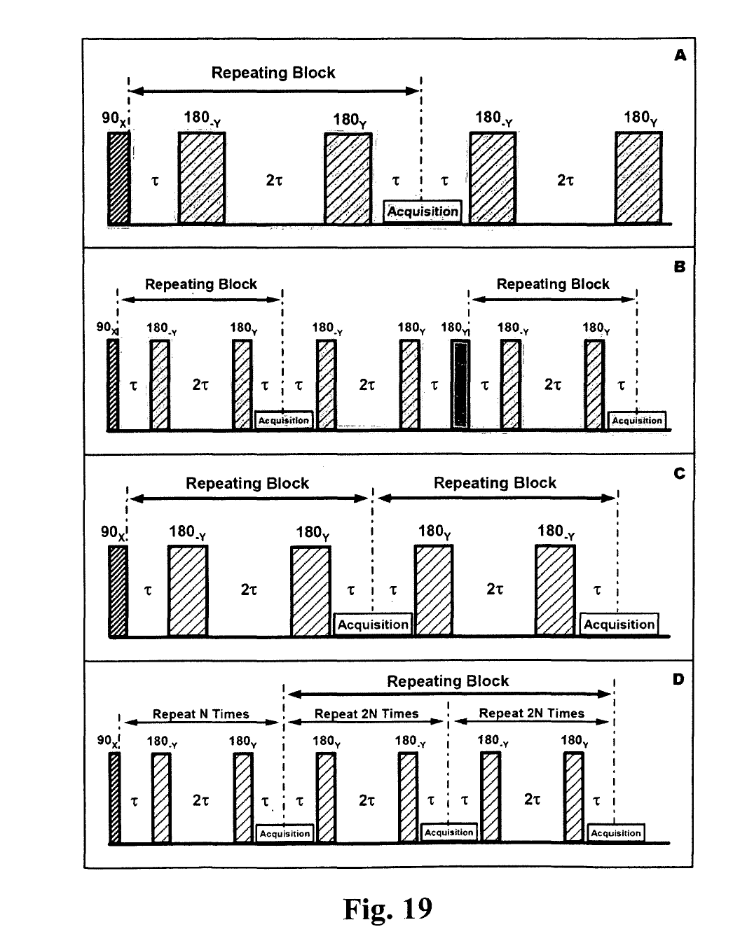

FIG. 2A illustrates the APCPMG pulse sequence. FIG. 2B illustrates the sequence 90_{X}-{−Y,Y}^{N1}-180_{Y}-{−Y,Y}^{N2}, where N₁ and N₂ are integers greater than or equal to one and represent the number of times each of the respective repeating blocks is repeated. FIG. 2C illustrates the sequence 90_{X}-{−Y,Y}^{N1}-{Y,−Y}^{N2}, where N₁ and N₂ are integers greater than or equal to one and represent the number of times each of the respective repeating blocks is repeated. FIG. 2D illustrates repeated application of the sequence of FIG. 2C. FIG. 19A-D illustrates the pulse sequences of FIGS. 2A-D, but with signal acquisition periods included during certain periods of free evolution. As discussed in Section 6.3, the APCPMG pulse sequence was modified with the introduction of a 180_{Y} pulse (see, e.g., FIGS. 2B and 19B), which produces an ‘echo of the echo train’ (FIG. 1B). Although the spectrum of FIG. 1B looks like a conventional Hahn echo, the signal actually extends over more than 800 individual spin echo peaks.

7.1.2 Reversing Zeeman and Dipolar Phase Wrap

FIG. 20 shows three echoes obtained NMR measurements obtained using the same sequences as in FIGS. 2A-D, but measured in a Silicon powder (²⁹Si) sample lightly-doped with Antimony (Si:Sb, with ˜10¹⁷ Sb/cm³), at room temperature. The pulse strength of ω₁/2π=35.2 kHz is approximately 145 times bigger than the 240 Hz linewidth of ²⁹Si, with a 101.56 MHz Larmor frequency, at B=12 Tesla. N=140 and τ=14 μs. The signal in FIG. 20 is normalized to the amplitude of the normal FID signal in the sample.

7.1.3 C₁₀H₁₆

FIG. 17 shows proton NMR in adamantane (C₁₀H₁₆) at room temperature. FIG. 17A shows an echo obtained using the sequence {−X, X}^{N}-90ₓ, as in FIGS. 2A-D, but with ν_{offset}=−25 kHz. FIG. 17B shows an improved echo using the composite sequence {−X, X}^{N/2}-{X, −X}^{N/2}-90₋ₓ and ν_{offset}=25 kHz. The pulse strength ω₁/2π≈89.3 kHz is approximately 6 times bigger than the 15 kHz linewidth of ¹H in adamantane, with a 127.79 MHz Larmor frequency, at B=3 Tesla. N=20 and τ=5.6 μs. The signal in FIGS. 17A-B are normalized to the amplitude of the normal FID signal in the sample.

### 7.2 Line Narrowing

In FIGS. 8, 9, 21A-F, and 23, the time-suspension sequence narrows the spectra (˜2 ppm) by a factor of ˜10⁴-10⁵. Since the measured T₂^{effective} approaches T₁/3, it may reflect the very weak dephasing due the environment of the spin system, which is normally obscured by the influence of Hᵢₙₜ=H_{Z}+H_{zz}^{~.}

7.2.1 C₆₀

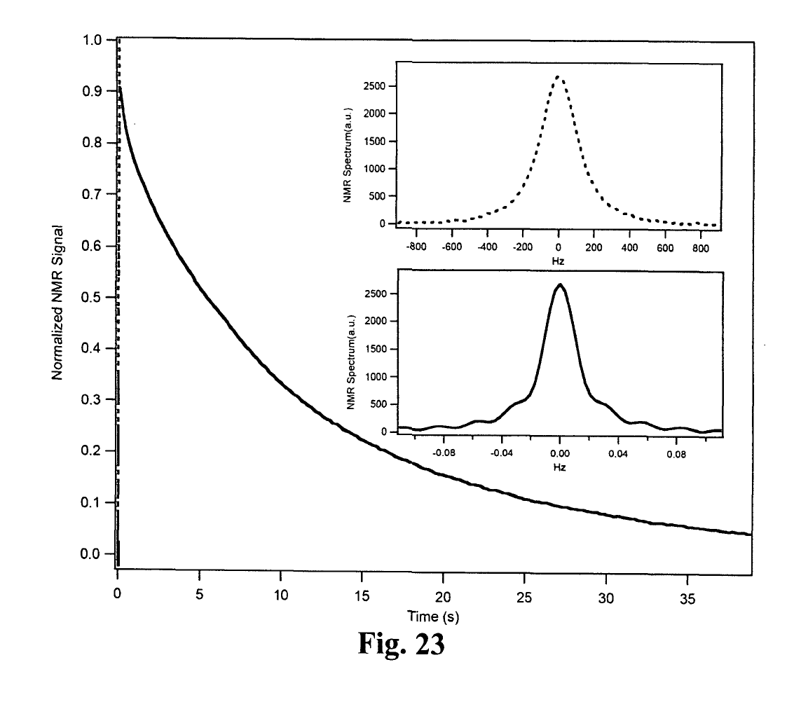

FIG. 23 shows the line narrowing sequence 90_{X}-{2, 0, −Y, −Y}^{m}, as in FIG. 8, applied to C₆₀ at room temperature, with ω₁/2π≈25 kHz, τ=22 μs, m≈96000, and ν_{offset}=3.5 kHz. The resulting signal (FIG. 23, solid line spectrum) extends well beyond the normal FID with v_{offset}=0 Hz (FIG. 23, dashed line spectrum). Fourier transformation of the decay curves shows that the 260 Hz normal spectrum (FIG. 23, inset, dashed line spectrum) is narrowed by a factor of almost 10,000, down to 0.03 Hz (FIG. 23, inset, solid line spectrum), centered at ν_{offset}. This line-narrowing sequence works similarly over the off-resonance range 2π|ν_{offset}|/ω₁≦20%, and for N=2-20 (FIGS. 21A-F). Using the line-narrowing sequence, the measured T₂^{effective}≈12 secs is close to the measured spin-lattice relaxation time T₁≈30 secs. The signals in FIG. 23 are normalized to the amplitude of the normal FID signal in the sample.

7.2.2 Silicon (²⁹Si)

FIG. 8 shows the line-narrowing data from sample Si:Sb (˜10¹⁷/cm³) using the sequence 90_{X}-{2, 0, −Y, −Y}^{m} with N=2, τ=60 μs, ν_{offset}=2.5 kHz, and m=84000. The line-narrowing signal (FIG. 8, dotted spectrum) extends well beyond the normal FID with ν_{offset}=0 Hz (FIG. 8, dashed line spectrum). Fourier transformation of the decay curves shows that the 200 Hz normal spectrum (FIG. 8, inset, dashed line spectrum) is narrowed to 0.003 Hz (FIG. 8, inset, solid line spectrum), centered at ν_{offset}.

7.2.3 Phosphorus (³¹P)

7.2.3.1 Human Tooth

FIG. 16A shows line narrowing sequence 90_{X}-{2, 0, +Y, +Y}^{m} applied to ³¹P NMR of a human deciduous tooth (τ=20 μs) at room temperature. Here, m≈1500, ν_{offset}=3 kHz, the pulse strength ω₁/2π≈80 kHz, and B=12 Tesla. The line narrowing sequence yields signal (FIG. 16A, dotted spectrum) that extends well beyond the normal FID with ν_{offset}=0 Hz (FIG. 16A, solid line spectrum). Fourier transformation of the decay curves shows that the 3.4 kHz normal spectrum (FIG. 16A, left inset spectrum) is narrowed by a factor of almost 300, down to 11 Hz, centered at ν_{offset} (FIG. 16A, right inset spectrum). These factors are preliminary, as they appear to be limited by the phase noise of the Tecmag Apollo “synth5” spectrometer at this 206.95 MHz Larmor frequency. A Tecmag Apollo “synth8” spectrometer yielded the data in FIG. 29, which is also a measurement on a human tooth, and which had a factor of 1200 line narrowing instead of 300. A Tecmag LapNMR “synth8” spectrometer, which is limited to <130 MHz, was used to acquire the longer T₂^{effective} data in FIGS. 8, 9, 21A-F, and 23.

7.2.3.2 Cattle Bone

FIG. 16B shows line narrowing sequence 90_{X}-{2, 0, +Y, +Y}^{m} applied to ³¹P NMR of a cattle bone (τ=12 μs), at room temperature. Here, m≈1500, ν_{offset}=3 kHz, the pulse strength ω₁/2π≈80 kHz, and B=12 Tesla. The line narrowing sequence yields signal (FIG. 16B, dotted spectrum) that extends well beyond the normal FID with ν_{offset}=0 Hz (FIG. 16B, solid line spectrum). Fourier transformation of the decay curves shows that the 3.4 kHz normal spectrum (FIG. 16B, left inset spectrum) is narrowed by a factor of almost 500, down to 8 Hz, centered at ν_{offset} (FIG. 16B, right inset spectrum). These factors are preliminary, as they appear to be limited by the phase noise of the Tecmag Apollo “synth5” spectrometer at this 206.95 MHz Larmor frequency. A Tecmag LapNMR “synth8” spectrometer, which is limited to <130 MHz, was used to acquire the longer T₂^{effective} data in FIGS. 8, 9, 21A-F, and 23).

### 7.3 Controlling Location of Signal Maxima Using Offset Frequencies

7.3.1 C₆₀

In FIGS. 7A-D, the simulated Zeeman phase angle Φ_{Z}(t) during and after the quadratic burst for (7A) ν_{offset}=0 Hz and (7B) ν_{offset}=−3 kHz evolves differently than the linear burst for (7C) ν_{offset}=0 Hz and (7D) ν_{offset}=−1 kHz, where Ω_{offset}^{global}≡−hv_{offset}. Representative

$$\frac{{Ω}_{z}^{loc}}{h} = + / - 100 Hz$$

values are shown in each of FIGS. 7A-D as a solid line and a dashed line. The Zeeman refocusing time occurs when the two lines cross at t=0 (FIGS. 7A, 7C, 7D) or t>0 (FIG. 7B). Signal measurement begins at the end of the burst (t=0 ms) and is shown in FIG. 7E, with the spectra labeled 700, 702, 704 and 706 corresponding to FIGS. 7A-D, respectively. Note that only the black echo is shifted to the right. FIG. 7F is an image plot of 31 quadratic echoes as a function of Ω_{offset}^{global}, for

$$0 Hz \leq \frac{{Ω}_{offset}^{global}}{h} \leq 3 kHz ,$$

in steps of 100 Hz. The black trend line in FIG. 7F indicates the Zeeman refocusing time predicted by our model. τ=10 μs and N=100.

A Tecmag Apollo “synth5” spectrometer was used to implement the phase-coherent frequency jumping in FIG. 7. FIG. 7F shows the strong agreement between the Zeeman refocusing time predicted by our model (black trend line) and the quadratic echo peak global measured over a range of Ω_{offset}^{global}.

7.3.2 Pseudo-Hahn Echo from C₆₀

The pseudo-Hahn echo from sample C₆₀ produced by the sequence 90_{X}-{2, 0, −Y, −Y}-{{2, −δ, −Y, −Y}{2, +δ, Y, Y}}^{m}^{₁}-{{2, +δ, −Y, −Y, }{2, −δ, Y, Y}}^{m}^{₂}, for m₁=29, m₂=58, ν_{offset}=−2 kHz, τ=22 μs and δ=30 μs. The <I_{y}_{_{T> (red) and <I}}ₓ_{_{T> (black) signals acquired after each block are plotted versus the net Zeeman phase wrapping time}} 2δP, where P=0, 1, 2, 3 . . . (FIG. 18). The pseudo-Hahn echo is induced by a reversal of the δ-pattern in the m₂ blocks, after the initial pseudo-FID in the m₁ blocks. The signals oscillate as expected for ν_{offset}^{global}=−2 kHz, and decay to zero during the first m₁ blocks, which we refer to as a “pseudo-FID”.

FIG. 10 shows a reproduction of a top-hat lineshape using our MRI of solids sequence 90_{X}-{2, tₒ, −Y, −Y}-{2, 0,−Y, Y}^{m}, for m=30, τ=22 μs, and tₒ=0. Each trace is the measured spectrum of a pseudo-FID with different ν_{offset}, for −4 kHz≦ν_{offset}≦+4 kHz in steps of 500 Hz. To obtain this full bandwidth, the pseudo-FID interleaves a second data set using the same sequence (FIG. 12), but with

$${t}_{0} = - ( \frac{Δ}{2} + \frac{1}{2 {ω}_{1}} ) .$$

Signal amplitude and frequency are accurately reconstructed over the range 2πν_{offset}|/ω₁≦16%, even with misadjustment of pulse angles (FIG. 11).

### 8. REFERENCES CITED

All references cited herein are incorporated herein by reference in their entirety and for all purposes to the same extent as if each individual publication or patent or patent application was specifically and individually indicated to be incorporated by reference in its entirety herein for all purposes. Discussion or citation of a reference herein will not be construed as an admission that such reference is prior art to the present invention.

### 9. MODIFICATIONS

Many modifications and variations of this invention can be made without departing from its spirit and scope, as will be apparent to those skilled in the art. The specific embodiments described herein are offered by way of example only, and the invention is to be limited only by the terms of the appended claims, along with the full scope of equivalents to which such claims are entitled.

1. A method of controlling coherence of a magnetic resonance signal of a sample in an external magnetic field applied in the positive z-direction, the sample comprising a plurality of spin species, the method comprising the following steps in the order stated:
(a) applying a first pulse sequence to the sample N/2 times, wherein N is an even integer greater than or equal to 2, the first pulse sequence consisting essentially of the following steps in the order stated:
(i) a first free-evolution period for a time duration τ₁;
(ii) a first approximate π pulse in the positive or negative x-direction applied for a time duration tₚ;
(iii) a second free-evolution period for a time duration 2τ₂;
(iv) a second approximate π pulse in the direction of the first approximate π pulse applied for the time duration tₚ; and
(v) a third free-evolution period for the time duration τ₃;
wherein the first approximate π pulse and the second approximate π pulse are each applied with an offset frequency ν having a magnitude greater than or equal to zero,
whereby the duration of the first pulse sequence is t_{c}≈τ₁+2τ₂+τ₃+2tₚ; and
(b) applying a second pulse sequence to the sample N/2 times, the second pulse sequence consisting essentially of the following steps in the order stated:
(i) a fourth free-evolution period for the time duration τ₄;
(ii) a third approximate π pulse in a second direction substantially opposite to the direction of the first approximate π pulse applied for the time duration tₚ;
(iii) a fifth free-evolution period for the time duration 2τ₅;
(iv) a fourth approximate π pulse in the direction of the third approximate π pulse applied for the time duration tₚ; and
(v) a sixth free-evolution period for the time duration τ₆;
wherein the third approximate π pulse and the fourth approximate π pulse are each applied with an offset frequency ν₁=±ν,
whereby the duration of the second pulse sequence is approximately t_{c};
whereby the coherence of the magnetic resonance signal is controlled.

2. (canceled)

3. (canceled)

4. The method of claim 1, wherein 2τ₂≈τ₁+τ₃ and 2τ₅≈τ₄+τ₆.

5. (canceled)

6. The method of claim 1, wherein ν₁=−ν and time durations τ₁, τ₂, τ₃, τ₄, τ₅, and τ₆ are approximately equal to each other, the method further comprising the steps of:
(c) after step (b), applying an approximate π/2 pulse to the sample:
(i) in the positive y-direction if ν≦0 and the first approximate π pulse is in the positive x-direction, or if ν≧0 and the first approximate π pulse is in the negative x-direction, or
(ii) in the negative y-direction if ν≦0 and the first approximate π pulse is in the positive x-direction, or if ν≧0 and the first approximate π pulse is in the negative x-direction; and
(d) after step (c), allowing free evolution of the plurality of spin species for a seventh free-evolution period;
whereby the magnetic resonance signal reaches a maximum value at a time proportional to the magnitude of the offset frequency ν.

7. (canceled)

8. (canceled)

9. (canceled)

10. The method of claim 1, wherein ν₁=ν and time durations τ₁, τ₂, τ₃, τ₄, τ₅, and τ₆ are approximately equal to each other, said method further comprising:
(c) prior to step (a), allowing free evolution of the plurality of spin species for a seventh free-evolution time period of duration Δ+δ, wherein Δ=N t_{c}/4 and Δ≧|δ|;
(d) after step (c) but prior to step (a), applying a first approximate π/2 pulse to the sample in the positive or negative y-direction with an offset frequency ν;
(e) after step (b), applying a second approximate π/2 pulse to the sample in the positive or negative y-direction with an offset frequency ν; and
(f) after step (e), allowing free evolution of the plurality of spin species for an eighth free-evolution time period of duration Δ−δ;
whereby performing steps (c), (d), (a), (b), (e), and (f) in the order stated results in substantially no net dipolar evolution of the plurality of spin species.

11. The method of claim 10, further comprising repeating steps (c), (d), (a), (b), (e), and (f) in the order stated, wherein, in said repeating, said first approximate π pulse is applied in the positive or negative x′-direction, and said first and second approximate π/2 pulses are applied in the positive or negative y′-direction, and wherein the x′-direction and the y′-direction are rotated in the x-y plane by an angle φrelative to the x-direction and the y-direction.

12. The method of claim 10, wherein δ=0 and wherein the first approximate π/2 pulse and the second approximate π/2 pulse are both in the positive y-direction or are both in the negative y-direction, the method further comprising:
(g) prior to step (c), applying a third approximate π/2 pulse in a first direction;
(h) repeating steps (c), (d), (a), (b), (e), and (f) in the order stated m−1 additional times, wherein m is an integer greater than or equal to 2; and
(i) measuring the magnetic resonance signal during at least one occurrence of step (c), during at least one occurrence of step (f), and/or at a time corresponding to a transition between an occurrence of step (c) and an occurrence of step (f).

13. The method of claim 12, wherein the first direction is the positive or negative x-direction.

14. The method of claim 12, wherein the first direction is the positive or negative y-direction, further comprising:
(j) after step (h), repeating steps (c), (d), (a), (b), (e), and (f) in the order stated P times, wherein P is an integer greater than or equal to 1,
wherein in a first occurrence of steps (c), (d), (a), (b), (e), and (f) in the order stated, the first approximate π pulse is in a second direction;
wherein in said repeating steps (c), (d), (a), (b), (e), and (f) in the order stated in step (h), the first approximate π pulse is in either the second direction or a direction opposite to the second direction; and
wherein in said repeating steps (c), (d), (a), (b), (e), and (f) in the order stated in step (j), the first approximate pi pulse is in the direction opposite to the second direction.

15. The method of claim 10, the method further comprising:
(g) prior to step (c), applying a pulse sequence consisting of the following steps in the order stated:
(i) a third approximate π/2 pulse in the positive or negative x-direction applied with an offset frequency ν;
(ii) a ninth free-evolution period for a time duration Δ+t₀, wherein Δ>|t₀|;
(iii) a fourth approximate π/2 pulse in the positive or negative y-direction applied with an offset frequency ν;
(iv) a tenth free-evolution period for the time duration τ,
(v) an fifth approximate π pulse in the positive or negative x-direction applied with the offset frequency ν;
(vi) an eleventh free-evolution period for the time duration 2τ,
(vii) a sixth approximate π pulse in the same direction as the fifth approximate π pulse applied with the offset frequency ν;
(viii) a twelfth free-evolution period for the time duration τ;
(ix) a thirteenth free-evolution period for the time duration τ,
(x) a seventh approximate π pulse in a direction substantially opposite to the direction of the fifth approximate π pulse applied with the offset frequency ν;
(xi) a fourteenth free-evolution period for the time duration 2τ,
(xii) an eighth approximate π pulse in the direction of the seventh approximate π pulse applied with the offset frequency ν;
(xiii) a fifteenth free-evolution period for the time duration τ;
(xiv) a fifth approximate π/2 pulse in the positive or negative y-direction applied with an offset frequency ν; and
(xv) a sixteenth free-evolution period for a time duration Δ−t₀;
(h) repeating steps (c), (d), (a), (b), (e), and (f) in the order stated m−1 additional times, wherein m is an integer greater than or equal to 2, wherein the first approximate π/2 pulse and the second approximate π/2 pulse are in opposite directions, and wherein the direction of the first approximate π/2 pulse in a first repetition is the same as or opposite to the direction of the first approximate π/2 pulse in any additional repetitions;
(i) measuring the magnetic resonance signal during at least one occurrence of step (c), during at least one occurrence of step (f), and/or at a time corresponding to a transition between an occurrence of step (c) and an occurrence of step (f).

16. The method of claim 15, further comprising the step of: (j) performing a Fourier transform on the measured time-domain magnetic resonance signal to provide a frequency-domain signal with a maximum value at a frequency proportional to the offset frequency ν.

17. (canceled)

18. The method of claim 15, further comprising
(j) repeating steps (g), (c), (d), (a), (b), (e), (f), (h), and (i) in the order stated,
wherein in a first occurrence of performing steps (g), (c), (d), (a), (b), (e), (f), (h), and (i) in the order stated, t₀=0 and a first measured time-domain magnetic resonance signal is obtained, and
wherein in said repeating steps (g), (c), (d), (a), (b), (e), (f), (h), and (i) in the order stated, t₀=t₁>0 and a second measured time-domain magnetic resonance signal is obtained;
(k) superimposing the first measured time-domain magnetic resonance signal and the second measured time-domain magnetic resonance signal to provide a composite time-domain signal;
(l) performing a Fourier transform on the composite time-domain signal to provide a frequency-domain signal with a maximum value at a frequency value proportional to the offset frequency ν;
(m) repeating steps (j), (k), and (l) in the order stated one or more times, each said repeating being with a different value of offset frequency u, thereby yielding a plurality of frequency-domain signals, each having a maximum value at a frequency proportional to the corresponding value of offset frequency ν.

19. The method of claim 18, wherein
$${t}_{1} = - ( \frac{Δ}{2} + \frac{1}{2 {ω}_{1}} )$$
and wherein the approximate π pulses have a strength ω₁=π/tₚ.

20. (canceled)

21. The method of claim 15, further comprising applying a gradient magnetic field in the z-direction during at least one occurrence of step (c) and/or step (f), wherein the gradient magnetic field has a magnitude that varies across the sample, and obtaining a frequency-domain signal with a plurality of local maxima corresponding to magnetic resonance signals for a plurality of regions of the sample.

22. The method of claim 21, further comprising applying the gradient magnetic field during at least one occurrence of step (a) and/or step (b).

23. (canceled)

24. The method of claim 10, wherein δ equals zero, the method further comprising:
(g) prior to step (c), applying a pulse sequence consisting of the following steps in the order stated:
(i) a third approximate π/2 pulse in the positive x-direction;
(ii) a ninth free-evolution period for a time duration Δ+t₀, wherein Δ>|t₀|;
(iii) a fourth approximate π/2 pulse in the negative or positive y-direction applied with an offset frequency ν;
(iv) a tenth free-evolution period for the time duration τ,
(v) a fifth approximate π pulse in the positive or negative x-direction applied with the offset frequency ν;
(vi) an eleventh free-evolution period for the time duration 2τ,
(vii) a sixth approximate π pulse in the same direction as the fifth approximate π pulse applied with the offset frequency ν;
(viii) a twelfth free-evolution period for the time duration τ;
(ix) a thirteenth free-evolution period for the time duration τ,
(x) a seventh approximate π pulse in a direction opposite to the direction of the fifth approximate π pulse applied with the offset frequency ν;
(xi) a fourteenth free-evolution period for the time duration 2τ,
(xii) an eighth approximate π pulse in the direction of the seventh approximate π pulse applied with the offset frequency ν;
(xiii) a fifteenth free-evolution period for the time duration τ;
(xiv) a fifth approximate π/2 pulse in the negative y-direction applied with an offset frequency ν; and
(xv) a sixteenth free-evolution period for a time duration Δ−t₀;
(h) repeating steps (c), (d), (a), (b), (e), and (f) in the order stated m−1 additional times, wherein m is an integer greater than or equal to 2, wherein the first approximate π/2 pulse and the second approximate π/2 pulse are in the same direction, and wherein the direction of the first approximate π/2 pulse in a first repetition is the same as or opposite to the direction of the first approximate π/2 pulse in any additional repetitions;
(i) applying a gradient magnetic field, wherein the gradient magnetic field varies with time during at least one occurrence of step (c) and/or step (f) and the gradient magnetic field remains constant with time during step (a) and/or step (b), whereby performing steps (c), (d), (a), (b), (e), (f), (h), and (i) in the order stated results in a net Zeeman evolution due to a Hamiltonian term dependant on D and no net Zeeman evolution due to local interactions;
(j) measuring the magnetic resonance signal during at least one occurrence of step (c), during at least one occurrence of step (f), and/or at a time corresponding to a transition between an occurrence of step (c) and an occurrence of step (f); and
(k) repeating steps (g), (c), (d), (a), (b), (e), (f), (h), (i), and (j) in the order stated one or more times, each said repeating being with a different value of offset frequency ν, thereby yielding a plurality of frequency-domain signals, each having a maximum value at a frequency proportional to the corresponding value of offset frequency ν.

25. The method of claim 1, wherein τ₁=τ₂=τ₃, further comprising:
(c) prior to step (a), allowing free evolution of the plurality of spin species for a seventh free-evolution time period of duration Δ+δ, wherein δ>−Δ;
(d) after step (c) but prior to step (a), applying a first approximate π/2 pulse to the sample in the positive or negative y-direction;
(e) after step (b), applying a second approximate π/2 pulse to the sample in the same direction as the first approximate π/2 pulse; and
(f) after step (e), allowing free evolution of the plurality of spin species for an eighth free-evolution time period of duration Δ+δ; and
(g) measuring the magnetic resonance signal.

26. The method of claim 1, wherein motion of the spin species is governed by a Hamiltonian having a Zeeman term H_{Z} and a dipolar-coupling term H_{ZZ}, and wherein ∥H_{Z}∥≧∥H_{ZZ}∥.

27. A method of controlling coherence of a magnetic resonance signal of a sample in an external magnetic field applied in the positive z-direction, the sample comprising a plurality of spin species, the method comprising the following steps in the order stated:
(a) applying a pulse sequence to the sample N times, wherein N is an integer greater than or equal to 1, the pulse sequence consisting of the following steps in the order stated:
(i) a first free-evolution period for a time duration τ;
(ii) a first approximate π pulse in the negative x-direction applied for a time duration tₚ;
(iii) a second free-evolution period for a time duration 2τ,
(iv) a second approximate π pulse in the positive x-direction applied for the time duration tₚ; and
(v) a third free-evolution period for the time duration τ;
whereby the duration of the pulse sequence is t_{c}≈4τ+2tₚ; and
(b) applying an approximate π/2 pulse to the sample in the negative x-direction; and
(c) applying a third approximate π pulse to the sample in the positive or negative y-direction at a time t₁ after step (b) selected to produce an echo at time t_{echo}>t₁, thereby controlling coherence of the magnetic resonance signal.

28. The method of claim 27, wherein
$${t}_{1} = ( \frac{α - β - 2 λ}{4} ) {Nt}_{c} ,$$
wherein
$$α = \frac{4 τ}{{t}_{c}} , β = \frac{{t}_{p}}{{t}_{c}} , and λ = \frac{4 {t}_{p}}{π {t}_{c}} .$$

29. The method of claim 28, wherein motion of a first subset of the plurality of spin species is governed by a first Hamiltonian H₁ having a first Zeeman term H_{Z1} and a first dipolar-coupling term H_{ZZ1} and motion of a second subset of the plurality of spin species is governed by a second Hamiltonian H₂ having a second Zeeman term H_{Z2} and a second dipolar-coupling term H_{ZZ2}, wherein H_{Z1} is different from H_{Z2} causing the magnetic resonance signal to decohere and/or H_{ZZ1} is different from H_{ZZ2} causing the magnetic resonance signal to decohere, the method further comprising selecting t₁ so that coherence is substantially restored at time t_{echo}.

30. (canceled)

31. (canceled)

32. A method of controlling coherence of a magnetic resonance signal of a sample in an external magnetic field applied in the positive z-direction, the sample comprising a plurality of spin species, wherein the motion of the spin species is governed by a Hamiltonian having a Zeeman term H_{Z} and a dipolar-coupling term H_{ZZ}, the method comprising applying a pulse sequence of the form {N, δ, Ψ₁, Ψ₂, Φ₁, Φ₂, Φ₃, Φ₄} to produce at least one echo, whereby the coherence of the magnetic resonance signal is controlled.

33. The method of claim 32, wherein ∥H_{Z∥≧∥H}_{ZZ}∥.

34. A method of controlling coherence of a magnetic resonance signal of a sample comprising a plurality of spin species, the method comprising applying an external magnetic field in a first direction, and applying a pulse sequence consisting essentially of a plurality of approximate π pulses in at least one direction approximately perpendicular to the external magnetic field, the approximate π pulses having respective durations, the approximate π pulses separated by periods of free evolution having respective durations, wherein the durations of the approximate π pulses and the durations of the periods of free evolution are selected to control coherence in the magnetic resonance signal, whereby the pulse sequence is defined by a Hamiltonian having a quadratic effective-field term that depends on the durations of the approximate π pulses and the durations of the free periods of evolution, and the coherence of the magnetic resonance signal is controlled by an effect of the quadratic effective-field term.

35. A method of controlling coherence of a magnetic resonance signal of a sample comprising a plurality of spin species, the method comprising applying an external magnetic field in a first direction, and applying a pulse sequence consisting essentially of a plurality of approximate π pulses in at least one direction approximately perpendicular to the external magnetic field, the approximate π pulses having respective durations, the approximate π pulses separated by periods of free evolution having respective durations, wherein the durations of the approximate π pulses and the durations of the periods of free evolution are selected to control coherence in the magnetic resonance signal, whereby the pulse sequence is defined by a Hamiltonian having a linear effective-field term that depends on the durations of the approximate π pulses and the durations of the free periods of evolution, and the coherence of the magnetic resonance signal is controlled by an effect of the linear effective-field term.

36. The method of claim 35 for controlling coherence of a magnetic resonance signal of a sample in an external magnetic field, wherein the first direction is the positive z-direction, the method comprising the following steps in the order stated:
(a) applying an approximate π/2 pulse in the positive or negative x-direction;
(b) applying the pulse sequence to the sample N times, wherein N is an integer greater than or equal to 1, the pulse sequence consisting essentially of the following steps in the order stated:
(i) a first free-evolution period for a time duration τ;
(ii) a first approximate π pulse in the positive or negative y-direction applied for a time duration tₚ;
(iii) a second free-evolution period for a time duration 2τ;
(iv) a second approximate π pulse in a direction opposite to the direction of the first approximate π pulse applied for the time duration tₚ; and
(v) a third free-evolution period for the time duration τ;
(c) applying a third approximate π pulse to the sample in the positive or negative y-direction; and
(d) applying the pulse sequence to the sample at least N times;
whereby an echo is produced in the magnetic resonance signal at a time occurring when the pulse sequence has been applied for a total of 2N times and coherence of the magnetic resonance signal is thereby controlled.

37. (canceled)

38. (canceled)

39. The method of claim 35 for controlling coherence of a magnetic resonance signal of a sample in an external magnetic field, wherein the first direction is the positive z-direction, the method comprising the following steps in the order stated:
(a) applying an approximate π/2 pulse in the positive or negative x-direction;
(b) applying a first pulse sequence to the sample N times, wherein N is an integer greater than or equal to 1, the first pulse sequence consisting essentially of the following steps in the order stated:
(i) a first free-evolution period for a time duration τ;
(ii) a first approximate π pulse in the positive or negative y-direction applied for a time duration tₚ;
(iii) a second free-evolution period for a time duration 2τ;
(iv) a second approximate π pulse in a direction opposite to the direction of the first approximate π pulse applied for the time duration tₚ; and
(v) a third free-evolution period for the time duration τ;
(c) applying a second pulse sequence to the sample M times, wherein M is an integer greater than or equal to N, the second pulse sequence consisting essentially of the following steps in the order stated:
(i) a fourth free-evolution period for a time duration τ;
(ii) a third approximate π pulse in the direction of the second approximate π pulse applied for a time duration tₚ;
(iii) a fifth free-evolution period for a time duration 2τ;
(iv) a fourth approximate π pulse in the direction of the first approximate π pulse applied for the time duration tₚ; and
(v) a sixth free-evolution period for the time duration τ; and
whereby an echo is produced in the magnetic resonance signal at a time occurring when the second pulse sequence has been applied N times and coherence of the magnetic resonance signal is thereby controlled.

40. The method of claim 39, wherein M=2N, further comprising the step of applying a third pulse sequence at least one time, wherein the third pulse sequence consists essentially of:
(d) applying the first pulse sequence M times;
(e) applying the second pulse sequence M times;
whereby an echo is produced during at least one occurrence of step (d) after the first pulse sequence has been applied M/2 times and an echo is produced during at least one occurrence of step (e) after the second pulse sequence has been applied M/2 times and coherence of the magnetic resonance signal is thereby controlled.

41. The method of claim 35 for controlling coherence of a magnetic resonance signal of a sample in an external magnetic field, wherein the first direction is the positive z-direction, the method comprising the following steps in the order stated:
(a) applying the pulse sequence to the sample N times, wherein N is an integer greater than or equal to 1, the pulse sequence consisting of the following steps in the order stated:
(i) a first free-evolution period for a time duration τ;
(ii) a first approximate π pulse in the positive or negative x-direction applied for a time duration tₚ;
(iii) a second free-evolution period for a time duration 2τ,
(iv) a second approximate π pulse in a direction opposite to the direction of the first approximate π pulse applied for the time duration tₚ; and
(v) a third free-evolution period for the time duration τ;
whereby the duration of the pulse sequence is t_{c}≈4τ+2tₚ; and
(b) applying an approximate π/2 pulse to the sample in the positive or negative x-direction; and
(c) allowing for free evolution of the plurality of spin species, whereby at a time during step (c) net evolution of the plurality of spin species due to dipolar coupling is zero;
whereby coherence of the magnetic resonance signal is controlled.

42. The method of claim 41, wherein the approximate π/2 pulse is in the positive or negative x-direction, whereby at a time during step (c) net evolution of the plurality of spin species due to Zeeman interaction is zero.

43. A method of controlling coherence of a magnetic resonance signal of a sample comprising a plurality of spin species, the method comprising:
(a) applying an external magnetic field in a positive direction along a first axis to a sample comprising a plurality of spin species, wherein motion of said plurality of spin species, in the absence of any additional externally applied magnetic field or radio-frequency (rf) field, is governed by an internal Hamiltonian (Hᵢₙₜ) comprising a Zeeman term (H_{Z}) and a dipolar term (H_{ZZ}); and
(b) applying two or more pulse sequences to said sample, each said pulse sequence consisting essentially of a plurality of hard approximate nπ pulses, wherein n is a positive odd integer, and a plurality of periods of free evolution having respective duration, said periods of free evolution separating each said hard approximate nπ pulse from each other, each said hard approximate nπ pulse in each said pulse sequence being applied in a positive or negative direction along a second axis perpendicular to said first axis, each said hard approximate nπ pulse in each said pulse sequence having a respective duration of ntₚ, wherein tₚ is a duration of a hard approximate π pulse, and each said approximate hard nπ pulse in each said pulse sequence optionally differing in values of n and in direction along the second axis;
wherein, each said pulse sequence has a even number greater than zero of said hard approximate nπ pulses such that in a limit where each of said hard approximate nπ pulses in said pulse sequence is considered to have zero duration, said plurality of spin species are returned at the end of said pulse sequence to substantially the same orientation as said plurality of spin species had prior to applying said pulse sequence;
wherein, for each said pulse sequence, the number of said approximate nπ pulses in said pulse sequence, said values of n for said approximate nπ pulses in said pulse sequence, said directions of said approximate nπ pulses in said pulse sequence, and said durations of said periods of free evolution in said pulse sequence, are such that when each said hard approximate nπ pulse is considered to have nonzero duration, said motion of said plurality of spin species during said applying said pulse sequence is governed by a respective effective Hamiltonian for said pulse sequence comprising a nonzero term representing an effective magnetic field applied in a positive or negative direction along a third axis;
wherein said motion of said plurality of spin species during said applying a first pulse sequence of said two or more pulse sequences is governed by an effective Hamiltonian H_{eff1} and said motion of said plurality of spin species during said applying a second pulse sequence of said two or more pulse sequences is governed by an effective Hamiltonian H_{eff2}≠H_{eff1}; and
wherein applying said first pulse sequence and said second pulse sequence of said two or more pulse sequences causes said plurality of spin species to cohere at one or more times after said applying said first pulse sequence and said second pulse sequence of said two or more pulse sequences, thereby controlling said coherence of said magnetic resonance signal of said sample.

44. The method of claim 43, further comprising allowing free evolution of said plurality of spin species for an additional period before or after said applying said two or more pulse sequences, whereby motion of said plurality of spin species during said additional period of free evolution is governed by Hᵢₙₜ, wherein said two or more pulse sequences are such that said applying said two or more pulse sequences causes a motion of said plurality of spin species opposite to a motion of said plurality of spin species caused by H_{z} and/or H_{zz} during said additional period of free evolution, whereby said plurality of spin species cohere at a time t after said applying said two or more pulse sequences, said time t occurring during or after said additional period.

45. The method of claim 44, wherein said respective effective Hamiltonians and Hᵢₙₜ are such that both Zeeman phases and dipolar phases of said motion of said plurality of spin species cohere substantially at time t.

46. The method of claim 43, wherein said applying said first pulse sequence of said two or more pulse sequences causes a first motion of said plurality of spin species, said applying said second pulse sequence causes a second motion of said plurality of spin species, and said second motion of said plurality of spin species reverses said first motion of said plurality of spin species.

47. (canceled)

48. (canceled)

49. The method of claim 43, wherein said sample comprises a solid, a soft solid or a partially aligned liquid.

50. The method of claim 43, wherein said first pulse sequence and said second pulse sequence are each repeated N/2 times, wherein N is an even integer greater than or equal to two.

51. (canceled)

52. The method of claim 43, wherein said first axis is the z-axis, said second axis is the y-axis, and said first pulse sequence comprises a repeating block of the form {Y,−Y} or {−Y,Y}, whereby said third axis is the x-axis and said respective effective Hamiltonian for said first pulse sequence has a term λΩ_{z}^{net}Iₓ_{_{T}} if the repeating block is {Y,−Y} and λΩ_{z}^{net}Iₓ_{_{T}} if the repeating block is {−Y,Y}.

53. (canceled)

54. The method of claim 43, wherein said first axis is the z-axis, the second axis is the y-axis, and said first pulse sequence comprises a repeating block of the form {±Y,±Y}, whereby said third axis is the y-axis and said respective effective Hamiltonian for said first pulse sequence has a term ±(κΩ_{z}^{net})²I_{y}_{_{T}}.

55. (canceled)

56. A method of imaging a solid, a soft solid or a partially aligned liquid, comprising performing the method of claim 1.

57. An apparatus for controlling an instrument for measuring a magnetic resonance signal of a sample in an external magnetic field applied in the positive z-direction, the sample comprising a plurality of spin species, the apparatus comprising:
(a) a processor; and
(b) a memory, coupled to the processor, the memory storing a module comprising:
(i) instructions for performing the method of claim 1; and
(ii) instructions for outputting a measured magnetic resonance signal to a user interface device, a monitor, a computer-readable storage medium, a computer-readable memory, or a local or remote computer system, or for displaying the measured magnetic resonance signal.

58. A computer readable medium storing a computer program executable by a computer to control an instrument for measuring a magnetic resonance signal of a sample in an external magnetic field in the positive z-direction, the sample comprising a plurality of spin species, the computer program comprising:
(a) instructions for performing the method of claim 1; and
(b) instructions for outputting a measured magnetic resonance signal to a user interface device, a monitor, a computer-readable storage medium, a computer-readable memory, or a local or remote computer system, or for displaying the measured magnetic resonance signal.

59. (canceled)

60. The method of claim 1, wherein motion of the spin species is governed by a Hamiltonian having a Zeeman term H_{Z}, a dipolar-coupling term H_{ZZ}, and another term Hₒₜₕₑᵣ.

61. The method of claim 60, wherein ∥H_{Z}+H_{zz}∥≧∥Hₒₜₕₑᵣ∥.

62. The method of claim 1, wherein the sample is subjected to magic angle spinning.

63. A method of controlling coherence of a resonance signal of a sample comprising a plurality of pseudospin species whose motion, in the absence of any externally applied field, is governed by an equivalent Hamiltonian (Hᵢₙₜ) comprising an equivalent Zeeman term (H_{z}) and an equivalent dipolar term (H_{ZZ}), the method comprising:
(a) applying two or more pulse sequences to said sample, each said pulse sequence consisting essentially of a plurality of hard approximate nπ pulses, wherein n is a positive odd integer, and a plurality of periods of free evolution having respective duration, said periods of free evolution separating each said hard approximate nπ pulse from each other, each said hard approximate nπ pulse in each said pulse sequence being applied along a first axis, each said hard approximate nπ pulse in each said pulse sequence having a respective duration of ntₚ, wherein tₚ is a duration of a hard approximate π pulse, and each said approximate hard nπ pulse in each said pulse sequence optionally differing in values of n and in direction along the first axis;
wherein, each said pulse sequence has an even number greater than zero of said hard approximate nπ pulses such that in a limit where each of said hard approximate nπ pulses in said pulse sequence is considered to have zero duration, said plurality of pseudospin species are returned at the end of said pulse sequence to substantially the same state as said plurality of pseudospin species had prior to applying said pulse sequence;
wherein, for each said pulse sequence, the number of said approximate nπ pulses in said pulse sequence, said values of n for said approximate nπ pulses in said pulse sequence, said directions of said approximate nπ pulses in said pulse sequence, and said durations of said periods of free evolution in said pulse sequence, are such that when each said hard approximate nπ pulse is considered to have nonzero duration, said motion of said plurality of pseudospin species during said applying said pulse sequence is governed by a respective effective Hamiltonian for said pulse sequence comprising a nonzero term representing an effective magnetic field applied in a positive or negative direction along a second axis perpendicular to the first axis;
wherein said motion of said plurality of pseudospin species during said applying a first pulse sequence of said two or more pulse sequences is governed by an effective Hamiltonian H_{eff1} and said motion of said plurality of pseudospin species during said applying a second pulse sequence of said two or more pulse sequences is governed by an effective Hamiltonian H_{eff2}≠H_{eff1}; and
wherein applying said first pulse sequence and said second pulse sequence of said two or more pulse sequences causes said plurality of pseudospin species to cohere at one or more times after said applying said first pulse sequence and said second pulse sequence of said two or more pulse sequences, thereby controlling said coherence of said resonance signal of said sample.

64. The method of claim 63, further comprising allowing free evolution of said plurality of pseudospin species for an additional period, whereby motion of said plurality of pseudospin species during said additional period of free evolution is governed by Hᵢₙₜ, wherein said two or more pulse sequences are such that said applying said two or more pulse sequences causes a motion of said plurality of pseudospin species opposite to a motion of said plurality of pseudospin species caused by H_{z} and/or H_{zz} during said additional period of free evolution, whereby said plurality of pseudospin species cohere at a time t after said applying said two or more pulse sequences, said time t occurring during or after said additional period.

65. The method of claim 64, wherein said respective effective Hamiltonians and Hᵢₙₜ are such that both Zeeman phases and dipolar phases of said motion of said plurality of pseudospin species cohere substantially at time t.

66. The method of claim 63, wherein, said applying said first pulse sequence of said two or more pulse sequences causes a first motion of said plurality of pseudospin species, said applying said second pulse sequence causes a second motion of said plurality of pseudospin species, and said second motion of said plurality of pseudospin species reverses said first motion of said plurality of pseudospin species.

67. The method of claim 63, wherein said sample comprises an array of pseudospin species.

68. The method of claim 63, wherein said first pulse sequence and said second pulse sequence are each repeated N/2 times, wherein N is an even integer greater than or equal to two.

69. (canceled)

70. The method of claim 63, wherein motion of the pseudospin species is governed by a Hamiltonian having an equivalent Zeeman term H_{Z}, an equivalent dipolar-coupling term H_{ZZ}, and another term Hₒₜₕₑᵣ.

71. A method of imaging an array of pseudospin species comprising performing the method of claim 63.

72. An apparatus for controlling an instrument for measuring a resonance signal of a sample, the sample comprising a plurality of pseudospin species, the apparatus comprising:
(a) a processor; and
(b) a memory, coupled to the processor, the memory storing a module comprising:
(i) instructions for performing the method of claim 63; and
(ii) instructions for outputting a measured magnetic resonance signal to a user interface device, a monitor, a computer-readable storage medium, a computer-readable memory, or a local or remote computer system, or for displaying the measured resonance signal.

73. A computer readable medium storing a computer program executable by a computer to control an instrument for measuring a resonance signal of a sample, the sample comprising a plurality of pseudospin species, the computer program comprising:
(a) instructions for performing the method of claim 63; and
(b) instructions for outputting a measured magnetic resonance signal to a user interface device, a monitor, a computer-readable storage medium, a computer-readable memory, or a local or remote computer system, or for displaying the measured resonance signal.

74. The method of claim 35 for controlling coherence of a magnetic resonance signal of a sample in an external magnetic field, wherein the first direction is the positive z-direction, the sample comprising a plurality of spin species, the method comprising:
(a) applying a first pulse sequence N times, wherein N is an integer greater than or equal to 1, the first pulse sequence having the form {−X,X};
(b) applying a second pulse sequence M times, wherein M is an integer greater than or equal to 1, wherein the second pulse sequence is applied before or after the first pulse sequence, the second pulse sequence having the form {X,−X}; and
(c) applying, after steps (a) and (b), an approximate π/2 pulse in the positive or negative x-direction, thereby producing an echo in the magnetic resonance signal.
